(19) United States
(12) Patent Application Publication
(10) Pub. No.: US 2024/0314999 A1
(43) Pub. Date: Sep. 19, 2024

(54) SEMICONDUCTOR DEVICE

(71) Applicant: Semiconductor Energy Laboratory Co., Ltd., Atsugi-shi (JP)

(72) Inventors: Hidekazu MIYAIRI, Hadano (JP); Motoki NAKASHIMA, Atsugi (JP)

(21) Appl. No.: 18/596,907

(22) Filed: Mar. 6, 2024

(30) Foreign Application Priority Data
Mar. 14, 2023 (JP) 2023-039908

(51) Int. Cl. H10B 12/00

(52) U.S. Cl. CPC H10B 12/00

(57) ABSTRACT

A semiconductor device that can be miniaturized or highly integrated is provided. The semiconductor device includes a first transistor, a capacitor, and a second transistor stacked in this order. The first and second transistors each include a semiconductor layer, a first conductor over the semiconductor layer, a first insulator, and a second conductor over the first insulator. In each of the first and second transistors, a side surface of the semiconductor layer is aligned with a side surface of the first conductor; the semiconductor layer and the first conductor each have an opening; the first insulator is inside the opening; the first insulator has a depressed portion reflecting the shape of the opening; and a second conductor fills the depressed portion. The second conductor of the first transistor, one of a pair of electrodes of the capacitor, and the semiconductor layer of the second transistor are connected to each other.

### BACKGROUND OF THE INVENTION

### 1. Field of the Invention

One embodiment of the present invention relates to a semiconductor device, a memory device, and an electronic device. One embodiment of the present invention relates to a method for manufacturing a semiconductor device. One embodiment of the present invention relates to a semiconductor wafer and a module.

In this specification and the like, a semiconductor device generally means a device that can function by utilizing semiconductor characteristics. A semiconductor element such as a transistor, a semiconductor circuit, an arithmetic device, and a memory device are each an embodiment of a semiconductor device. It can be said that a display device (e.g., a liquid crystal display device and a light-emitting display device), a projection device, a lighting device, an electro-optical device, a power storage device, a memory device, a semiconductor circuit, an imaging device, an electronic device, and the like include a semiconductor device in some cases.

Note that one embodiment of the present invention is not limited to the above technical field. One embodiment of the invention disclosed in this specification and the like relates to an object, a method, or a manufacturing method. Furthermore, one embodiment of the present invention relates to a process, a machine, manufacture, or a composition of matter.

### 2. Description of the Related Art

The reduction in the area occupied by memories is required along with higher integration of memory devices. However, miniaturization of memory devices including Si transistors is becoming difficult in terms of technique and cost.

In recent years, an oxide semiconductor has been attracting attention as a semiconductor material with which a transistor having high resistance to a short-channel effect and having an extremely low off-leakage current can be formed. A technique for forming an OS transistor (a transistor including a metal oxide in a channel formation region) directly on a conventional Si transistor (a transistor including silicon in a channel formation region) (such a technique is also referred to as a back end of line (BEOL)-Tr technique) enables formation of a 3D functional circuit while maintaining the design rule. Thus, this technique has been expected to provide a highly functional memory device with low power consumption at low cost.

Furthermore, if a vertical OS transistor can be used, the design rule can be minimized; specifically, the 4F² design rule can be employed instead of the 6F² design rule (F represents the minimum feature size). For example, Patent Document 1 discloses a vertical transistor in which the side surface of an oxide semiconductor is covered with a word line with a gate insulating layer therebetween.

### REFERENCE

[Patent Document 1] Japanese Published Patent Application No. 2021-108331

### SUMMARY OF THE INVENTION

An object of one embodiment of the present invention is to provide a transistor that can be miniaturized or highly integrated. An object of one embodiment of the present invention is to provide a transistor with favorable electrical characteristics. An object of one embodiment of the present invention is to provide a transistor in which a variation in electrical characteristics is small. An object of one embodiment of the present invention is to provide a transistor having a high on-state current. An object of one embodiment of the present invention is to provide a highly reliable transistor. An object of one embodiment of the present invention is to provide a novel transistor. An object of one embodiment of the present invention is to provide a semiconductor device or memory device including the transistor. An object of one embodiment of the present invention is to provide a semiconductor device or memory device with low power consumption. An object of one embodiment of the present invention is to provide a semiconductor device or memory device that operates at high speed.

Note that the description of these objects does not preclude the existence of other objects. In one embodiment of the present invention, there is no need to achieve all these objects. Other objects will be apparent from and can be derived from the description of the specification, the drawings, the claims, and the like.

One embodiment of the present invention is a semiconductor device including a first transistor, a second transistor, and a capacitor. The first transistor, the capacitor, and the second transistor are stacked in this order. The first transistor and the second transistor each include a semiconductor layer, a first conductor over the semiconductor layer, a first insulator, and a second conductor over the first insulator. In each of the first transistor and the second transistor, a side surface of the semiconductor layer is aligned with a side surface of the first conductor; the semiconductor layer and the first conductor each have an opening; the first insulator is positioned inside the opening; the first insulator has a depressed portion reflecting a shape of the opening; and a second conductor fills the depressed portion. The capacitor includes a third conductor serving as one of a pair of electrodes. The second conductor of the first transistor, the third conductor, and the semiconductor layer of the second transistor are connected to each other.

The above semiconductor device preferably further includes a fourth conductor. The third conductor and the semiconductor layer of the second transistor are preferably connected to each other with the fourth conductor therebetween.

In a plan view of the above semiconductor device, a center of the fourth conductor is preferably shifted from a center of the opening of the semiconductor layer of the second transistor, and the center of the fourth conductor is preferably shifted from a center of the third conductor.

In the above semiconductor device, the capacitor preferably includes a fifth conductor serving as the other of the pair of electrodes, and the fifth conductor preferably has a planar shape.

In the above semiconductor device, the fifth conductor preferably includes a first region facing the third conductor with a dielectric of the capacitor therebetween and a second region not overlapping with the first transistor, and a width of the first region is preferably equal to a thickness of the second region.

One embodiment of the present invention is a semiconductor device including a first transistor, a second transistor, and a capacitor. The first transistor, the capacitor, and the second transistor are stacked in this order. The first transistor and the second transistor each include a semiconductor layer, a first conductor over the semiconductor layer, a first insulator, and a second conductor over the first insulator. In each of the first transistor and the second transistor, a side surface of the semiconductor layer is aligned with a side surface of the first conductor; the semiconductor layer and the first conductor each have an opening; the first insulator is positioned inside the opening; the first insulator has a depressed portion reflecting a shape of the opening; and a second conductor fills the depressed portion. The second conductor of the first transistor includes a region serving as one of a pair of electrodes of the capacitor. The second conductor of the first transistor and the semiconductor layer of the second transistor are connected to each other.

The above semiconductor device preferably further includes a third conductor. The second conductor of the first transistor and the semiconductor layer of the second transistor are preferably connected to each other with the third conductor therebetween.

In a plan view of the above semiconductor device, a center of the third conductor is preferably shifted from a center of the opening of the semiconductor layer of the second transistor, and the center of the third conductor is preferably shifted from a center of the second conductor of the first transistor.

In the above semiconductor device, the capacitor preferably includes a fourth conductor serving as the other of the pair of electrodes, and the fourth conductor preferably has a planar shape.

In the above semiconductor device, the second conductor of the first transistor preferably includes a first region facing the semiconductor layer of the first transistor with the first insulator of the first transistor therebetween and a second region above the other of the pair of electrodes of the capacitor and in contact with a bottom surface of the semiconductor layer of the second transistor. The first region preferably has a first width. The second region preferably has a second width larger than the first width.

In a cross-sectional view of the above semiconductor device, a side surface of the semiconductor layer on an opening side preferably has a tapered shape.

In the above semiconductor device, the semiconductor layer preferably includes a first metal oxide, a second metal oxide over the first metal oxide, and a third metal oxide over the second metal oxide.

In the above semiconductor device, the second metal oxide preferably contains indium and one or more selected from zinc, gallium, aluminum, and tin.

Another embodiment of the present invention is a memory device including a driver circuit and any one of the above semiconductor devices. The driver circuit and the semiconductor device are provided to overlap with each other. A peripheral circuit included in the driver circuit has a function of writing and reading data to/from the semiconductor device.

One embodiment of the present invention can provide a transistor that can be miniaturized or highly integrated. One embodiment of the present invention can provide a transistor with favorable electrical characteristics. One embodiment of the present invention can provide a transistor in which a variation in electrical characteristics is small. One embodiment of the present invention can provide a transistor having a high on-state current. One embodiment of the present invention can provide a highly reliable transistor. One embodiment of the present invention can provide a novel transistor. One embodiment of the present invention can provide a semiconductor device or memory device including the transistor. One embodiment of the present invention can provide a semiconductor device or memory device with low power consumption. One embodiment of the present invention can provide a semiconductor device or memory device that operates at high speed.

Note that the description of these effects does not preclude the existence of other effects. One embodiment of the present invention does not necessarily achieve all these effects. Other effects will be apparent from and can be derived from the description of the specification, the drawings, the claims, and the like.

### BRIEF DESCRIPTION OF THE DRAWINGS

In the accompanying drawings:

FIG. 1A is a perspective view illustrating a structure example of a semiconductor device, and FIG. 1B is a circuit diagram illustrating a structure example of the semiconductor device;

FIG. 2A is a perspective view illustrating a structure example of a semiconductor device, and FIGS. 2B to 2F are cross-sectional views illustrating the structure example of the semiconductor device;

FIG. 3A is a perspective view illustrating a structure example of a semiconductor device, and FIGS. 3B and 3C are cross-sectional views illustrating the structure example of the semiconductor device;

FIG. 4A is a perspective view illustrating a structure example of a semiconductor device, and FIGS. 4B to 4D are cross-sectional views illustrating the structure example of the semiconductor device;

FIGS. 5A and 5B are cross-sectional views illustrating a structure example of a semiconductor device, and FIG. 5C is a plan view illustrating the structure example of the semiconductor device;

FIG. 6A is a perspective view illustrating a structure example of a semiconductor device, FIGS. 6B and 6C are cross-sectional views illustrating the structure example of the semiconductor device, and FIG. 6D is a plan view illustrating the structure example of the semiconductor device;

FIGS. 7A and 7B are cross-sectional views illustrating a structure example of a semiconductor device, and FIG. 7C is a plan view illustrating the structure example of the semiconductor device;

FIG. 8A is a perspective view illustrating a structure example of a semiconductor device, FIGS. 8B and 8C are cross-sectional views illustrating the structure example of the semiconductor device, and FIG. 8D is a plan view illustrating the structure example of the semiconductor device;

FIG. 9 is a perspective view illustrating a structure example of a semiconductor device;

FIG. 10A is a perspective view illustrating a structure example of a semiconductor device, and FIGS. 10B and 10C are cross-sectional views illustrating the structure example of the semiconductor device;

FIG. 11 is a perspective view illustrating a structure example of a semiconductor device;

FIG. 12A is a perspective view illustrating a structure example of a semiconductor device, and FIGS. 12B and 12C are cross-sectional views illustrating the structure example of the semiconductor device;

FIGS. 13A and 13B are cross-sectional views illustrating a structure example of a semiconductor device;

FIG. 14A is a perspective view illustrating a structure example of a semiconductor device, and FIGS. 14B and 14C are cross-sectional views illustrating the structure example of the semiconductor device;

FIG. 15A is a perspective view illustrating a structure example of a semiconductor device, FIGS. 15B and 15C are cross-sectional views illustrating the structure example of the semiconductor device, and FIG. 15D is a plan view illustrating the structure example of the semiconductor device;

FIG. 16A is a perspective view illustrating a structure example of a semiconductor device, and FIGS. 16B and 16C are cross-sectional views illustrating the structure example of the semiconductor device;

FIG. 17A is a perspective view illustrating a structure example of a semiconductor device, FIGS. 17B and 17C are cross-sectional views illustrating the structure example of the semiconductor device, and FIG. 17D is a plan view illustrating the structure example of the semiconductor device;

FIG. 18A is a perspective view illustrating a structure example of a semiconductor device, and FIGS. 18B and 18C are cross-sectional views illustrating the structure example of the semiconductor device;

FIGS. 19A and 19B are cross-sectional views illustrating structure examples of a semiconductor device;

FIGS. 20A and 20B are cross-sectional views illustrating structure examples of a semiconductor device;

FIGS. 21A and 21B are cross-sectional views illustrating structure examples of a semiconductor device;

FIG. 22A is a plan view illustrating a structure example of a semiconductor device, and FIGS. 22B and 22C are cross-sectional views illustrating the structure example of the semiconductor device;

FIGS. 23A to 23C are cross-sectional views illustrating a structure example of a semiconductor device, and FIG. 23D is a plan view illustrating the structure example of the semiconductor device;

FIG. 24A is a plan view illustrating an example of a method for manufacturing a semiconductor device, and FIGS. 24B and 24C are cross-sectional views illustrating the example of the method for manufacturing the semiconductor device;

FIG. 25A is a plan view illustrating an example of a method for manufacturing a semiconductor device, and FIGS. 25B and 25C are cross-sectional views illustrating the example of the method for manufacturing the semiconductor device;

FIG. 26A is a plan view illustrating an example of a method for manufacturing a semiconductor device, and FIGS. 26B and 26C are cross-sectional views illustrating the example of the method for manufacturing the semiconductor device;

FIG. 27A is a plan view illustrating an example of a method for manufacturing a semiconductor device, and FIGS. 27B and 27C are cross-sectional views illustrating the example of the method for manufacturing the semiconductor device;

FIG. 28A is a plan view illustrating an example of a method for manufacturing a semiconductor device, and FIGS. 28B and 28C are cross-sectional views illustrating the example of the method for manufacturing the semiconductor device;

FIG. 29A is a plan view illustrating an example of a method for manufacturing a semiconductor device, and FIGS. 29B and 29C are cross-sectional views illustrating the example of the method for manufacturing the semiconductor device;

FIG. 30A is a plan view illustrating an example of a method for manufacturing a semiconductor device, and FIGS. 30B and 30C are cross-sectional views illustrating the example of the method for manufacturing the semiconductor device;

FIG. 31A is a plan view illustrating an example of a method for manufacturing a semiconductor device, and FIGS. 31B and 31C are cross-sectional views illustrating the example of the method for manufacturing the semiconductor device;

FIG. 32A is a plan view illustrating an example of a method for manufacturing a semiconductor device, and FIGS. 32B and 32C are cross-sectional views illustrating the example of the method for manufacturing the semiconductor device;

FIG. 33A is a plan view illustrating an example of a method for manufacturing a semiconductor device, and FIGS. 33B and 33C are cross-sectional views illustrating the example of the method for manufacturing the semiconductor device;

FIG. 34A is a plan view illustrating an example of a method for manufacturing a semiconductor device, and FIGS. 34B and 34C are cross-sectional views illustrating the example of the method for manufacturing the semiconductor device;

FIG. 35A is a plan view illustrating an example of a method for manufacturing a semiconductor device, and FIGS. 35B and 35C are cross-sectional views illustrating the example of the method for manufacturing the semiconductor device;

FIG. 36A is a plan view illustrating an example of a method for manufacturing a semiconductor device, and FIGS. 36B and 36C are cross-sectional views illustrating the example of the method for manufacturing the semiconductor device;

FIG. 37A is a plan view illustrating an example of a method for manufacturing a semiconductor device, and FIGS. 37B and 37C are cross-sectional views illustrating the example of the method for manufacturing the semiconductor device;

FIG. 38A is a plan view illustrating an example of a method for manufacturing a semiconductor device, and FIGS. 38B and 38C are cross-sectional views illustrating the example of the method for manufacturing the semiconductor device;

FIG. 39A is a plan view illustrating an example of a method for manufacturing a semiconductor device, and FIGS. 39B and 39C are cross-sectional views illustrating the example of the method for manufacturing the semiconductor device;

FIG. 40A is a plan view illustrating an example of a method for manufacturing a semiconductor device, and FIGS. 40B and 40C are cross-sectional views illustrating the example of the method for manufacturing the semiconductor device;

FIG. 41A is a plan view illustrating an example of a method for manufacturing a semiconductor device, and FIGS. 41B and 41C are cross-sectional views illustrating the example of the method for manufacturing the semiconductor device;

FIG. 42A is a plan view illustrating an example of a method for manufacturing a semiconductor device, and FIGS. 42B and 42C are cross-sectional views illustrating the example of the method for manufacturing the semiconductor device;

FIG. 43A is a plan view illustrating an example of a method for manufacturing a semiconductor device, and FIGS. 43B and 43C are cross-sectional views illustrating the example of the method for manufacturing the semiconductor device;

FIG. 44A is a plan view illustrating an example of a method for manufacturing a semiconductor device, and FIGS. 44B and 44C are cross-sectional views illustrating the example of the method for manufacturing the semiconductor device;

FIG. 45A is a plan view illustrating a structure example of a semiconductor device, and FIGS. 45B and 45C are cross-sectional views illustrating the structure example of the semiconductor device;

FIG. 46A is a plan view illustrating a structure example of a semiconductor device, and FIGS. 46B and 46C are cross-sectional views illustrating the structure example of the semiconductor device;

FIG. 47A is a plan view illustrating an example of a method for manufacturing a semiconductor device, and FIGS. 47B and 47C are cross-sectional views illustrating the example of the method for manufacturing the semiconductor device;

FIG. 48A is a plan view illustrating an example of a method for manufacturing a semiconductor device, and FIGS. 48B and 48C are cross-sectional views illustrating the example of the method for manufacturing the semiconductor device;

FIG. 49A is a plan view illustrating a structure example of a semiconductor device, and FIGS. 49B and 49C are cross-sectional views illustrating the structure example of the semiconductor device;

FIG. 50A is a plan view illustrating an example of a method for manufacturing a semiconductor device, and FIGS. 50B and 50C are cross-sectional views illustrating the example of the method for manufacturing the semiconductor device;

FIG. 51A is a plan view illustrating an example of a method for manufacturing a semiconductor device, and FIGS. 51B and 51C are cross-sectional views illustrating the example of the method for manufacturing the semiconductor device;

FIG. 52A is a plan view illustrating an example of a method for manufacturing a semiconductor device, and FIGS. 52B and 52C are cross-sectional views illustrating the example of the method for manufacturing the semiconductor device;

FIG. 53A is a plan view illustrating an example of a method for manufacturing a semiconductor device, and FIGS. 53B and 53C are cross-sectional views illustrating the example of the method for manufacturing the semiconductor device;

FIG. 54A is a plan view illustrating a structure example of a semiconductor device, and FIGS. 54B and 54C are cross-sectional views illustrating the structure example of the semiconductor device;

FIG. 55A is a plan view illustrating a structure example of a semiconductor device, and FIGS. 55B and 55C are cross-sectional views illustrating the structure example of the semiconductor device;

FIG. 56A is a plan view illustrating a structure example of a semiconductor device, and FIGS. 56B and 56C are cross-sectional views illustrating the structure example of the semiconductor device;

FIG. 57A is a plan view illustrating an example of a method for manufacturing a semiconductor device, and FIGS. 57B and 57C are cross-sectional views illustrating the example of the method for manufacturing the semiconductor device;

FIG. 58A is a plan view illustrating an example of a method for manufacturing a semiconductor device, and FIGS. 58B and 58C are cross-sectional views illustrating the example of the method for manufacturing the semiconductor device;

FIG. 59A is a plan view illustrating an example of a method for manufacturing a semiconductor device, and FIGS. 59B and 59C are cross-sectional views illustrating the example of the method for manufacturing the semiconductor device;

FIG. 60A is a plan view illustrating an example of a method for manufacturing a semiconductor device, and FIGS. 60B and 60C are cross-sectional views illustrating the example of the method for manufacturing the semiconductor device;

FIG. 61A is a plan view illustrating an example of a method for manufacturing a semiconductor device, and FIGS. 61B and 61C are cross-sectional views illustrating the example of the method for manufacturing the semiconductor device;

FIG. 62A is a plan view illustrating an example of a method for manufacturing a semiconductor device, and FIGS. 62B and 62C are cross-sectional views illustrating the example of the method for manufacturing the semiconductor device;

FIG. 63A is a plan view illustrating a structure example of a semiconductor device, and FIGS. 63B and 63C are cross-sectional views illustrating the structure example of the semiconductor device;

FIG. 64 is a block diagram illustrating a structure example of a semiconductor device;

FIGS. 65A to 65H illustrate circuit configuration examples of memory cells;

FIGS. 66A and 66B are perspective views illustrating structure examples of a semiconductor device;

FIG. 67 is a block diagram illustrating a central processing unit (CPU);

FIGS. 68A and 68B are perspective views of a semiconductor device;

FIGS. 69A and 69B are perspective views of a semiconductor device;

FIGS. 70A and 70B illustrate hierarchies of various kinds of memory devices;

FIGS. 71A and 71B illustrate examples of electronic components;

FIGS. 72A and 72B illustrate examples of electronic devices, and FIGS. 72C to 72E illustrate an example of a large computer;

FIG. 73 illustrates an example of space equipment; and

FIG. 74 illustrates an example of a storage system that can be used for a data center.

### DETAILED DESCRIPTION OF THE INVENTION

Embodiments will be described below with reference to the drawings. Note that the embodiments can be implemented with various modes, and it will be readily appreciated by those skilled in the art that modes and details can be changed in various ways without departing from the spirit and scope of the present invention. Thus, the present invention should not be interpreted as being limited to the following description of the embodiments.

In the drawings, the size, the layer thickness, or the region is exaggerated for clarity in some cases. Therefore, the size, the layer thickness, or the region is not limited to the illustrated scale. Note that the drawings are schematic views of ideal examples, and shapes or values are not limited to those illustrated in the drawings. For example, in the actual manufacturing process, a layer, a resist mask, or the like might be unintentionally reduced in size by treatment such as etching, which is not illustrated in some cases for easy understanding. In the drawings, the same portions or portions having similar functions are denoted by the same reference numerals in different drawings, and explanation thereof will not be repeated in some cases. The same hatching pattern is used for portions having similar functions, and the portions are not denoted by specific reference numerals in some cases.

Moreover, some components may be omitted particularly in a perspective view, a plan view, or the like for easy understanding of the invention. In addition, some hidden lines or the like may be omitted. In the drawings, for example, a hatching pattern or the like may be omitted. Furthermore, a hatching pattern for one component may be different between a plan view and a cross-sectional view.

The ordinal numbers such as “first” and “second” in this specification and the like are used for convenience and do not denote the order of steps or the stacking order of layers. Therefore, for example, description can be made even when “first” is replaced with “second”, “third”, or the like as appropriate. In addition, the ordinal numbers in this specification and the like are not necessarily the same as those used to specify one embodiment of the present invention.

In this specification and the like, the terms for describing arrangement, such as “over”, “above”, “under”, and “below”, are used for convenience to describe a positional relation between components with reference to drawings. The positional relation between components is changed as appropriate in accordance with the direction from which each component is described. Thus, the positional relation is not limited to that described with a term used in the specification and can be explained with other terms as appropriate depending on the situation.

For example, when this specification and the like explicitly state that X and Y are connected, the case where X and Y are electrically connected, the case where X and Y are functionally connected, and the case where X and Y are directly connected are regarded as being disclosed in this specification and the like. Accordingly, without being limited to a predetermined connection relation, for example, a connection relation shown in drawings or texts, a connection relation other than one shown in drawings or texts is regarded as being disclosed in the drawings or the texts. Here, X and Y each denote an object (e.g., a device, an element, a circuit, a wiring, an electrode, a terminal, a conductive film, or a layer).

In this specification and the like, a transistor is an element including at least three terminals of a gate, a drain, and a source. The transistor includes a region where a channel is formed (hereinafter also referred to as a channel formation region) between the drain (a drain terminal, a drain region, or a drain electrode) and the source (a source terminal, a source region, or a source electrode), and a current can flow between the source and the drain through the channel formation region. Note that in this specification and the like, a channel formation region refers to a region through which a current mainly flows.

The functions of a source and a drain are sometimes replaced with each other when a transistor of different polarity is used or when the direction of current flow is changed in circuit operation, for example. Thus, in some cases, the terms “source” and “drain” can be used interchangeably in this specification and the like.

An impurity in a semiconductor refers to, for example, elements other than the main components of the semiconductor. For example, an element with a concentration lower than 0.1 atomic % is regarded as an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as Vo) in an oxide semiconductor, for example.

Note that in this specification and the like, an oxynitride refers to a material that contains more oxygen than nitrogen, and a nitride oxide refers to a material that contains more nitrogen than oxygen. For example, silicon oxynitride refers to a material that contains more oxygen than nitrogen, and silicon nitride oxide refers to a material that contains more nitrogen than oxygen.

In this specification and the like, the term “insulator” can be replaced with an insulating film or an insulating layer. The term “conductor” can be replaced with a conductive film or a conductive layer. The term “oxide” can be replaced with an oxide film or an oxide layer.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 60° and less than or equal to 120°.

In this specification and the like, a metal oxide means an oxide of metal in a broad sense. Metal oxides are classified into an oxide insulator, an oxide conductor (including a transparent oxide conductor), an oxide semiconductor (also simply referred to as an OS), and the like. For example, in the case where a metal oxide is used in a semiconductor layer of a transistor, the metal oxide is referred to as an oxide semiconductor in some cases. That is, an OS transistor is a transistor including a metal oxide or an oxide semiconductor.

In this specification and the like, when a plurality of components denoted by the same reference numerals need to be distinguished from each other, identification signs such as “[n]” and “[m,n]” are sometimes added to the reference numerals.

In this specification and the like, the expression “level with” indicates a structure having the same level from a reference surface (e.g., a flat surface such as a substrate surface) in a cross-sectional view. For example, in a manufacturing process of a semiconductor device, planarization treatment (typically, chemical mechanical polishing (CMP) treatment) is performed, whereby the surface(s) of a single layer or a plurality of layers may be exposed. In this case, the surfaces on which the CMP treatment is performed are at the same level from a reference surface. Note that a plurality of layers may be on different levels depending on a treatment apparatus, a treatment method, or a material of the treated surfaces, used for the CMP treatment. This case is also included in the scope of “level with” in this specification and the like. For example, the expression “level with” also includes the case where two layers (here, a first layer and a second layer) have different two levels with respect to a reference surface and the difference in the top-surface level between the first and second layers is less than or equal to 20 nm.

In this specification and the like, the expression “an end portion is aligned with another end portion” indicates that at least outlines of stacked layers partly overlap with each other in a plan view. For example, the case of patterning or partly patterning an upper layer and a lower layer with the use of the same mask pattern is included. The expression “an end portion is aligned with another end portion” also includes the case where the outlines do not completely overlap with each other; for instance, the outline of the upper layer may be positioned inward or outward from the outline of the lower layer.

In general, it is difficult to clearly differentiate “completely aligned” from “substantially aligned”. Thus, in this specification and the like, the expression “aligned” includes both “completely aligned” and “substantially aligned”.

Note that in this specification and the like, the expression “a first thickness and a second thickness are equal to each other” indicates that a value obtained by dividing the absolute value of a difference between the first thickness and the second thickness by the first thickness or the second thickness is 0.1 or less.

### Embodiment 1

In this embodiment, a semiconductor device of one embodiment of the present invention and a method for manufacturing the semiconductor device will be described with reference to drawings.

One embodiment of the present invention relates to a semiconductor device in which a memory layer is provided over a substrate. The memory layer includes a first transistor, a second transistor, and a capacitor, which can form a memory cell. The semiconductor device of one embodiment of the present invention includes the memory cell, i.e., includes the first transistor, the second transistor, and the capacitor. The semiconductor device of one embodiment of the present invention includes the memory cell and thus has a function of storing data. Therefore, the semiconductor device of one embodiment of the present invention can be referred to as a memory device.

In the case where the memory cell is formed using the first transistor, the second transistor, and the capacitor, the first transistor and the second transistor function as a read transistor and a write transistor, respectively.

The semiconductor device of one embodiment of the present invention preferably includes a transistor including a metal oxide (also referred to as an oxide semiconductor) in a channel formation region (such a transistor is also referred to as an OS transistor). An OS transistor has a low off-state current. Thus, by including an OS transistor, the semiconductor device capable of serving as a memory device can retain stored contents for a long time. In other words, such a semiconductor device does not require refresh operation or has an extremely low frequency of refresh operation, leading to a sufficient reduction in power consumption. Therefore, a semiconductor device with low power consumption can be provided. An OS transistor has high frequency characteristics and thus the semiconductor device can perform data reading and data writing at high speed. Thus, a semiconductor device that operates at high speed can be provided.

An OS transistor has high resistance to a short-channel effect. Accordingly, as compared with a transistor including silicon in a channel formation region (also referred to as a Si transistor), an OS transistor is hardly affected by a substrate floating effect even with a vertical structure, and can easily have a short channel length even with a thick gate insulating film. That is, a gate leakage current can be reduced, so that the memory device can have improved retention characteristics.

The short-channel effect refers to degradation of electrical characteristics that becomes obvious along with miniaturization (a decrease in channel length) of a transistor. Examples of the short-channel effect include drain-induced barrier lowering, electron velocity saturation, and hot-carrier degradation. Specific examples of the short-channel effect include a decrease in threshold voltage, an increase in subthreshold swing value, an increase in leakage current, and the like. Here, the subthreshold swing value means the amount of change in gate voltage in the subthreshold region when the drain voltage keeps constant and the drain current changes by one order of magnitude.

In each of the first and second transistors, one of a source and a drain is positioned below and the other is positioned above; thus, a current flows in the vertical direction. In other words, the channel length direction of each of the first and second transistors is the vertical direction. That is, the first and second transistors are each a transistor having a vertical structure (hereinafter also referred to as a vertical transistor). A vertical transistor can be miniaturized as compared with a transistor having what is called a horizontal structure (hereinafter also referred to as a horizontal transistor) in which a current flows in the horizontal direction. Accordingly, the first and second transistors each having a vertical structure can be arranged at high density and thus the semiconductor device can be highly integrated. In addition, a vertical transistor can have a larger channel width per unit area than a horizontal transistor. Thus, the density of a current flowing through the transistor is increased, the on-state current of the transistor is increased, and the frequency characteristics can be improved.

The first transistor, the capacitor, and the second transistor are stacked in this order. Such a structure does not require a wiring for connecting the first transistor and the second transistor, so that the number of steps in the manufacturing process of the semiconductor device can be reduced and the productivity can be improved. Moreover, a region for a wiring for connecting the first transistor and the second transistor is not required, so that the semiconductor device can be highly integrated.

The channel length of the vertical transistor included in the semiconductor device of one embodiment of the present invention can be controlled by the thickness of an oxide semiconductor, so that a processing variation in the channel length can be smaller than that of a horizontal transistor. That is, a variation in the density of a current flowing through the transistor can be suppressed. Consequently, the frequency characteristics can be improved.

### <Structure Example of Semiconductor Device>

A structure example of the semiconductor device of one embodiment of the present invention is described below. Note that components of the semiconductor device of this embodiment may each have either a single-layer structure or a stacked-layer structure.

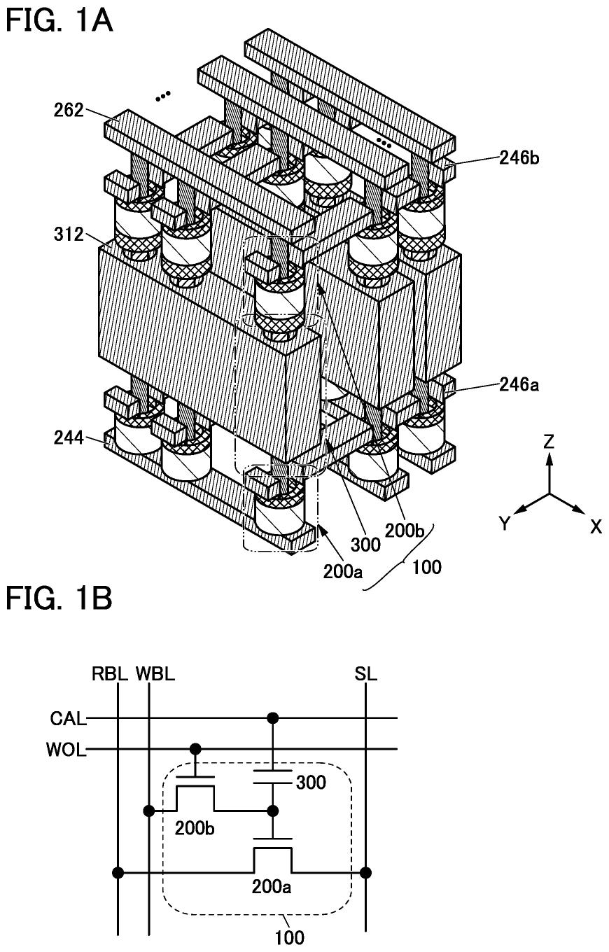

FIG. 1A is a perspective view illustrating a structure example of the semiconductor device of one embodiment of the present invention.

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The semiconductor device of one embodiment of the present invention includes a plurality of memory cells 100. FIG. 1A illustrates an example in which the plurality of memory cells 100 of the semiconductor device are arranged in a matrix. The memory cells 100 are arranged in a matrix, whereby a memory cell array can be formed. The semiconductor device includes a conductor 244, a conductor 312, a conductor 262, a conductor 246a, and a conductor 246b. These conductors function as wirings.

The memory cell 100 includes a transistor 200a, a transistor 200b, and a capacitor 300. The memory cell 100 is electrically connected to the conductors 244, 312, 262, 246a, and 246b.

The conductors 244, 312, 262, 246a, and 246b are each preferably formed using a conductive material containing tungsten, copper, or aluminum as its main component. One or more of the conductors 244, 312, 262, 246a, and 246b may have a stacked-layer structure, e.g., a stacked-layer structure of titanium or titanium nitride and any of the above conductive materials or a stacked-layer structure of tantalum or tantalum nitride and any of the above conductive materials.

The semiconductor device of one embodiment of the present invention can be used as a memory device. FIG. 1B is a circuit diagram of the semiconductor device used as a memory device. The semiconductor device can be rephrased as a memory device including the memory cell 100.

As illustrated in FIG. 1B, in the transistor 200a, a gate is electrically connected to one of a pair of electrodes of the capacitor 300, one of a source and a drain is electrically connected to a wiring SL, and the other of the source and the drain is electrically connected to a wiring RBL. In the transistor 200b, a gate is electrically connected to a wiring WOL, one of a source and a drain is electrically connected to the one of the pair of electrodes of the capacitor 300, and the other of the source and the drain is electrically connected to a wiring WBL. The other of the pair of electrodes of the capacitor 300 is electrically connected to a wiring CAL.

The wiring WOL functions as a write word line, the wiring WBL functions as a write bit line, the wiring RBL functions as a read bit line, the wiring SL functions as a selection line, and the wiring CAL functions as a capacitor line.

The wiring WOL corresponds to the conductor 262, the wiring WBL corresponds to the conductor 246b, the wiring RBL corresponds to one of the conductor 246a and the conductor 244, the wiring SL corresponds to the other of the conductor 246a and the conductor 244, and the wiring CAL corresponds to the conductor 312. That is, the conductor 262 includes a region functioning as a write word line, the conductor 246b includes a region functioning as a write bit line, the one of the conductor 246a and the conductor 244 includes a region functioning as a read bit line, the other of the conductor 246a and the conductor 244 includes a region functioning as a selection line, and the conductor 312 includes a region functioning as a capacitor line.

Note that the memory cell 100 of the semiconductor device does not necessarily include the transistor 200a in some cases. For example, the memory cell 100 may include the transistor 200b and the capacitor 300. In this case, the semiconductor device is provided with a plurality of memory cells each including one transistor and one capacitor, and the semiconductor device can be used as a memory device.

The memory device including the memory cell will be described in detail in a later embodiment.

### [Memory Cell 100]

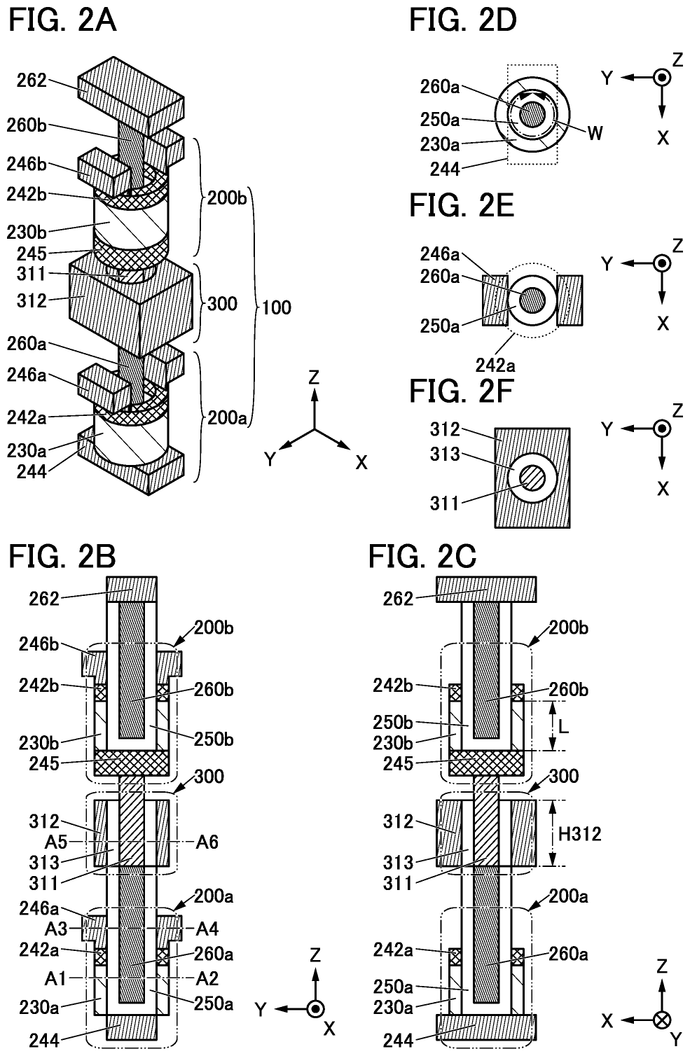

FIGS. 2A to 2F are a perspective view and cross-sectional views illustrating a structure example of the memory cell of the semiconductor device of one embodiment of the present invention. FIG. 2A is the perspective view of a region including the memory cell 100. FIGS. 2B to 2F are the cross-sectional views of the region including the memory cell 100.

The memory cell 100 illustrated in FIGS. 2A to 2F includes the transistor 200a, the capacitor 300 over the transistor 200a, and the transistor 200b over the capacitor 300. By stacking the transistor 200a, the transistor 200b, and the capacitor 300, the area occupied by the memory cell 100 can be reduced and the memory density can be improved. The memory cell 100 includes a conductor 245.

In the memory cell 100, the gate of the transistor 200a, one of the pair of electrodes of the capacitor 300, and one of the source and the drain of the transistor 200b are electrically connected to each other. In FIGS. 2A to 2C, a gate electrode of the transistor 200a, the one of the pair of electrodes of the capacitor 300, and one of a source region and a drain region of the transistor 200b are connected to each other. The one of the pair of electrodes of the capacitor 300 and the one of the source region and the drain region of the transistor 200b are connected to each other through the conductor 245. Specifically, the gate electrode of the transistor 200a includes a region in contact with the one of the pair of electrodes of the capacitor 300, the one of the pair of electrodes of the capacitor 300 includes a region in contact with the conductor 245, and the conductor 245 includes a region in contact with the one of the source region and the drain region of the transistor 200b.

The transistor 200a includes an oxide 230a, a conductor 242a over the oxide 230a, an insulator 250a, and a conductor 260a over the insulator 250a. The oxide 230a includes a region in contact with the top surface of the conductor 244. The conductor 242a includes a region in contact with the bottom surface of the conductor 246a.

The transistor 200b includes an oxide 230b, a conductor 242b over the oxide 230b, an insulator 250b, and a conductor 260b over the insulator 250b. The oxide 230b includes a region in contact with the top surface of the conductor 245. The conductor 242b includes a region in contact with the bottom surface of the conductor 246b. The conductor 260b includes a region in contact with the bottom surface of the conductor 262.

The capacitor 300 includes a conductor 311, an insulator 313, and the conductor 312. For easy understanding of an overall view of the memory cell 100, the length (height) of the conductor 312 illustrated in FIGS. 2A to 2C is shorter (smaller) than that of the conductor 312 in the Z direction illustrated in FIG. 1A.

The conductor 311 includes a region in contact with the top surface of the conductor 260a and a region in contact with the bottom surface of the conductor 245.

Note that in the structure illustrated in FIGS. 2A to 2C, the transistors 200a and 200b are stacked and thus may have different structures. For example, one of the transistor 200a and the transistor 200b may be a planar transistor, a staggered transistor, or an inverted staggered transistor. Alternatively, one of the transistor 200a and the transistor 200b may be either a top-gate transistor or a bottom-gate transistor. Further alternatively, one of the transistor 200a and the transistor 200b may be a transistor in which gates are provided above and below a semiconductor layer where a channel is formed.

Hereinafter, as for components that are distinguished from each other using letters of the alphabet, matters common to the components are sometimes described using reference numerals excluding the letters of the alphabet. For example, matters common to the transistors 200a and 200b are sometimes described using the term “transistor 200”.

### [Transistor 200]

As described above, the transistor 200 includes the oxide 230, the conductor 242 over the oxide 230, the insulator 250, and the conductor 260 over the insulator 250.

Here, FIG. 2D is the cross-sectional view taken along the XY plane including the oxide 230a. FIG. 2D also illustrates a cross section taken along the dashed-dotted line A1-A2 in FIG. 2B. Note that FIG. 2D can be referred to for a cross-sectional view taken along the XY plane including the oxide 230b. In FIG. 2D, the outline of the conductor 244 is indicated by a dotted line for easy understanding.

As illustrated in FIGS. 2B to 2D, the oxide 230 and the conductor 242 each have a cylindrical shape (also referred to as a circular column shape). The cylindrical shape of each of the oxide 230 and the conductor 242 extends in the Z direction. The oxide 230 and the conductor 242 each have an opening. The opening of each of the oxide 230 and the conductor 242 is sometimes referred to as an opening portion, a hollow, a hollow portion, or the like. The opening of the oxide 230 and the opening of the conductor 242 overlap with each other. The top surfaces of the oxide 230 and the conductor 242 each have a hollow circular shape. In other words, the oxide 230 and the conductor 242 each have a cylindrical shape provided with a hollow portion. Note that a cylindrical shape provided with a hollow portion is sometimes referred to as a hollow cylindrical shape. The side surface of the oxide 230 is aligned with the side surface of the conductor 242. Specifically, the side surface of the oxide 230 on the opening side is aligned with the side surface of the conductor 242 on the opening side, and the outer side surface of the oxide 230 is aligned with the outer side surface of the conductor 242.

Note that in this specification and the like, the expression “two side surfaces are aligned with each other” refers to the case where two side surfaces flush with each other and the case where two side surfaces are level with or substantially level with each other.

Note that in this specification and the like, a top surface shape of a component means the outline of the component in the plan view. A plan view means that the component is observed from a normal direction of a surface where the component is formed or from a normal direction of a surface of a support (e.g., a substrate) where the component is formed.

Although FIG. 2D illustrates the structure in which the top surfaces of the oxide 230 and the conductor 242 each have a hollow circular shape, the present invention is not limited thereto. The top surfaces of the oxide 230 and the conductor 242 may each have a hollow elliptical shape, a hollow polygonal shape, or a hollow polygonal shape with rounded corners, for example. The polygonal shape here means a triangle, a quadrangle, a pentagon, a hexagon, and the like.

The insulator 250 and the conductor 260 are placed inside the openings of the oxide 230 and the conductor 242. The insulator 250 has a depressed portion reflecting the shapes of the openings. The conductor 260 is provided to fill the depressed portion. The insulator 250 includes a region in contact with the side surface of the oxide 230 on the opening side, a region in contact with the side surface of the conductor 242 on the opening side, a region in contact with the top surface of the conductor 244 or the conductor 245, a region in contact with the side surface of the conductor 260, and a region in contact with the bottom surface of the conductor 260.

In the transistor 200, the conductor 260 functions as a gate electrode, and the insulator 250 functions as a gate insulator. Note that the gate insulator is also referred to as a gate insulating layer or a gate insulating film in some cases. At least part of a region of the oxide 230 opposite to the conductor 260 with the insulator 250 therebetween functions as a channel formation region.

The conductor 244 functions as one of a source electrode and a drain electrode of the transistor 200a, and the conductor 242a functions as the other of the source electrode and the drain electrode of the transistor 200a. The conductor 245 functions as one of a source electrode and a drain electrode of the transistor 200b, and the conductor 242b functions as the other of the source electrode and the drain electrode of the transistor 200b.

The transistor 200 is a vertical transistor. The transistor 200 has a structure in which the channel formation region surrounds the gate electrode. Thus, the transistor 200 can be referred to as a transistor having a channel-all-around (CAA) structure.

Note that the channel length of the transistor 200 refers to the distance between the source and the drain in a region where a semiconductor (or a portion where a current flows in a semiconductor when the transistor is on) and the gate electrode overlap with each other or in a region where a channel is formed in a cross-sectional view. That is, the channel length of the transistor 200 corresponds to the thickness (the distance from the bottom surface to the top surface) of the oxide 230. Thus, since the channel length of the transistor 200 can be adjusted by the thickness of the oxide 230, the transistor 200 with a short channel length can be fabricated by reducing the thickness of the oxide 230. When the oxide 230 is deposited by a thin-film deposition method, the channel length of the transistor 200 can be, for example, less than or equal to 30 nm, less than or equal to 20 nm, less than or equal to 15 nm, less than or equal to 10 nm, less than or equal to 8 nm, or less than or equal to 5 nm. That is, the oxide 230 can be formed to a thickness greater than or equal to 3 nm and less than or equal to 30 nm, for example. Since an OS transistor has an extremely low off-state current, the transistor 200 can have a low off-state current even with the above channel length. In FIG. 2C, the channel length (length L) of the transistor 200 is indicated by a dashed-dotted double-headed arrow.

Meanwhile, in the case where a transistor operates in a saturation region, the channel length of the transistor is sometimes lengthened so that its electrical characteristics in the saturation region can be improved. Since the transistor 200 is a vertical transistor, the area occupied by the transistor 200 in a plan view does not depend on the thickness of the oxide 230. Thus, the thickness of the oxide 230 corresponding to the channel length may be large. For example, the thickness of the oxide 230 may be greater than 30 nm and less than or equal to 100 nm.

Accordingly, the thickness of the oxide 230 is greater than or equal to 3 nm and less than or equal to 100 nm, preferably greater than or equal to 3 nm and less than or equal to 30 nm, further preferably greater than or equal to 5 nm and less than or equal to 30 nm, still further preferably greater than or equal to 5 nm and less than or equal to 15 nm.

The channel width of the transistor 200 refers to the length of the channel formation region perpendicular to a channel length direction in a region where a semiconductor (or a portion where a current flows in a semiconductor when the transistor is on) and the gate electrode overlap with each other or in a region where a channel is formed in a plan view. That is, the channel width of the transistor 200 corresponds to the circumference of the hollow in the oxide 230 in a plan view. Note that in one transistor, channel widths in all regions are not necessarily the same. In other words, the channel width of one transistor is not fixed to one value in some cases. Examples of such a case include a case where the side surface of the hollow portion of the oxide 230 has a tapered shape in a cross-sectional view of the transistor as described later. Therefore, in this specification and the like, the channel width is any one of values, the maximum value, the minimum value, or the average value in a channel formation region. In FIG. 2D, the channel width (length W) of the transistor 200 is indicated by a dashed-dotted double-headed arrow.

Note that the values of the channel length and the channel width can be determined by analyzing a cross-sectional transmission electron microscope (TEM) image, for example.

In FIGS. 2A to 2C, the conductors 262, 312, and 244 are provided to extend in the X direction. That is, the conductors 262, 312, and 244 extend in the same direction.

Here, FIG. 2E is the cross-sectional view taken along the XY plane including the conductor 246a. FIG. 2E also illustrates a cross section taken along the dashed-dotted line A3-A4 in FIG. 2B. Note that FIG. 2E can be referred to for a cross-sectional view taken along the XY plane including the conductor 246b. In FIG. 2E, the outline of the conductor 242a is indicated by a dotted line for easy understanding.

As illustrated in FIG. 2E, the conductor 246a is divided in the vicinity of a region overlapping with the conductor 260a. Note that since the conductor 246a includes a region overlapping and in contact with the conductor 242a, the divided conductors 246a are electrically connected to each other through the conductor 242a provided below the conductors 246a. Thus, the conductor 246a can be regarded as extending in the Y direction through the conductor 242a. That is, the conductor 246a can be regarded as extending in the Y direction. Similarly, the conductor 246b can be regarded as extending in the Y direction.

Accordingly, the conductor 244 extends in the direction orthogonal to the direction where the conductor 246a extends. The conductor 262 extends in the direction orthogonal to the direction where the conductor 246b extends.

As described above, the transistor 200 is a vertical transistor. A vertical transistor can be formed at a cross point where wirings with the minimum pitch intersect with each other. Specifically, the transistor 200a is formed in a region between the conductor 244 and the conductor 246a intersecting with each other, and the transistor 200b is formed in a region between the conductor 262 and the conductor 246b intersecting with each other. Thus, the semiconductor device can be miniaturized or highly integrated.

In the transistor 200, a metal oxide functioning as a semiconductor (an oxide semiconductor) is preferably used for the oxide 230 including a channel formation region.

The band gap of the metal oxide functioning as a semiconductor is preferably greater than or equal to 2.0 eV, further preferably greater than or equal to 2.5 eV. The use of such a metal oxide having a wide band gap can reduce the off-state current of the transistor.

As the oxide 230, a metal oxide such as indium oxide, gallium oxide, or zinc oxide is preferably used, for example. Alternatively, as the oxide 230, a metal oxide containing two or three selected from indium, an element M, and zinc is preferably used, for example. Note that the element M is one or more selected from gallium, aluminum, silicon, boron, yttrium, tin, antimony, copper, vanadium, beryllium, titanium, iron, nickel, germanium, zirconium, molybdenum, lanthanum, cerium, neodymium, hafnium, tantalum, tungsten, and magnesium. In particular, the element M is preferably one or more selected from gallium, aluminum, and tin. In this case, the oxide 230 preferably contains indium and one or more selected from zinc, gallium, aluminum, and tin, and further preferably contains indium, zinc, and one or more selected from gallium, aluminum, and tin. Note that a metal oxide containing indium, the element M, and zinc is referred to as In-M-Zn oxide in some cases.

Specifically, as the oxide 230, a metal oxide having an atomic ratio of In:M:Zn=4:2:3 or a neighborhood thereof, In:M:Zn=1:1:1 or a neighborhood thereof, In:M:Zn=1:1:1.2 or a neighborhood thereof, or In:M:Zn=1:1:2 or a neighborhood thereof can be used. Note that the neighborhood of the atomic ratio includes ±30% of an intended atomic ratio.

It is particularly preferable that an oxide containing indium (In), gallium (Ga), and zinc (Zn) (also referred to as IGZO) be used as the oxide 230. Alternatively, an oxide containing indium (In), aluminum (Al), and zinc (Zn) (also referred to as IAZO) may be used as the oxide 230. Alternatively, an oxide containing indium (In), aluminum (Al), gallium (Ga), and zinc (Zn) (also referred to as IAGZO, IGAZO, or AGIZO) may be used as the oxide 230.

Note that in this specification and the like, a metal oxide containing nitrogen is also referred to as a metal oxide in some cases. In addition, a metal oxide containing nitrogen may be referred to as a metal oxynitride.

A vertical transistor including silicon in a channel formation region has unstable electrical characteristics due to a substrate floating effect. Meanwhile, a metal oxide such as IGZO, IAZO, or IAGZO has a large effective mass of a hole. Thus, by using such a metal oxide for a channel formation region, hole accumulation in the channel formation region is reduced, so that a vertical transistor that is less affected or substantially not affected by the substrate floating effect can be fabricated. That is, the use of the above metal oxide as the oxide 230 imparts stable electrical characteristics to the transistor 200. Thus, a transistor having favorable electrical characteristics and a semiconductor device including the transistor can be provided. Moreover, a transistor with a small variation in electrical characteristics and a semiconductor device including the transistor can be provided.

An oxide semiconductor having crystallinity is preferably used for the oxide 230. Examples of an oxide semiconductor having crystallinity include a c-axis aligned crystalline oxide semiconductor (CAAC-OS), a nanocrystalline oxide semiconductor (nc-OS), a polycrystalline oxide semiconductor, and a single-crystal oxide semiconductor. For the oxide 230, the CAAC-OS or the nc-OS is preferably used, and the CAAC-OS is particularly preferably used.

The CAAC-OS is a metal oxide having a dense structure with high crystallinity and a small amount of impurities and defects (e.g., oxygen vacancies). In particular, after the formation of a metal oxide, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. As the density of the CAAC-OS is increased in such a manner, diffusion of impurities or oxygen in the CAAC-OS can be further reduced.

In the CAAC-OS, a reduction in electron mobility due to a crystal grain boundary is less likely to occur because it is difficult to observe a clear crystal grain boundary. Thus, a metal oxide including the CAAC-OS is physically stable. Accordingly, the metal oxide including the CAAC-OS is resistant to heat and has high reliability.

When an oxide having crystallinity, such as the CAAC-OS, is used as the oxide 230, extraction of oxygen from the oxide 230 by the conductors 245, 244, and 242 can be inhibited. In this case, extraction of oxygen from the oxide 230 can be inhibited even when heat treatment is performed; hence, the transistor is stable against high temperatures in the manufacturing process (i.e., thermal budget). In addition, a reduction in the conductivity of the conductors 242, 244, and 245 can be inhibited.

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal (also referred to as a nanocrystal). There is no regularity of crystal orientation between different nanocrystals in the nc-OS, and thus the orientation in the whole film is not observed. That is, in the case where the nc-OS is used as the oxide 230, the oxide 230 has uniform film characteristics regardless of the direction of carriers flowing in the oxide 230; thus, the transistor has stable electrical characteristics.

Note that an oxide semiconductor has any of various structures that show different properties. The oxide 230 may include two or more of the CAAC-OS, the nc-OS, an amorphous-like oxide semiconductor (a-like OS), an amorphous oxide semiconductor, a polycrystalline oxide semiconductor, and a cloud-aligned composite oxide semiconductor (CAC-OS).

When a CAAC-OS film is subjected to structural analysis by out-of-plane XRD measurement with an XRD apparatus using θ/2θ scanning, for example, a peak indicating c-axis alignment is detected at or around 2θ=31°. Note that the position of the peak indicating c-axis alignment (the value of 2θ) may change depending on the kind, composition, or the like of the metal element contained in the CAAC-OS. For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

In some cases, a plurality of spots in a ring-like region with a direct spot as the center are observed in a nanobeam electron diffraction pattern of the nc-OS film obtained using an electron beam with a probe diameter substantially equal to or smaller than the diameter of a nanocrystal (e.g., 1 nm or larger and 30 nm or smaller).

The oxide 230 can be rephrased as a semiconductor layer including the channel formation region of the transistor 200. Note that a material that can be used for the semiconductor layer is not limited to a metal oxide functioning as a semiconductor (an oxide semiconductor).

Other examples of the semiconductor material that can be used for the semiconductor layer include a single-element semiconductor and a compound semiconductor. Examples of the single-element semiconductor include silicon and germanium. Examples of the compound semiconductor include gallium arsenide and silicon germanium. Other examples of the compound semiconductor include an organic semiconductor and a nitride semiconductor. Note that the above-described oxide semiconductor is also one kind of the compound semiconductor. These semiconductor materials may contain an impurity as a dopant.

Examples of silicon that can be used for the semiconductor layer include single crystal silicon, polycrystalline silicon, microcrystalline silicon, and amorphous silicon. An example of polycrystalline silicon is low-temperature polysilicon (LTPS).

A transistor including amorphous silicon in a semiconductor layer can be fabricated at low cost. A transistor including polycrystalline silicon in a semiconductor layer has high field-effect mobility and enables high-speed operation. A transistor including microcrystalline silicon in a semiconductor layer has higher field-effect mobility and enables higher speed operation than the transistor including amorphous silicon.

As the semiconductor layer, a transition metal chalcogenide functioning as a semiconductor may be used. Examples of the transition metal chalcogenide include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

The oxide 230 can be deposited by a sputtering method, a chemical vapor deposition (CVD) method, a molecular beam epitaxy (MBE) method, a pulsed laser deposition (PLD) method, an atomic layer deposition (ALD) method, or the like. In particular, a sputtering method is preferably employed for deposition of the oxide 230. By employing a sputtering method, a metal oxide having crystallinity can be formed. In addition, a sputtering method enables deposition of a thin film, and thus can be suitably employed for deposition of the oxide 230.

In the case where the transistor 200a and the transistor 200b are stacked as illustrated in FIGS. 2A to 2C, the oxide 230a and the oxide 230b can have different thicknesses. In other words, the transistor 200a and the transistor 200b can have different channel lengths.

An increase in the channel length of the transistor can reduce a variation in the threshold voltage of the transistor. Thus, the thickness of the oxide 230a is made larger than that of the oxide 230b, for example. In this case, the transistor 200a functioning as a read transistor has a long channel length, so that a memory cell that allows highly accurate reading can be provided.

The shorter the channel length of a transistor is, the lower the on-state resistance becomes; thus, the transistor is capable of high-speed operation. Thus, the thickness of the oxide 230b is made smaller than that of the oxide 230a, for example. In this case, the transistor 200b functioning as a write transistor has a short channel length, so that a memory cell that allows high-speed writing can be provided. Moreover, when the thickness of the oxide 230a is made large, the transistor 200a functioning as a read transistor has a long channel length, so that a memory cell that allows high-speed writing and highly accurate reading can be provided.

In the structure illustrated in FIGS. 2A to 2C, the semiconductor layers of the transistors 200a and 200b may be formed using the same material or different materials. For example, a semiconductor material different from a metal oxide functioning as a semiconductor is preferably used for the transistor 200a, and the metal oxide functioning as a semiconductor is preferably used for the transistor 200b. A memory cell having such a structure can retain stored contents for a long time and allows high-speed reading.

Here, in what is called a gate-all-around transistor in which the side surface of a metal oxide functioning as a semiconductor is covered with a word line with a gate insulating layer therebetween, the metal oxide is provided inside an opening portion formed in the word line or the gate insulating layer. In order to miniaturize the transistor, an inner wall of the opening portion needs to be as perpendicular as possible to the substrate surface. At this time, the metal oxide to be deposited requires high step coverage, so that there is a limitation on the flexibility of a method for depositing the metal oxide.

Meanwhile, the transistor 200 is formed in such a manner that an opening is formed in a stack of the oxide 230 and the conductor 242, and the insulator 250 and the conductor 260 are formed inside the opening. In this case, the oxide 230 is formed over a flat surface, and thus the oxide 230 to be deposited does not require high step coverage. Thus, any of methods for depositing the oxide 230 can be freely employed. For example, a sputtering method can be employed for depositing the oxide 230, and a metal oxide having crystallinity can be formed.

Note that for formation of the opening or the depressed portion, any of multi-patterning techniques, for example, any of double patterning such as litho-etch-litho-etch (LELE) patterning and self-aligned double patterning (SADP), quadruple patterning such as self-aligned quadruple patterning (SAQP), and octuple patterning such as self-aligned octuple patterning (SAOP) is preferably employed. The multi-patterning technique enables formation of a minute opening or a minute depressed portion.

A shrinking agent may be used for a resist pattern to shrink an opening portion of the resist pattern. For example, a shrinking agent is applied to the surface of a resist, and then heat treatment is performed. Accordingly, the resist reacts with the shrinking agent and a reaction layer is formed on the surface of the resist. At this time, the reaction layer is formed on the side surface of an opening portion of the resist pattern; thus, the opening portion can be made small. With use of the resist pattern having the small opening portion, a minute opening or a minute depressed portion can be formed. Note that the shrinking agent is referred to as a pattern shrinking agent or a hole shrinking agent in some cases.

Alternatively, a fine pattern may be directly formed by light exposure using extreme ultraviolet (EUV) light or the like.

Alternatively, the above methods may be combined for the patterning.

As described above, an oxide semiconductor that is less affected or substantially not affected by the substrate floating effect is deposited by a sputtering method and then multi-patterning is performed with the technique such as SAQP, whereby a cylindrical channel provided with a hollow portion is formed. By providing a gate electrode in the hollow portion, a vertical transistor that can be miniaturized or highly integrated can be provided. With use of the transistor, a memory cell with the minimum feature size (F) less than or equal to 15 nm can be formed, for example. Here, the minimum feature size (F) is, for example, the width of the conductor 244 in the Y direction, the width of the conductor 262 in the Y direction, or the width of the conductor 246 in the X direction.

For the conductor 242, a nitride containing tantalum, a nitride containing titanium, a nitride containing molybdenum, a nitride containing tungsten, a nitride containing tantalum and aluminum, or a nitride containing titanium and aluminum is preferably used, for example. In one embodiment of the present invention, a nitride containing tantalum is particularly preferable. For another example, ruthenium, ruthenium oxide, ruthenium nitride, an oxide containing strontium and ruthenium, or an oxide containing lanthanum and nickel may be used. These materials are preferable because they are conductive materials that are not easily oxidized or materials that maintain their conductivity even after absorbing oxygen.

Note that hydrogen contained in the oxide 230 or the like diffuses into the conductor 242 in some cases. In particular, when a nitride containing tantalum is used for the conductor 242, hydrogen contained in the oxide 230 or the like is likely to diffuse into the conductor 242, and the diffused hydrogen is bonded to nitrogen contained in the conductor 242 in some cases. That is, hydrogen contained in the oxide 230 or the like is sometimes absorbed by the conductor 242.

The conductor 242 includes a region in contact with the oxide 230 and thus is preferably formed using a conductive material containing oxygen. When a conductive material containing oxygen is used for the conductor 242, the conductor 242 can maintain its conductivity even when absorbing oxygen. In addition, also in the case of using an insulator containing oxygen as the insulator 250, the conductor 242 can maintain its conductivity, which is preferable.

Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (a registered trademark)), and indium zinc oxide containing tungsten oxide. Examples of the conductive material containing oxygen also include ruthenium oxide, an oxide containing strontium and ruthenium, and an oxide containing lanthanum and nickel. In this specification and the like, a conductive film deposited using the conductive material containing oxygen may be referred to as an oxide conductive film.

The insulator 250 is preferably formed using an insulator having a function of inhibiting the diffusion of oxygen. Owing to this structure, diffusion of oxygen contained in the oxide 230 into the conductor 260 can be inhibited. That is, formation of oxygen vacancies in the oxide 230 can be inhibited. Moreover, oxidation of the conductor 260 due to oxygen contained in the oxide 230 can be inhibited. Thus, the electrical characteristics and reliability of the transistor 200 can be improved.

An insulator containing oxygen and one or both of aluminum and hafnium is preferably used as the insulator 250, for example. As the insulator, aluminum oxide, hafnium oxide, an oxide containing aluminum and hafnium (hafnium aluminate), an oxide containing hafnium and silicon (hafnium silicate), or the like can be used.

An insulator having a function of capturing or fixing hydrogen is preferably used as the insulator 250. When the insulator 250 provided in contact with the oxide 230 has a function of capturing or fixing hydrogen, the hydrogen concentration in the oxide 230 can be reduced.

Note that a function of capturing or fixing a target substance can also be referred to as a property that does not easily allow diffusion of a target substance. Thus, a function of capturing or fixing a target substance can be rephrased as a barrier property.

Examples of an insulator having a function of capturing or fixing hydrogen include an oxide containing magnesium and an oxide containing one or both of aluminum and hafnium. Examples of the oxide containing one or both of aluminum and hafnium include aluminum oxide, hafnium oxide, and an oxide containing aluminum and hafnium (hafnium aluminate). Silicon oxide may be added to these oxides. Examples of an insulator having a function of capturing or fixing hydrogen include an oxide containing magnesium and silicon, an oxide containing aluminum and silicon, and an oxide containing hafnium and silicon (hafnium silicate).

A high dielectric constant (high-k) material described later may be used for the insulator 250. When a high-k material is used for the insulator 250, the equivalent oxide thickness (EOT) of the insulator functioning as the gate insulator can be reduced. Therefore, the breakdown voltage of the insulator 250 can be increased.

A low dielectric constant material described later may be used for the insulator 250. When a low dielectric constant material is used for the insulator 250, parasitic capacitance generated between the conductor 260 and the conductor 246 can be reduced.

The insulator 250 extends in the Z direction. The top surface of the insulator 250 is preferably positioned above the top surface of the conductor 246. This structure can prevent the conductor 246 and the conductor 260 from being in contact with each other, and can prevent a leakage current and a short circuit between the conductor 246 and the conductor 260. Note that in the case where, over the insulator 250, an insulator is provided between the conductor 246 and the conductor 260 and the top surface of the insulator is positioned above the top surface of the conductor 246, the top surface of the insulator 250 may be positioned below the top surface of the conductor 246.

Although FIGS. 2B to 2E illustrate a single-layer structure of the insulator 250, the present invention is not limited thereto, and a stacked-layer structure of two or more layers may be employed. In the case where the insulator 250 has a two-layer structure, for example, an insulator provided on the oxide 230 side may be formed using an insulator having a function of inhibiting diffusion of oxygen, and an insulator provided on the conductor 260 side may be formed using a high-k material.

For the conductor 260, a nitride containing tantalum, a nitride containing titanium, a nitride containing molybdenum, a nitride containing tungsten, a nitride containing tantalum and aluminum, a nitride containing titanium and aluminum, or ruthenium nitride is preferably used, for example. For another example, ruthenium, ruthenium oxide, an oxide containing strontium and ruthenium, or an oxide containing lanthanum and nickel may be used. These materials are suitable in the case of using an insulating material containing oxygen is used for the insulator 250 in contact with the conductor 260 because they are conductive materials that are not easily oxidized or materials that maintain their conductivity even after absorbing oxygen.

The conductor 260 is preferably formed using a conductive material having a function of inhibiting diffusion of impurities such as hydrogen atoms, hydrogen molecules, water molecules, nitrogen atoms, nitrogen molecules, nitrogen oxide molecules, and copper atoms. Alternatively, the conductor 260 may be formed using a conductive material having a function of inhibiting diffusion of oxygen (e.g., at least one of oxygen atoms, oxygen molecules, and the like). Examples of the conductive material having a function of inhibiting diffusion of oxygen include titanium, titanium nitride, tantalum, tantalum nitride, ruthenium, and ruthenium oxide.

When the conductor 260 has a function of inhibiting diffusion of oxygen, the conductivity of the conductor 260 can be inhibited from being lowered because of oxidation of the conductor 260 due to oxygen contained in the insulator 250. As the conductive material having a function of inhibiting diffusion of oxygen, for example, titanium, titanium nitride, tantalum, tantalum nitride, ruthenium, or ruthenium oxide is preferably used.

The above is the description of the transistor 200.

### [Capacitor 300]

The capacitor 300 includes the conductor 311, the insulator 313, and the conductor 312.

In the capacitor 300, the conductor 311 functions as one of the pair of electrodes, the conductor 312 functions as the other of the pair of electrodes, and the insulator 313 functions as a dielectric.

Here, FIG. 2F is the cross-sectional view taken along the XY plane including the conductor 312. Note that FIG. 2F also illustrates a cross section taken along the dashed-dotted line A5-A6 in FIG. 2B.

It is preferable that the area of a region where the conductor 311 and the conductor 312 face each other with the insulator 313 therebetween be increased (i.e., the distance from the bottom surface to the top surface of each of the conductor 311 and the conductor 312 be increased, or the distance in the Z direction in the region be increased). By increasing the area of the region where the conductor 311 and the conductor 312 face each other with the insulator 313 therebetween, the capacitance of the capacitor 300 can be increased. By increasing the capacitance per unit area in the XY plane of the capacitor 300, data with higher reliability can be read.

Here, the distance from the bottom surface to the top surface of the conductor 312 (the height of the conductor 312 or the thickness of the conductor 312) is referred to as a length H312 (see FIG. 2C). In this case, for example, the length H312 is preferably greater than or equal to the length L, greater than or equal to 2 times the length L (2L), or greater than or equal to 3 times the length L (3L). Note that although there is no particular upper limitation on the length H312, the length H312 is preferably less than or equal to 20 times the length L (20L), less than or equal to 10 times the length L (10L), or less than or equal to 5 times the length L (5L), in terms of an improvement in the productivity of the semiconductor device, for example. Thus, the length H312 is preferably greater than or equal to L and less than or equal to 10L, greater than or equal to 2L and less than or equal to 10L, greater than or equal to 3L and less than or equal to 10L, or greater than or equal to 3L and less than or equal to 5L.

The conductor 311 can be formed using a conductive material that can be used for the conductor 260. The conductor 312 can be formed using a conductive material that can be used for the conductor 244.

A high-k material described later is preferably used for the insulator 313. Using such a high-k material allows the insulator 313 to be thick enough to inhibit a leakage current and a sufficiently high capacitance of the capacitor 300 to be ensured. The insulator 313 is preferably deposited by a deposition method that offers excellent coverage, such as an ALD method or a CVD method.

It is preferable to use stacked insulators each formed of any of the above-described materials. A stacked structure using a high dielectric constant material and a material having higher dielectric strength than the high dielectric constant material is preferably used. For example, as the insulator 313, an insulator in which zirconium oxide, aluminum oxide, and zirconium oxide are stacked in this order can be used. For another example, an insulator in which zirconium oxide, aluminum oxide, zirconium oxide, and aluminum oxide are stacked in this order can be used. For another example, an insulator in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor 300.

Alternatively, a material that can show ferroelectricity may be used for the insulator 313. Examples of the material that can show ferroelectricity include metal oxides such as hafnium oxide, zirconium oxide, and an oxide containing hafnium and zirconium. Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 is preferably, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 is preferably, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a K-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can show ferroelectricity, a mixture or compound containing a plurality of materials selected from the above-listed materials can be used, for example. Alternatively, the insulator 313 can have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

The ferroelectric refers to an insulator having a property of causing internal polarization by application of an electric field from the outside and maintaining the polarization even after the electric field is made zero. Thus, with the use of a capacitor that includes this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 300, the memory device described in this embodiment functions as a ferroelectric memory.

The above is the description of the capacitor 300.

As illustrated in FIG. 2D, in the plan view, the conductor 244 overlaps with the center of the hollow of the oxide 230a. Note that the conductor 244 does not necessarily overlap with the center of the hollow of the oxide 230a in the plan view as long as the conductor 244 is in contact with at least part of the oxide 230a. For example, in the plan view, the conductor 244 may be placed at a position shifted in the Y direction from the center of the hollow of the oxide 230a.

The conductor 262 is preferably in contact with at least part of the conductor 260b. For example, in the plan view, the conductor 262 may be placed so that a bisector of the width of the conductor 262 in the Y direction is aligned with the center of the conductor 260b or the bisector is shifted from the center of the conductor 260b in the Y direction.

As illustrated in FIG. 2B, the conductor 246 may have a protruding portion. The protruding portion is provided in a region where the conductor 246 and the conductor 242 overlap with each other and is in contact with the conductor 242. Note that a method for forming the conductor 246 having the protruding portion will be described later.

FIG. 2B illustrates a structure in which the conductor 246 has the protruding portion. Note that the present invention is not limited thereto as long as the conductor 246 is in contact with at least part of the top surface of the conductor 242.

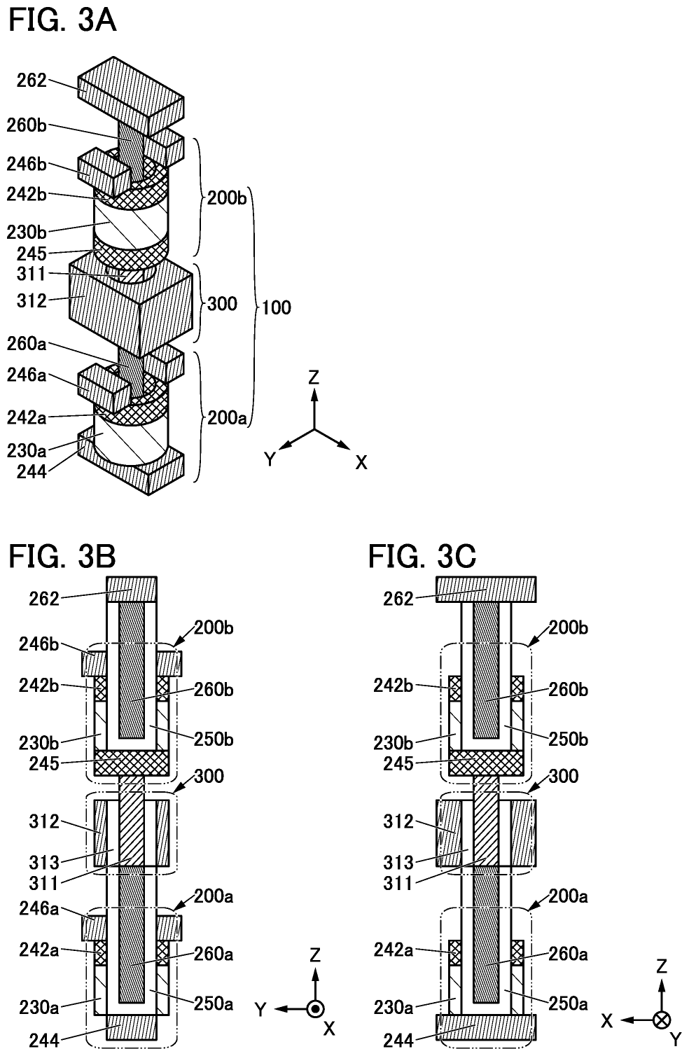

Another example of a structure of a semiconductor device is described with reference to FIGS. 3A to 3C. Note that the semiconductor device illustrated in FIGS. 3A to 3C is a variation example of the semiconductor device illustrated in FIGS. 2A to 2C. FIG. 3A is a perspective view of a region including the memory cell 100. FIGS. 3B and 3C are cross-sectional views of the region including the memory cell 100.

The semiconductor device illustrated in FIGS. 3A to 3C is different from the semiconductor device illustrated in FIGS. 2A to 2C in the shapes of the conductors 246a and 246b. Specifically, the conductor 246 has no protruding portion. In other words, the bottom surface of the conductor 246 is flat from a region not in contact with the conductor 242 to a region in contact with the conductor 242. Even in such a structure, the conductor 246 can be in contact with the conductor 242.

As described above, the conductor 246 is divided in the vicinity of a region overlapping with the conductor 260. Note that the present invention is not limited thereto as long as the conductor 246 is not in contact with the conductor 260.

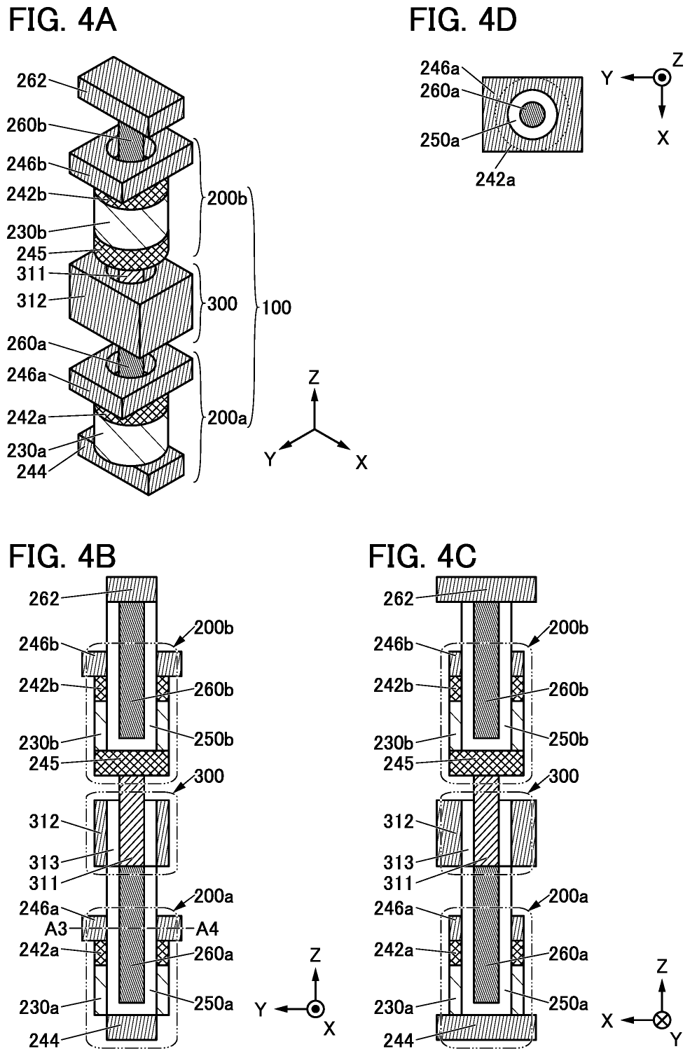

Another example of a structure of a semiconductor device is described with reference to FIGS. 4A to 4D. Note that the semiconductor device illustrated in FIGS. 4A to 4C is a variation example of the semiconductor device illustrated in FIGS. 2A to 2C. FIG. 4A is a perspective view of a region including the memory cell 100. FIGS. 4B and 4C are cross-sectional views of the region including the memory cell 100.

FIG. 4D is the cross-sectional view taken along the XY plane including the conductor 246a. FIG. 4D also illustrates a cross section taken along the dashed-dotted line A3-A4 in FIG. 4B. Note that FIG. 4D can be referred to for a cross-sectional view taken along the XY plane including the conductor 246b. In FIG. 4D, the outline of the conductor 242a is indicated by a dotted line for easy understanding.

The semiconductor device illustrated in FIGS. 4A to 4C is different from the semiconductor device illustrated in FIGS. 2A to 2C in the shapes of the conductors 246a and 246b. Specifically, the conductor 246 is provided to extend in the Y direction as a continuous conductor without being divided. With this structure, the contact area between the conductor 246 and the conductor 242 can be increased, thereby reducing contact resistance and suppressing the generation of problems such as disconnection.

As illustrated in FIG. 4D, the conductor 246 has an opening. The insulator 250 and the conductor 260 are provided inside the opening. Note that when the width of the conductor 246 in the X direction is larger than the diameter of the outer periphery of the insulator 250 in the plan view (see FIG. 4D), the conductor 246 extends in the Y direction as a continuous conductor. In contrast, when the width of the conductor 246 in the X direction is equal to or smaller than the diameter of the outer periphery of the insulator 250 in the plan view, the conductor 246 is divided by the insulator 250. However, as described above, since the divided conductors 246 are electrically connected to each other through the conductor 242, the conductor 246 can be regarded as extending in the Y direction.

FIG. 2E illustrates a structure in which an end portion of a region of the conductor 246 overlapping with the conductor 242 has a linear shape in the plan view. Note that the present invention is not limited thereto. In the plan view, the outline of the conductor 246 overlapping with the conductor 242 and the outer periphery of the insulator 250 may be aligned with each other, for example.

The semiconductor device illustrated in FIGS. 2A to 2C has a structure in which the outline of the conductor 245 and the outer periphery of the oxide 230b are aligned with each other in the plan view. That is, in this structure, the side surface of the conductor 245 and the outer side surface of the oxide 230b are aligned with each other in the cross-sectional view. Moreover, in this structure, the center (center of gravity) of the conductor 245 and the center of the hollow of the oxide 230b overlap with each other and the side surface of the conductor 245 and the outer periphery of the oxide 230b are aligned with each other in the plan view. With this structure, the contact area between the conductor 245 and the oxide 230b can be increased. Accordingly, the transistor 200b can have a higher on-state current and favorable electrical characteristics. Thus, a semiconductor device that operates at high speed can be provided.

Note that the side surface of the conductor 245 and the outer side surface of the oxide 230b are not necessarily aligned with each other in the cross-sectional view as long as the conductor 245 is in contact with at least part of the oxide 230b. In other words, the outline of the conductor 245 and the outer periphery of the oxide 230b are not necessarily aligned with each other in the plan view.

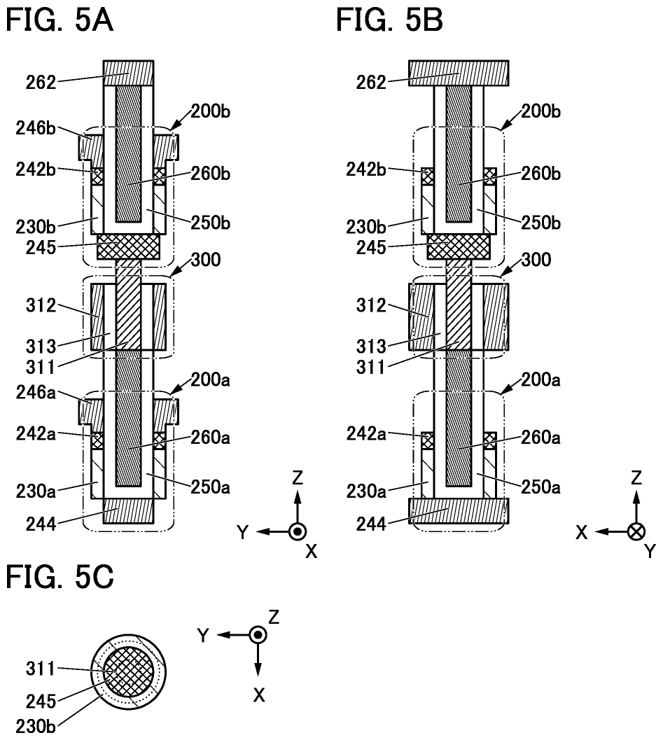

The semiconductor device illustrated in FIGS. 5A and 5B is a variation example of the semiconductor device illustrated in FIGS. 2A to 2C. FIGS. 5A and 5B are cross-sectional views of a region including the memory cell 100. FIG. 5C is a plan view of the region including the memory cell 100. Note that for easy understanding, FIG. 5C illustrates the oxide 230b, the conductor 245, and the conductor 311.

For example, as illustrated in FIGS. 5A and 5B, the side surface of the conductor 245 may be positioned inward from the outer side surface of the oxide 230b in the cross-sectional view. Here, by making the width of the conductor 245 larger than the width of the hollow portion of the oxide 230b (the diameter of the inner periphery of the oxide 230b in the plan view) in the cross-sectional view, the conductor 245 can include a region in contact with the oxide 230b. In other words, as illustrated in FIG. 5C, by making the area of the conductor 245 larger than the area of the hollow portion of the oxide 230b in the plan view, the conductor 245 can include a region in contact with the oxide 230b.

Note that even when the area of the conductor 245 is smaller than the area of the hollow portion of the oxide 230b in the plan view, the conductor 245 can sometimes include a region in contact with the oxide 230b.

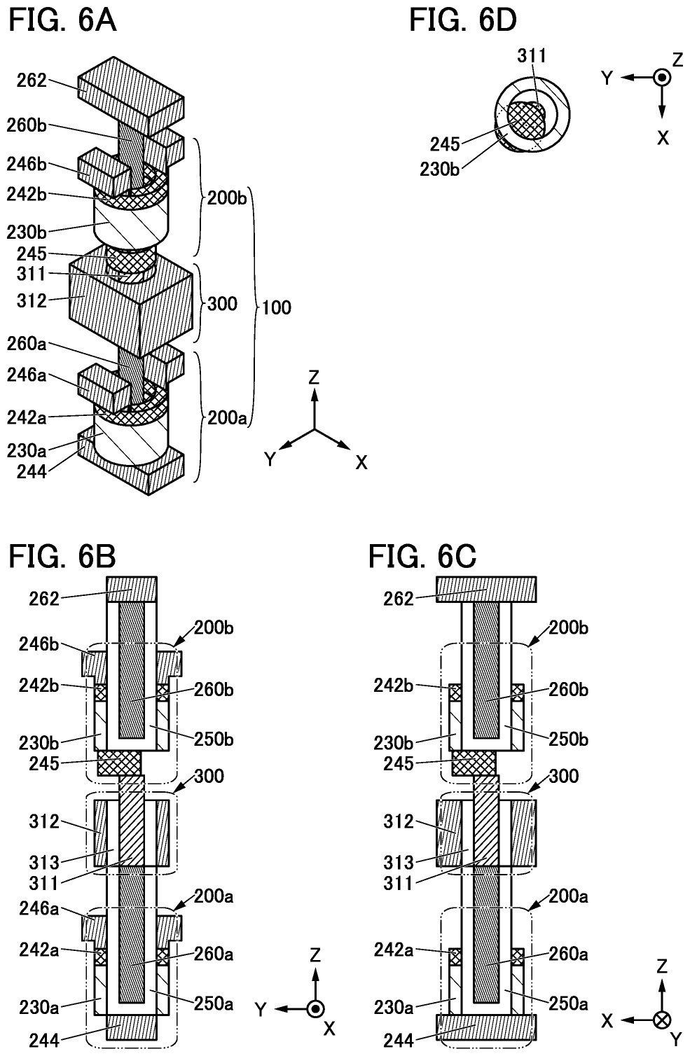

Another example of a structure of a semiconductor device is described with reference to FIGS. 6A to 6D. Note that the semiconductor device illustrated in FIGS. 6A to 6C is a variation example of the semiconductor device illustrated in FIGS. 2A to 2C. FIG. 6A is a perspective view of a region including the memory cell 100. FIGS. 6B and 6C are cross-sectional views of the region including the memory cell 100. FIG. 6D is a plan view of the region including the memory cell 100. Note that for easy understanding, FIG. 6D illustrates the oxide 230b, the conductor 245, and the conductor 311.

As illustrated in FIG. 6D, the conductor 245 may be placed so that the center of the conductor 245 is shifted from the center of the hollow portion of the oxide 230b in the plan view as long as the conductor 245 includes a region overlapping with the oxide 230b. In other words, a structure may be employed in which at least part of the conductor 245 overlaps with the oxide 230b and the center of the conductor 245 is shifted from the center of the hollow portion of the oxide 230b. Alternatively, the conductor 245 may be placed so that the center of the conductor 245 is shifted from the center of the conductor 311 as long as the conductor 245 includes a region overlapping with the conductor 311. In other words, a structure may be employed in which at least part of the conductor 245 overlaps with the conductor 311 and the center of the conductor 245 is shifted from the center of the conductor 311. Accordingly, the conductor 311 and the oxide 230b can be connected to each other.

In this specification and the like, the expression “the center of A is shifted from the center of B” can be rephrased as “the center of A is not aligned with the center of B”, “the center of A does not overlap with the center of B”, or “the center of A is positioned differently from the center of B”.

FIG. 6D illustrates a structure in which the conductor 245 is provided at a position shifted from the center of the hollow portion of the oxide 230b in the X direction and the Y direction. Note that the present invention is not limited thereto. The conductor 245 may be provided at a position shifted from the center of the hollow portion of the oxide 230b in either the X direction or the Y direction.

In the structure illustrated in FIG. 6D, the center of the conductor 311 and the center of the conductor 260a are aligned with each other in the plan view. Note that the present invention is not limited thereto as long as the oxide 230b, the conductor 245, the conductor 311, and the conductor 260a are connected to each other.

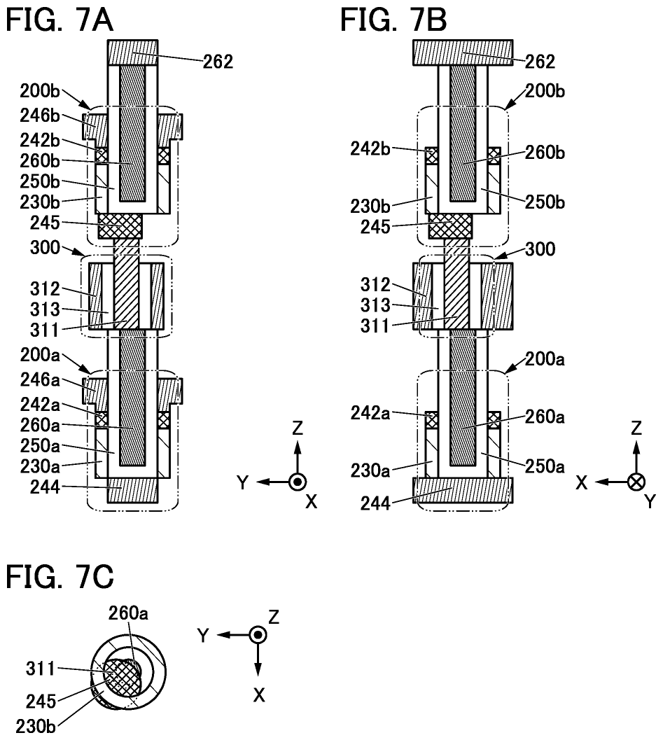

The semiconductor device illustrated in FIGS. 7A and 7B is a variation example of the semiconductor device illustrated in FIGS. 6A to 6C. FIGS. 7A and 7B are cross-sectional views of a region including the memory cell 100. FIG. 7C is a plan view of the region including the memory cell 100. Note that for easy understanding, FIG. 7C illustrates the oxide 230b, the conductor 245, the conductor 311, and the conductor 260a.

As illustrated in FIG. 7C, for example, the conductor 311 may be placed so that the center of the conductor 311 is shifted from the center of the conductor 260a in the plan view as long as the conductor 311 includes a region overlapping with the conductor 260a. In other words, a structure may be employed in which at least part of the conductor 311 overlaps with the conductor 260a and the center of the conductor 311 is shifted from the center of the hollow portion of the conductor 260a.

FIG. 5C illustrates a structure in which the center of the transistor 200a and the center of the transistor 200b are aligned with each other in the plan view. Here, the center of the transistor 200 in the plan view can also be regarded as the center of the conductor 260, the center of the hollow portion of the conductor 242, or the center of the hollow portion of the oxide 230 in the plan view. Note that the present invention is not limited thereto. For example, the center of the transistor 200a and the center of the transistor 200b are not necessarily aligned with each other as long as the transistor 200a, the conductor 311, and the transistor 200b can be electrically connected to each other.

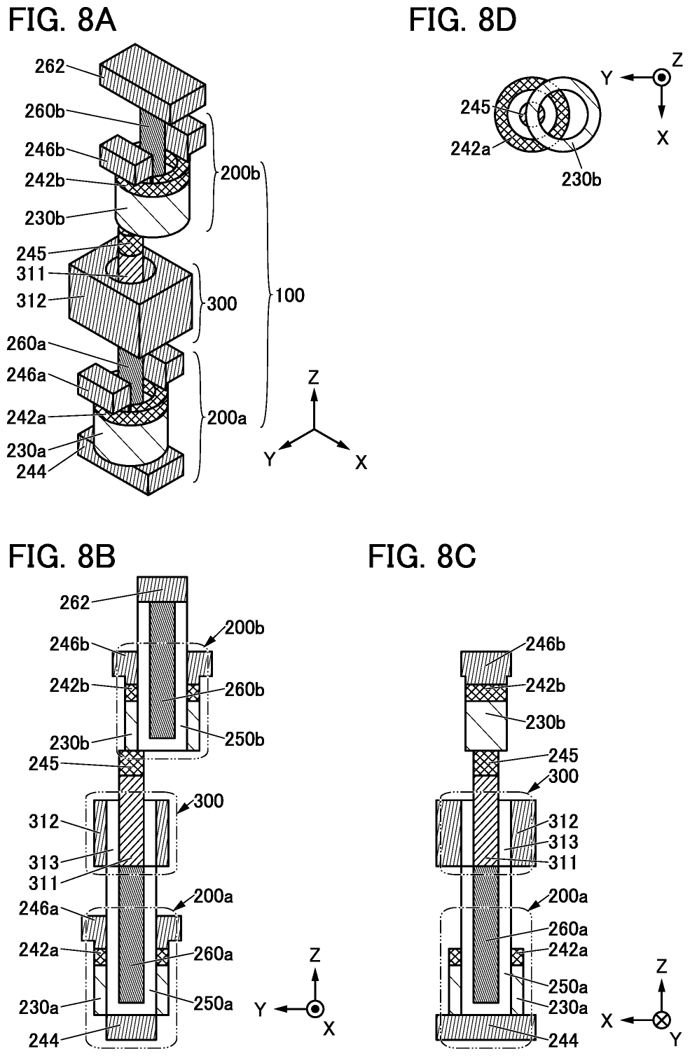

Another example of a structure of a semiconductor device is described with reference to FIGS. 8A to 8D. Note that the semiconductor device illustrated in FIGS. 8A to 8C is a variation example of the semiconductor device illustrated in FIGS. 2A to 2C. FIG. 8A is a perspective view of a region including the memory cell 100. FIGS. 8B and 8C are cross-sectional views of the region including the memory cell 100. FIG. 8D is a plan view of the region including the memory cell 100. Note that for easy understanding, FIG. 8D illustrates the oxide 230b, the conductor 245, and the conductor 242a.

As illustrated in FIG. 8D, even in the case where the area of the conductor 245 is smaller than the area of the hollow portion of the oxide 230b in the plan view, the conductor 311 and the transistor 200b can be electrically connected to each other by shifting the center of the transistor 200a and the center of the transistor 200b from each other. Note that FIG. 8D illustrates a structure in which the transistor 200b is provided at a position shifted from the center of the conductor 245 in the Y direction. Note that the present invention is not limited thereto. The transistor 200b may be provided at a position shifted from the center of the conductor 245 in the X direction or a position shifted from the center of the conductor 245 in the X direction and the Y direction in the plan view.

FIG. 1A illustrates a structure in which the conductor 312 is provided to extend in the X direction. Note that the present invention is not limited thereto. For example, the conductor 312 may be provided to extend in the Y direction or may be provided to have a planar shape.

In this specification and the like, a planar shape refers to the shape of a layer provided as a continuous layer shared by a plurality of elements (e.g., memory cells arranged in a matrix).

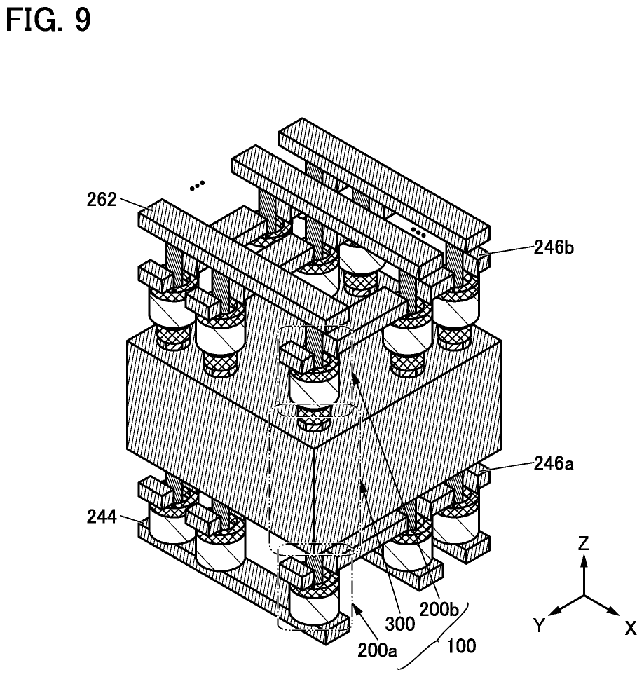

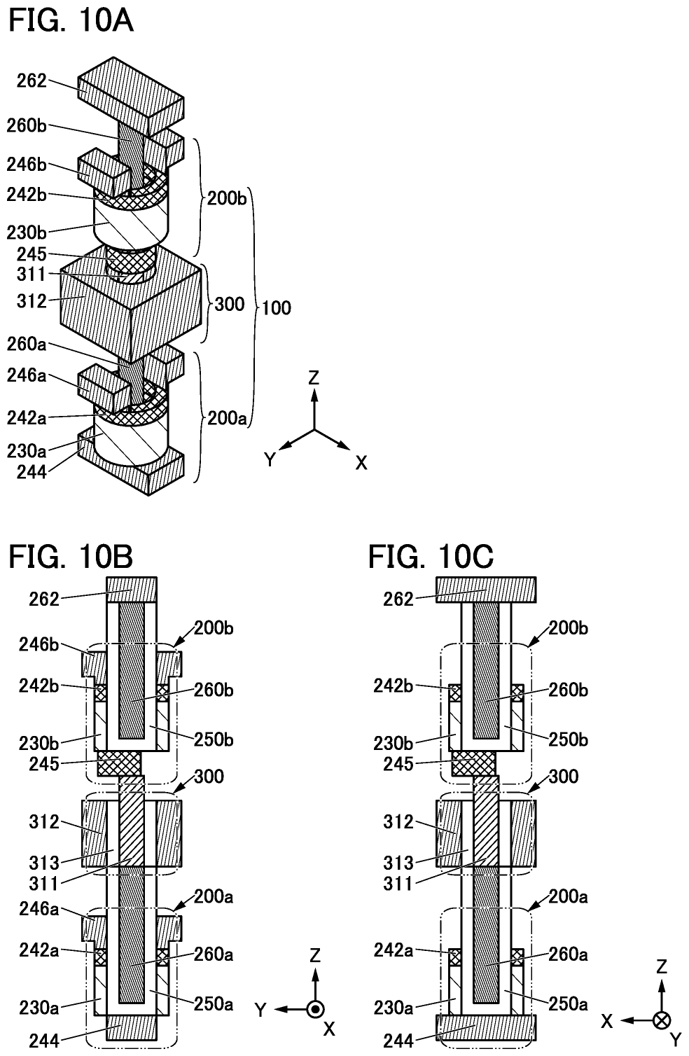

FIG. 9 is a perspective view illustrating a structure example of a semiconductor device in which the conductor 312 is provided to have a planar shape. FIGS. 10A to 10C are a perspective view and cross-sectional views of a region including the memory cell 100 of the semiconductor device illustrated in FIG. 9. FIG. 10A is the perspective view of the region including the memory cell 100. FIGS. 10B and 10C are the cross-sectional views of the region including the memory cell 100. For easy understanding of an overall view of the memory cell 100, the length (height) of the conductor 312 illustrated in FIGS. 10A to 10C is shorter (smaller) than that of the conductor 312 in the Z direction illustrated in FIG. 9.

The semiconductor device illustrated in FIGS. 10A to 10C is a variation example of the semiconductor device illustrated in FIGS. 2A to 2C.

As illustrated in FIG. 9 and FIGS. 10A to 10C, the conductor 312 is provided to have a planar shape. By employing such a structure, a step for processing the shape of the conductor 312 can be omitted, and the manufacturing cost of the semiconductor device can be reduced.

Note that FIG. 9 and FIGS. 10A to 10C illustrate an example in which the thickness of the entire conductor 312 is uniform. Note that the present invention is not limited thereto as long as the capacitance necessary for the capacitor 300 is ensured.

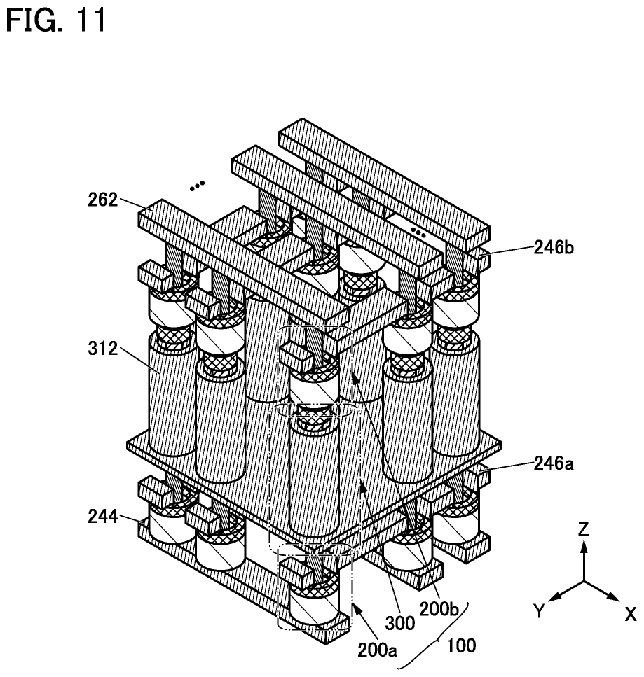

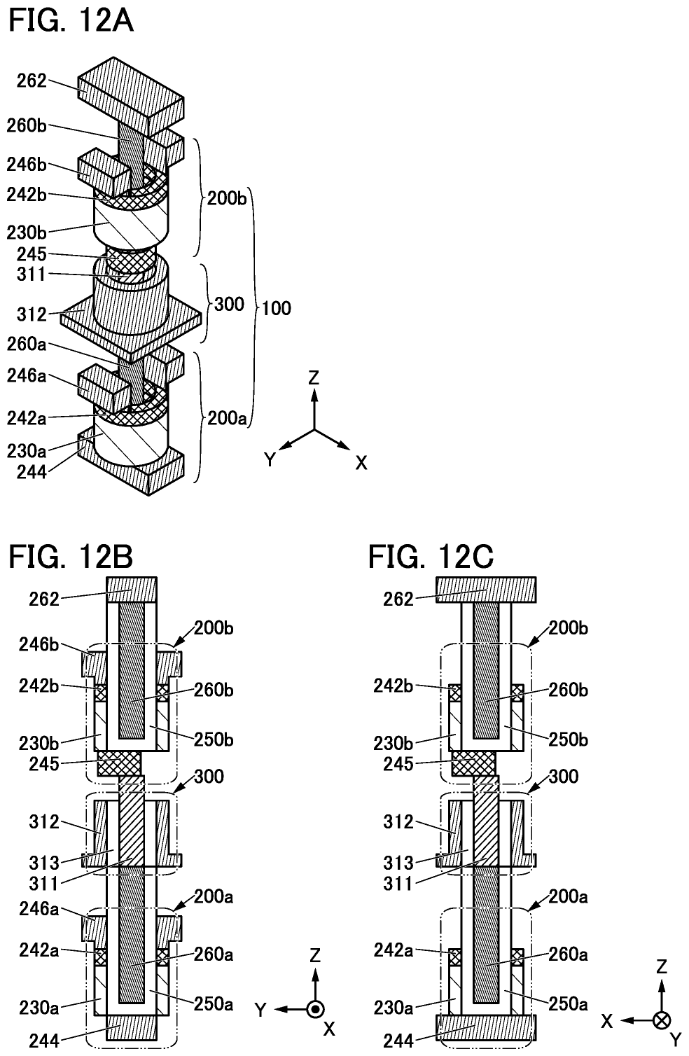

FIG. 11 is a perspective view illustrating another structure example of a semiconductor device of one embodiment of the present invention. FIGS. 12A to 12C are a perspective view and cross-sectional views of a region including the memory cell 100 of the semiconductor device illustrated in FIG. 11. FIG. 12A is the perspective view of the region including the memory cell 100. FIGS. 12B and 12C are the cross-sectional views of the region including the memory cell 100. For easy understanding of an overall view of the memory cell 100, the length (height) of the conductor 312 illustrated in FIGS. 12A to 12C is shorter (smaller) than that of the conductor 312 in the Z direction illustrated in FIG. 11.

The semiconductor device illustrated in FIGS. 12A to 12C is a variation example of the semiconductor device illustrated in FIGS. 10A to 10C.

As illustrated in FIG. 11 and FIGS. 12A to 12C, the conductor 312 is provided to have a planar shape. Note that in the semiconductor device illustrated in FIG. 11 and FIGS. 12A to 12C, the conductor 312 includes a first region facing the conductor 311 with the insulator 313 therebetween and a second region not overlapping with the transistor 200. Furthermore, the width of the first region is equal to the thickness of the second region. With such a structure, even in the case where the area of the region where the conductor 311 and the conductor 312 face each other with the insulator 313 therebetween is increased (i.e., the height of the conductor 311 is increased), it is unnecessary to increase the thickness of the conductor 312. Thus, the deposition time of the conductor 312 can be shortened and the productivity can be improved. Note that a conductor that is electrically connected to the conductor 312 and functions as a wiring may be provided.

A conductive film to be the conductor 312 is preferably deposited by a deposition method that enables favorable coverage, such as an ALD method or a CVD method, after an insulating film to be the insulator 313 is deposited, for example. A method for forming the conductor 312 illustrated in FIGS. 12A to 12C will be described later.

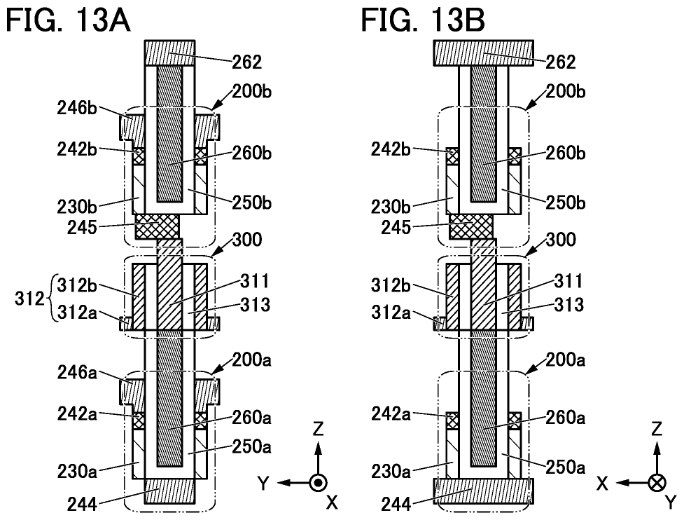

Note that as illustrated in FIGS. 13A and 13B, the conductor 312 may include a conductor 312a and a conductor 312b. The conductor 312a is provided in a region not overlapping with the transistor 200, and the conductor 312b is provided to face the conductor 311 with the insulator 313 therebetween. With such a structure, the thickness of the conductor 312a and the width of the conductor 312 can be made different from each other. For example, since the conductor 312a includes a region functioning as a wiring, the conductivity of the conductor 312a can be increased by increasing the thickness of the conductor 312a.

FIGS. 2A to 2C illustrate a structure in which the conductor 260a is provided as the gate electrode of the transistor 200a and the conductor 311 is provided as one of the pair of electrodes of the capacitor 300. Note that the present invention is not limited thereto. For example, one conductor may have a function of the gate electrode of the transistor 200a and a function of one of the pair of electrodes of the capacitor 300.

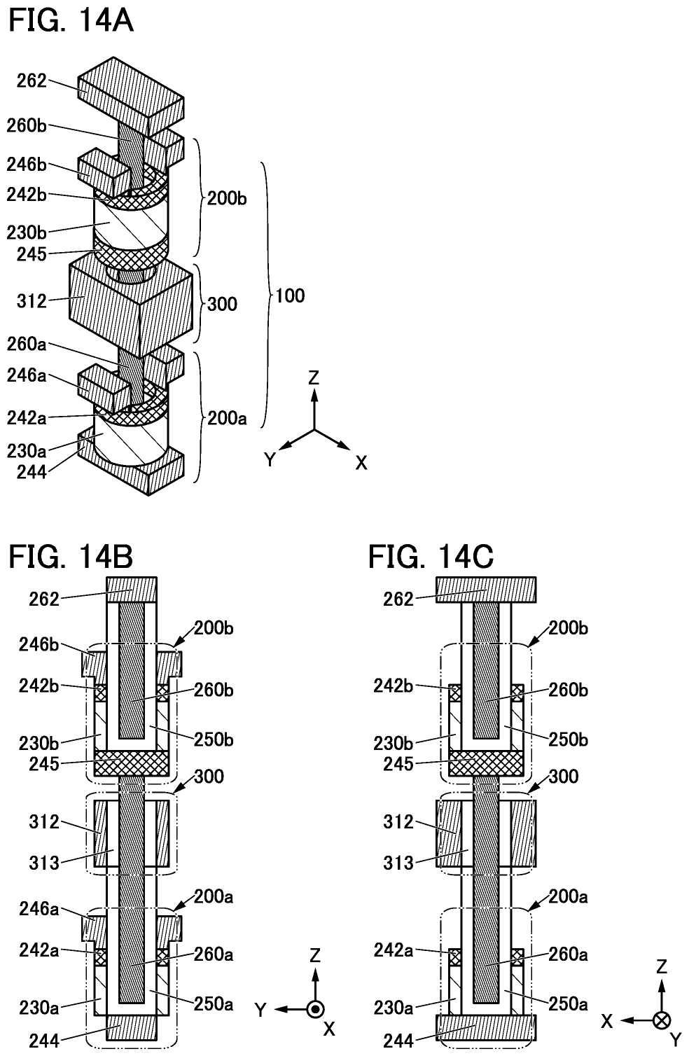

Another example of a structure of a semiconductor device is described with reference to FIGS. 14A to 14C. Note that the semiconductor device illustrated in FIGS. 14A to 14C is a variation example of the semiconductor device illustrated in FIGS. 2A to 2C. FIG. 14A is a perspective view of a region including the memory cell 100. FIGS. 14B and 14C are cross-sectional views of the region including the memory cell 100.

As illustrated in FIGS. 14A to 14C, the conductor 260a may be provided to extend in the Z direction so as to be in contact with the conductor 245. Here, the conductor 260a includes a region facing the conductor 312 with the insulator 313 therebetween. Thus, the conductor 260a includes a region functioning as the gate electrode of the transistor 200a and a region functioning as one of the pair of electrodes of the capacitor 300. With such a structure, a step for forming the conductor 311 can be omitted. Accordingly, a semiconductor device with high productivity can be provided.

Note that the semiconductor device illustrated in FIGS. 14A to 14C may employ the structure described with reference to FIG. 5C, in which the area of the conductor 245 is smaller than the total area of the oxide 230b and the hollow portion of the oxide 230b in the plan view.

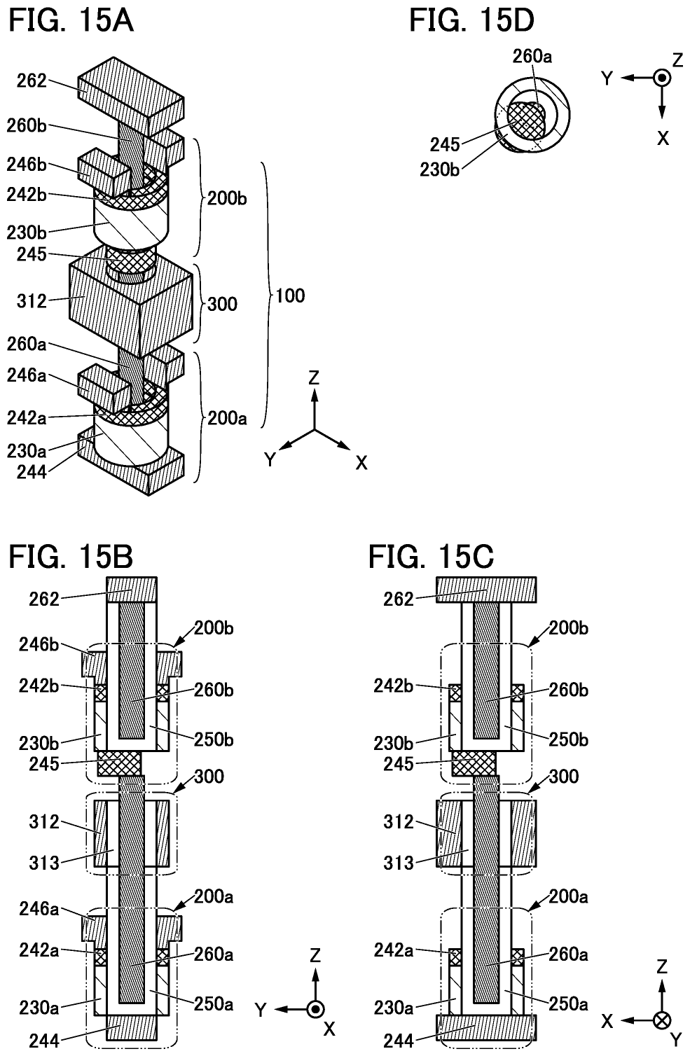

Alternatively, the semiconductor device illustrated in FIGS. 14A to 14C may employ the structure described with reference to FIG. 6D, in which the conductor 245 is placed so that, in the plan view, the center of the conductor 245 is shifted from the center of the hollow portion of the oxide 230b and the center of the conductor functioning as one of the pair of electrodes of the capacitor 300. A semiconductor device illustrated in FIGS. 15A to 15C has a structure in which, in a plan view, the area of the conductor 245 is equal to the area of the hollow portion of the oxide 230b and the center of the conductor 245 is shifted from the center of the hollow portion of the oxide 230b and the center of the transistor 200a. FIG. 15A is a perspective view of a region including the memory cell 100, and FIGS. 15B and 15C are cross-sectional views of the region including the memory cell 100. FIG. 15D is a plan view of the region including the memory cell 100. Note that for easy understanding, FIG. 15D illustrates the oxide 230b, the conductor 245, and the conductor 260a. The semiconductor device illustrated in FIGS. 15A to 15C is a variation example of the semiconductor device illustrated in FIGS. 14A to 14C.

FIGS. 2A to 2C illustrate a structure in which the conductor 311 is provided as one of the pair of electrodes of the capacitor 300 and the conductor 245 is provided as a conductor for electrically connecting one of the pair of electrodes of the capacitor 300 to the transistor 200b. Note that the present invention is not limited thereto. For example, the conductor functioning as one of the pair of electrodes of the capacitor 300 may be electrically connected to the transistor 200b.

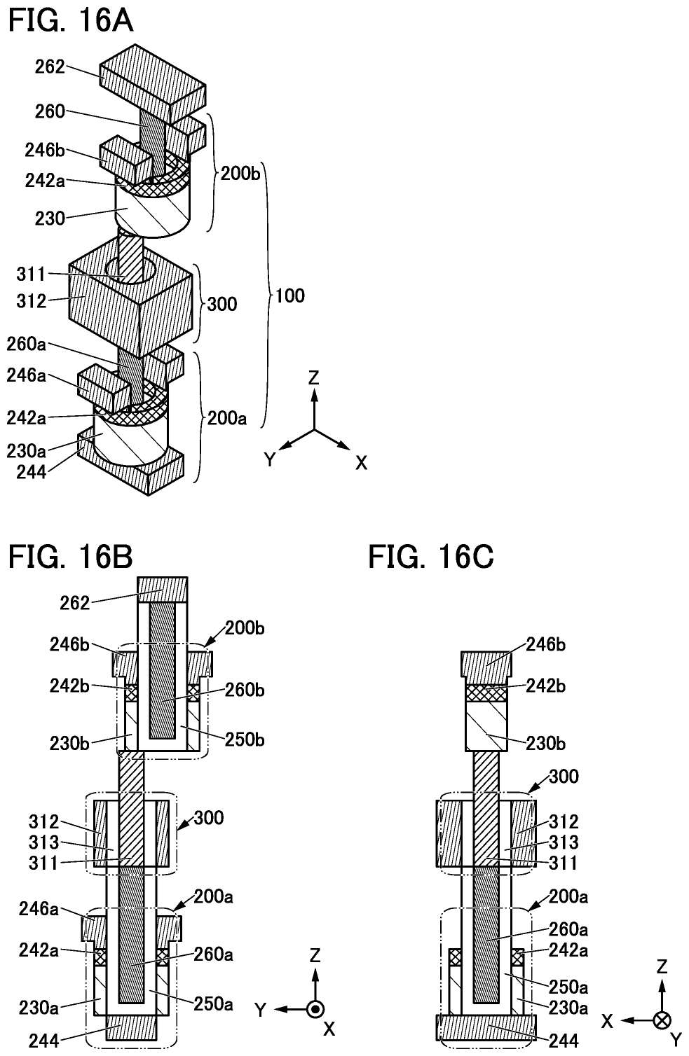

Another example of a structure of a semiconductor device is described with reference to FIGS. 16A to 16C. Note that the semiconductor device illustrated in FIGS. 16A to 16C is a variation example of the semiconductor device illustrated in FIGS. 8A to 8C. FIG. 16A is a perspective view of a region including the memory cell 100. FIGS. 16B and 16C are cross-sectional views of the region including the memory cell 100.

As illustrated in FIGS. 16A to 16C, the conductor 311 may be provided to extend in the Z direction so as to be in contact with the oxide 230b. Thus, the conductor 311 includes a region functioning as one of the pair of electrodes of the capacitor 300 and is electrically connected to the transistor 200b. With such a structure, a step for forming the conductor 245 can be omitted. Accordingly, a semiconductor device with high productivity can be provided.

Note that the conductor 312 has an opening in which the insulator 313 and the conductor 311 are provided. In the case where the conductor 312 is provided to extend in the X direction, the diameter of the opening needs to be smaller than the width of the conductor 312 in the Y direction. Here, the area of the conductor 311 in the plan view also needs to be small. In view of the above, the center of the transistor 200a and the center of the transistor 200b are preferably shifted from each other in the structure illustrated in FIGS. 16A to 16C.

As described with reference to FIG. 9 and FIGS. 10A to 10C, in the case where the conductor 312 is provided to have a planar shape, the area of the conductor 311 in the plan view can be increased.

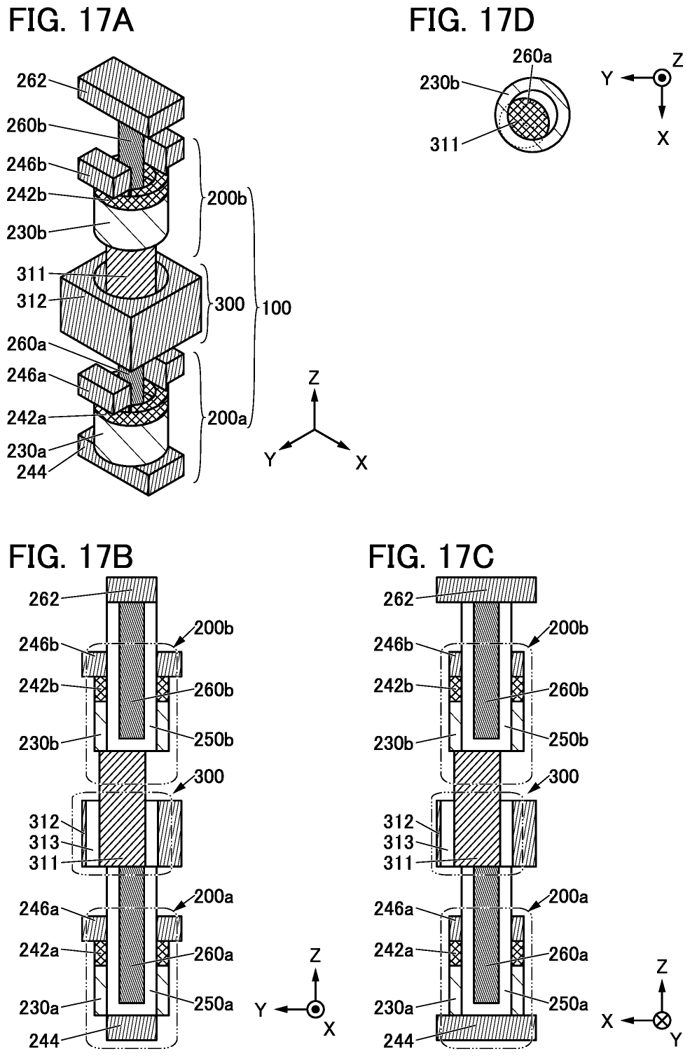

Another example of a structure of a semiconductor device is described with reference to FIGS. 17A to 17D. Note that the semiconductor device illustrated in FIGS. 17A to 17C is a variation example of the semiconductor device illustrated in FIGS. 10A to 10C. FIG. 17A is a perspective view of a region including the memory cell 100. FIGS. 17B and 17C are cross-sectional views of the region including the memory cell 100. FIG. 17D is a plan view of the region including the memory cell 100. Note that for easy understanding, FIG. 17D illustrates the conductor 260a, the conductor 311, and the oxide 230b.

As illustrated in FIG. 17D, in the plan view, the area of the conductor 311 is preferably larger than the area of the conductor 260a. Furthermore, in the plan view, the conductor 311 is preferably placed so that the center of the conductor 311 is shifted from the center of the transistor 200a. With such a structure, the conductor 260a, the conductor 311, and the oxide 230b can be connected to each other without shifting the center of the transistor 200a and the center of the transistor 200b from each other. By increasing the area of the conductor 311 in the plan view, the alignment of a mask used for forming the oxide 230b is relaxed, so that a minute memory cell can be easily fabricated. By increasing the area of the conductor 311 in the plan view, the capacitance of the capacitor 300 can be increased. Alternatively, by increasing the area of the conductor 311 in the plan view, the area of the region where the conductor 311 and the conductor 312 face each other with the insulator 313 therebetween in the cross-sectional view can be reduced without reducing the capacitance of the capacitor 300. Thus, the thickness of the conductor 312 can be reduced, and the deposition time can be shortened.

Note that in the plan view, the area of the conductor 311 is preferably smaller than the total area of the oxide 230b and the hollow portion of the oxide 230b. With such a structure, the distance between the memory cells can be reduced, and high integration of the semiconductor device can be achieved.

FIGS. 2A to 2C illustrate a structure in which the conductor 260a is provided as the gate electrode of the transistor 200a, the conductor 311 is provided as one of the pair of electrodes of the capacitor 300, and the conductor 245 is provided as a conductor for electrically connecting one of the pair of electrodes of the capacitor 300 to the transistor 200b. Note that the present invention is not limited thereto. For example, the conductor having a function of the gate electrode of the transistor 200a and a function of one of the pair of electrodes of the capacitor 300 may be electrically connected to the transistor 200b.

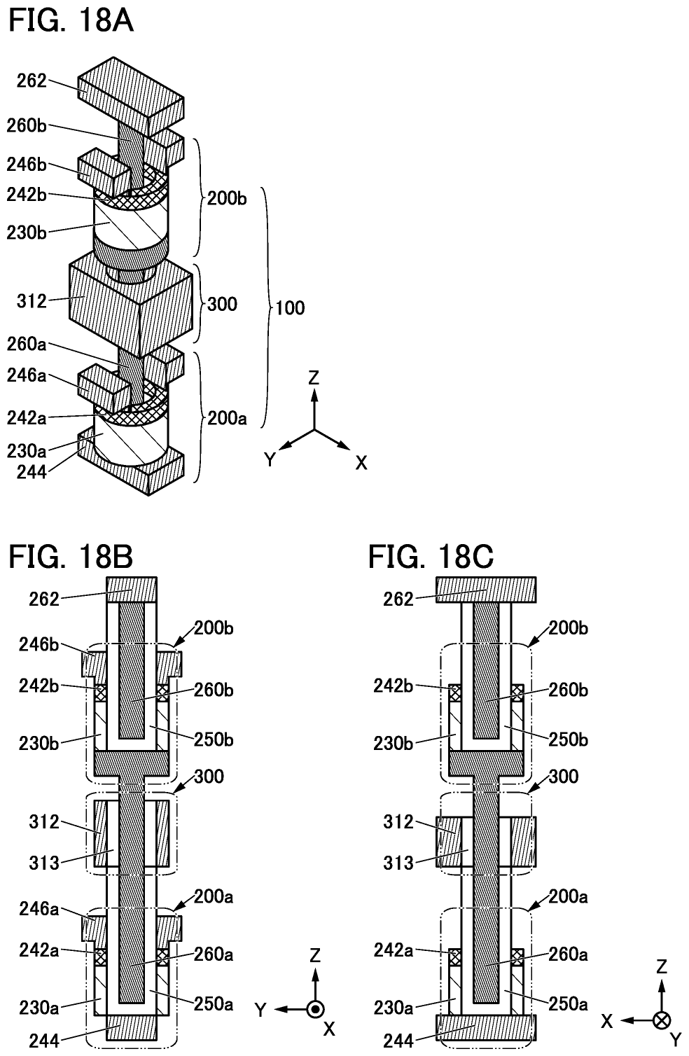

Another example of a structure of a semiconductor device is described with reference to FIGS. 18A to 18C. Note that the semiconductor device illustrated in FIGS. 18A to 18C is a variation example of the semiconductor device illustrated in FIGS. 2A to 2C. FIG. 18A is a perspective view of a region including the memory cell 100. FIGS. 18B and 18C are cross-sectional views of the region including the memory cell 100.

As illustrated in FIGS. 18A to 18C, the conductor 260a may be provided to extend in the Z direction so as to be in contact with the oxide 230b. Here, the conductor 260a includes a region facing the conductor 312 with the insulator 313 therebetween. Thus, the conductor 260a includes a region functioning as the gate electrode of the transistor 200a and a region functioning as one of the pair of electrodes of the capacitor 300, and is electrically connected to the transistor 200b. With such a structure, a step for forming the conductor 311 and the conductor 245 can be omitted. Accordingly, a semiconductor device with high productivity can be provided.

The conductor 260a illustrated in FIGS. 18A to 18C includes a first region and a second region. The first region refers to a region facing the oxide 230a with the insulator 250 therebetween and a region facing the conductor 312 with the insulator 313 therebetween. The second region refers to a region above the conductor 312 and in contact with the bottom surface of the oxide 230b. The first region has a first width and the second region has a second width larger than the first width. With such a structure, the alignment of a mask used for forming the oxide 230b is relaxed, so that a minute memory cell can be easily fabricated.

Note that even part of the conductor 260a that is above the conductor 312 may have the first width. In this case, by shifting the center of the transistor 200a and the center of the transistor 200b from each other, the conductor 260a and the transistor 200b can be electrically connected to each other.

FIGS. 2A to 2C illustrate a structure in which the side surface of each of the oxide 230 and the conductor 242 is perpendicular to the substrate surface (not illustrated). Note that the present invention is not limited thereto. For example, the side surface of each of the oxide 230 and the conductor 242a may have a tapered shape.

In this specification and the like, a tapered shape refers to a shape such that at least part of the side surface of a component is inclined with respect to the substrate surface or the formation surface. For example, a tapered shape refers to a shape including a region where the angle between the inclined side surface and the substrate surface or the formation surface (such an angle is also referred to as a taper angle) is less than 90°. Note that the side surface of the component and the substrate surface are not necessarily completely flat and may be substantially flat with a curvature or with unevenness.

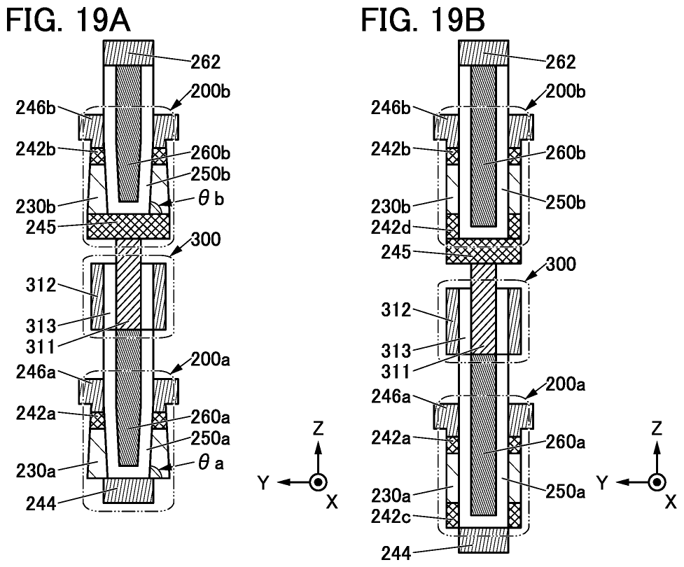

FIG. 19A is a cross-sectional view of a region including the memory cell 100. As illustrated in FIG. 19A, in the cross-sectional view, the side surface of the oxide 230a on the opening side (the insulator 250a side) may have a tapered shape with a taper angle θa. In the cross-sectional view, the side surface of the oxide 230b on the opening side (the insulator 250b side) may have a tapered shape with a taper angle θb. Here, the taper angle θ (the taper angle θa and the taper angle θb) is an angle between the side surface of the oxide 230 on the opening side and the substrate surface. Note that lower one of two sides extending from the vertex of the angle θ may correspond to the top surface of the conductor 244 or the conductor 245, the bottom surface of the oxide 230, or the like instead of the substrate surface. That is, the taper angle θ may be an angle between the side surface of the oxide 230 and the top surface of the conductor 244 or the conductor 245 or the bottom surface of the oxide 230. In that case, the outer side surface of the oxide 230 also has a tapered shape with the taper angle θ. Note that the taper angle da and the taper angle θb may be equal or not equal to each other.

When the side surface of the oxide 230 on the opening side has a tapered shape, the coverage with the insulator 250 provided in the opening of the oxide 230 is improved, so that a defect such as a void can be reduced. Moreover, the area of the lower base of the oxide 230 is increased, and the contact area between the oxide 230 and the conductor 244 or 245 can be increased.

As the taper angle θ is closer to 90°, the conductor 260 can be provided in a portion on the lower side of the opening of the oxide 230. Thus, the area of the region where the oxide 230 faces the conductor 260 with the insulator 250 therebetween can be increased, and the electrical characteristics of the transistor can be stabilized. Furthermore, the area occupied by the transistor 200 can be reduced. For example, the taper angle θ is greater than or equal to 80°, greater than or equal to 85°, or greater than or equal to 87° and less than 90°.

Also in the above structure, the top surface of the oxide 230 has a hollow circular shape. That is, in the above structure, the oxide 230 has a hollow conical frustum shape. That is, in the conical frustum shape of the oxide 230, the area of the upper base (the surface on the conductor 242 side) is smaller than the area of the lower base (the surface on the conductor 244 side or the conductor 245 side).

The side surface on the opening side (the insulator 250 side) and the outer side surface of the conductor 242 each have a tapered shape, like those of the oxide 230. Note that the angle between the side surface of the conductor 242 on the opening side and the substrate surface and the angle between the outer side surface of the conductor 242 and the substrate surface are equal to the taper angle θ. Note that depending on the combination of a material used for the oxide 230 and a material used for the conductor 242, processing conditions for the oxide 230 and the conductor 242, or the like, the angle between the side surface of the conductor 242 on the opening side and the substrate surface and the angle between the outer side surface of the conductor 242 and the substrate surface are not equal to the taper angle θ in some cases.

The conductor 242 has a hollow conical frustum shape. That is, in the conical frustum shape of the conductor 242, the area of the upper base (the surface on the conductor 246 side) is smaller than the area of the lower base (the surface on the oxide 230 side).

FIGS. 2A to 2C illustrate a structure in which the oxide 230a and the oxide 230b are in contact with the conductor 244 and the conductor 245, respectively. Note that the present invention is not limited thereto. For example, a conductor may be provided between the oxide 230a and the conductor 244. A conductor may be provided between the oxide 230b and the conductor 245.

FIG. 19B is a cross-sectional view of a region including the memory cell 100. As illustrated in FIG. 19B, a conductor 242c may be provided between the oxide 230a and the conductor 244. Here, the conductor 242c includes a region in contact with the bottom surface of the oxide 230a and a region in contact with at least part of the top surface of the conductor 244. In addition, a conductor 242d may be provided between the oxide 230b and the conductor 245. Here, the conductor 242d includes a region in contact with the bottom surface of the oxide 230b and a region in contact with at least part of the top surface of the conductor 245.

The conductors 242c and 242d each have a cylindrical shape. The cylindrical shape of each of the conductors 242c and 242d extends in the Z direction. The conductors 242c and 242d each have an opening. The top surface of each of the conductors 242c and 242d has a hollow circular shape. In other words, the conductors 242c and 242d each have a cylindrical shape provided with a hollow portion. The conductor 242c functions as one of the source electrode and the drain electrode of the transistor 200a, and the conductor 242d functions as one of the source electrode and the drain electrode of the transistor 200b.

The insulator 250a and the conductor 260a are placed inside the opening of the conductor 242c. With such a structure, an end portion of the region where the oxide 230a and the conductor 260a face each other with the insulator 250a therebetween can be made closer to the conductor 244. In other words, such a structure allows a region where the oxide 230a and the conductor 260a do not overlap with each other with the insulator 250a therebetween, what is called an Loff region, to be narrow or omitted. Consequently, the frequency characteristics of the transistor 200a can be improved. Note that the same applies to the transistor 200b provided with the conductor 242d. Accordingly, the memory cell 100 enables high-speed writing and high-speed reading and the operation speed of the semiconductor device can be increased, for example. Thus, a semiconductor device that operates at high speed can be provided.

Note that a conductive film to be the conductor 242c and a conductive film to be the conductor 242d are deposited in different steps. Thus, the conductor 242c and the conductor 242d may be formed using different materials or the same material.

In the case where the conductor 242d is provided to be in contact with the conductor 311, the conductor 245 is not necessarily provided. By employing such a structure, a step for forming the conductor 245 can be omitted, and the manufacturing cost of the semiconductor device can be reduced.

Although FIGS. 2A to 2C illustrate a structure in which the oxide 230 is a single layer, the present invention is not limited thereto. For example, the oxide 230 may have a stacked-layer structure of two or more layers.

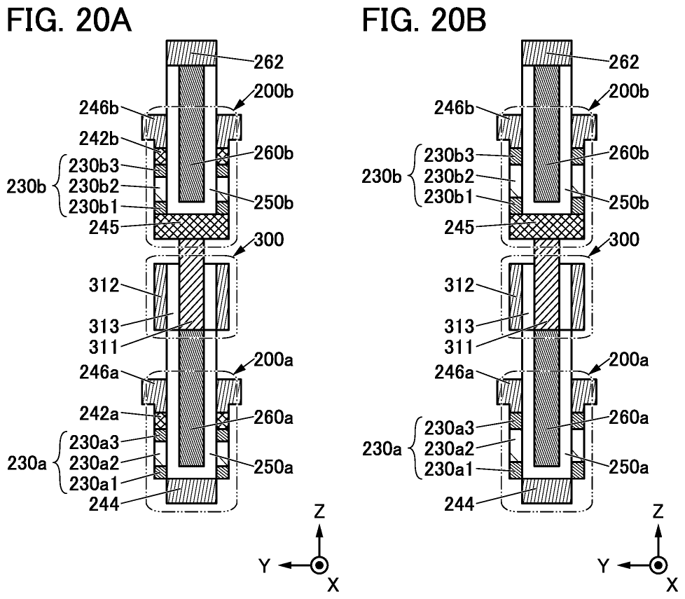

FIG. 20A is a cross-sectional view of a region including the memory cell 100. As illustrated in FIG. 20A, the oxide 230a may have a three-layer structure of an oxide 230al, an oxide 230a2 over the oxide 230al, and an oxide 230a3 over the oxide 230a2. The oxide 230b may have a three-layer structure of an oxide 230b1, an oxide 230b2 over the oxide 230b1, and an oxide 230b3 over the oxide 230b2.

In the transistor 200a, the oxide 230a2 functions as the channel formation region, the oxide 230al functions as one of a source region and a drain region, and the oxide 230a3 functions as the other of the source region and the drain region. In the transistor 200b, the oxide 230b2 functions as the channel formation region, the oxide 230b1 functions as one of the source region and the drain region, and the oxide 230b3 functions as the other of the source region and the drain region.

Hereinafter, the oxide 230al and the oxide 230b1 may be collectively referred to as an oxide 230_1. The oxide 230a2 and the oxide 230b2 may be collectively referred to as an oxide 230_2. The oxide 230a3 and the oxide 230b3 may be collectively referred to as an oxide 230_3.

A metal oxide that can be used as the oxide 230 described above may be used as the oxide 230_2.

For each of the oxides 230_1 and 230_3, a material having higher conductivity than the oxide 230_2 is preferably used. For each of the oxides 230_1 and 230_3, a degenerated oxide semiconductor is preferably used.

For example, for each of the oxides 230_1 and 230_3, a material obtained by adding nitrogen to a metal oxide that can be used for the oxide 230_2 can be used. Specifically, a metal oxide containing indium, the element M described above, zinc, and nitrogen (also referred to as a metal oxynitride) is preferably used. Specifically, it is possible to use an oxide containing indium (In), gallium (Ga), zinc (Zn), and nitrogen (also referred to as an oxynitride containing In, Ga, and Zn or IGZO to which nitrogen is added), an oxide containing indium (In), aluminum (Al), zinc (Zn), and nitrogen (also referred to as an oxynitride containing In, Al, and Zn or IAZO to which nitrogen is added), an oxide containing indium (In), aluminum (Al), gallium (Ga), zinc (Zn), and nitrogen (also referred to as an oxynitride containing In, Al, Ga, and Zn, IAGZO to which nitrogen is added, IGAZO to which nitrogen is added, or AGIZO to which nitrogen is added), or the like.

For example, IGZO to which nitrogen is added tends to have a wurtzite crystal structure. The lattice matching between a wurtzite crystal structure and a crystal structure of a crystal included in In-M-Zn oxide is favorable. Accordingly, when a metal oxynitride having a wurtzite crystal structure is used as the oxide 230_1, the crystallinity of the oxide 230_2 can be increased. That is, a metal oxide having a CAAC structure is easily formed as the oxide 230_2.

In the case where the CAAC-OS is used as the oxide 230_2 as described above, a crystal included in the oxide 230_2 has c-axis alignment with respect to the substrate surface. Note that impurities in the CAAC-OS are less likely to diffuse in the c-axis direction. That is, the use of the CAAC-OS as the oxide 230_2 can inhibit entry of impurities into the oxide 230_2. For example, entry of nitrogen into the oxide 230_2 can be inhibited. Thus, an increase in conductivity of the oxide 230_2 can be inhibited.

Although the materials each obtained by adding nitrogen to a metal oxide that can be used for the oxide 230_2 are described above, an element that increases the conductivity of the metal oxide may be added to a metal oxide that can be used for the oxide 230_2. As the element, for example, one or more elements selected from a Group 15 element (typically, nitrogen (N), phosphorus (P), arsenic (As), and antimony (Sb)), boron (B), aluminum (Al), argon (Ar), helium (He), neon (Ne), indium (In), fluorine (F), chlorine (Cl), titanium (Ti), and zinc (Zn) can be used.

Metal oxides used for the oxides 230_1 and 230_3 preferably have higher conductivity than the oxide 230_2. Metal oxides used for the oxides 230_1 and 230_3 may contain the same constituent elements as the oxide 230_2 as main components in addition to oxygen and may have different chemical compositions from the oxide 230_2.

In the case where the oxides 230_1 and 230_3 contain the same constituent elements as the oxide 230_2 as main components in addition to oxygen, the oxide 230 preferably has a stacked-layer structure of a plurality of oxide layers having different chemical compositions. For example, in the case where In-M-Zn oxide is used as the oxide 230_2, the proportion of indium atoms to the sum of atoms of metal elements that are main components in a metal oxide used for the oxide 230_1 or the oxide 230_3 is preferably larger than that in a metal oxide used for the oxide 230_2. In addition, the proportion of indium atoms to atoms of the element M in a metal oxide used for the oxide 230_1 or the oxide 230_3 is preferably larger than that in a metal oxide used for the oxide 230_2.

When the oxides 230_1 and 230_3 contain the same constituent elements as the oxide 230_2 as main components in addition to oxygen, the density of defect states at the interface between the oxide 230_2 and the oxide 230_1 or the oxide 230_3 can be reduced. Since the density of defect states at the interface between the oxide 230_2 and the oxide 230_1 or the oxide 230_3 can be low, the influence of interface scattering on carrier conduction can be small and a high on-state current can be obtained.

Alternatively, as each of the oxides 230_1 and 230_3, titanium oxide, molybdenum oxide, zinc oxide, indium oxide, tungsten oxide, magnesium oxide, calcium oxide, tin oxide, indium zinc oxide, indium tin oxide, indium tin oxide containing silicon, or the like may be used.

Note that in the case where the oxide 230 has the above-described three-layer structure, the conductor 242 is sometimes not necessarily provided as illustrated in FIG. 20B. In such a case, the conductor 246 also functions as the conductor 242. That is, the conductor 246 has a function of a wiring and a function of the other of the source electrode and the drain electrode. With a structure not including the conductor 242, the number of steps in the manufacturing process of the semiconductor device can be reduced and the productivity can be improved.

Although FIG. 20A illustrates the structure in which the oxide 230 has the above-described three-layer structure, the oxide 230 may have a stacked-layer structure of two or four or more layers.

For example, the oxide 230 may have a two-layer structure of the oxide 230_1 and the oxide 230_2 over the oxide 230_1. In the case where heat treatment is performed in a state where the conductor 242 and the oxide 230_2 are in contact with each other, the sheet resistance of the oxide 230_2 in the vicinity of the conductor 242 may be lowered. In addition, the carrier concentration may be increased. Thus, the resistance of the oxide 230_2 in the vicinity of the conductor 242 can be lowered in a self-aligned manner. Here, the low-resistance region of the oxide 230_2 can function as the other of the source region and the drain region.

FIGS. 2A to 2C illustrate a structure in which the insulator 250a is provided as the gate insulator of the transistor 200a and the insulator 313 is provided as the dielectric of the capacitor 300. Note that the present invention is not limited thereto. For example, one insulator may have a function of the gate insulator of the transistor 200a and a function of the dielectric of the capacitor 300.

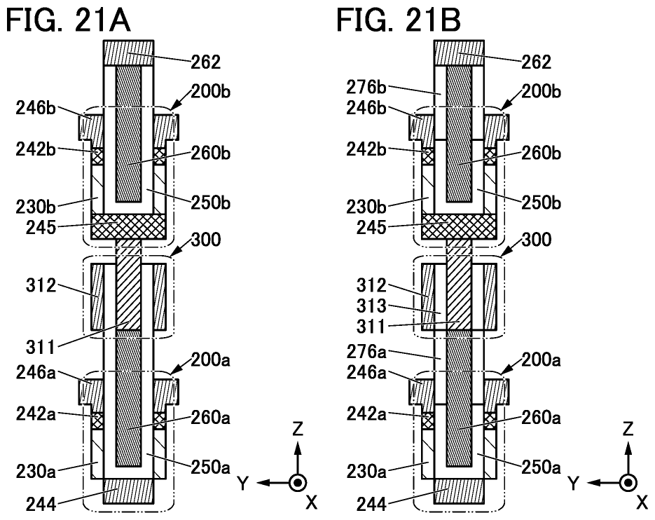

FIG. 21A is a cross-sectional view of a region including the memory cell 100. As illustrated in FIG. 21A, the insulator 250a may be provided to extend in the Z direction so that the top surface is positioned above the bottom surface of the conductor 312. The top surface of the insulator 250a is preferably level with the top surface of the conductor 312. Alternatively, the top surface of the insulator 250a is preferably positioned above the top surface of the conductor 312. At this time, the insulator 250a includes a region positioned between the conductor 311 and the conductor 312. Thus, the insulator 250a includes a region functioning as the gate insulator of the transistor 200a and a region functioning as the dielectric of the capacitor 300. With such a structure, a step for forming the insulator 313 can be omitted. Accordingly, a semiconductor device with high productivity can be provided.

Alternatively, an insulator may be provided between the insulator 250a and the insulator 313. An insulator may be provided between the insulator 250a and the conductor 262. FIG. 21B is a cross-sectional view of a region including the memory cell 100. As illustrated in FIG. 21B, an insulator 276a may be provided between the insulator 250a and the insulator 313, and an insulator 276b may be provided between the insulator 250b and the conductor 262. For example, the insulator 276 is preferably formed using a material having a lower dielectric constant than the insulator 250. With such a structure, parasitic capacitance generated between the conductor 246 and the conductor 260 can be reduced. Thus, freedom of choice of materials and structures is extended, whereby the reliability of the semiconductor device can be improved.

### Specific Structure Example 1 of Semiconductor Device

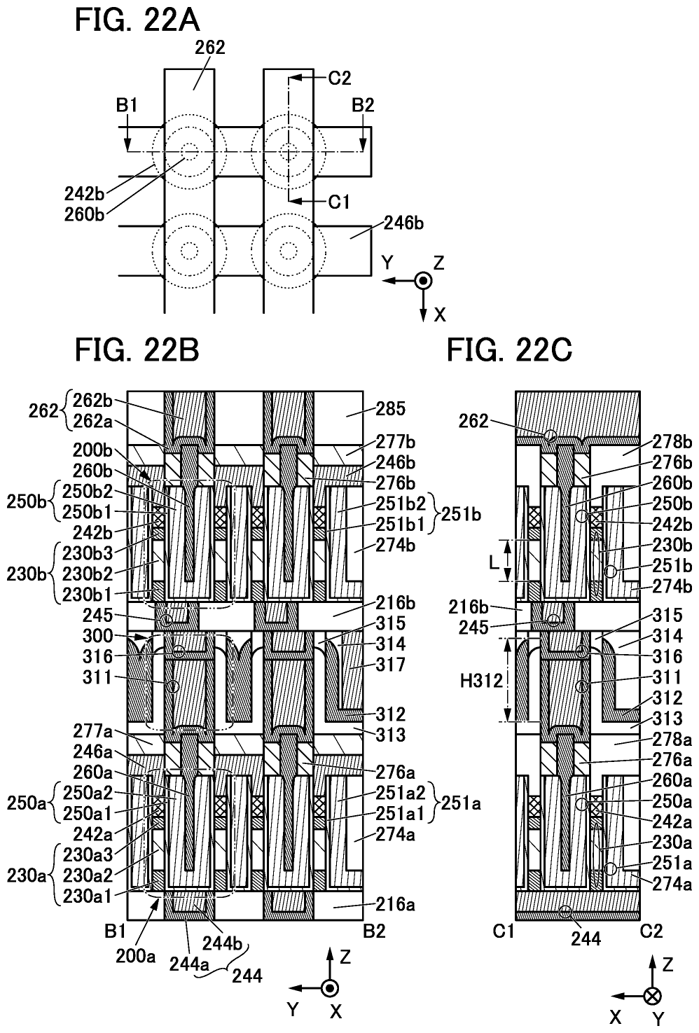

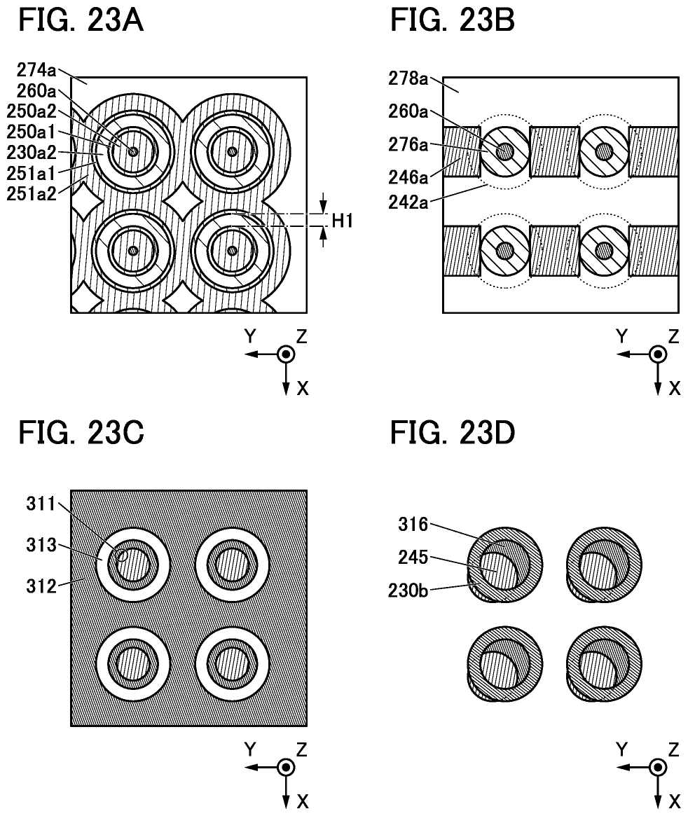

An example of a specific structure of a semiconductor device of one embodiment of the present invention is described below with reference to FIGS. 22A to 22C and FIGS. 23A to 23D. Note that in the semiconductor device described below, components having the same functions as the components in the semiconductor device described in <Structure example of semiconductor device> above are denoted by the same reference numerals. Differences from the semiconductor device described in <Structure example of semiconductor device> above will be mainly described below, and the description of portions similar to those in the above example is omitted.

FIGS. 22A to 22C are a plan view and cross-sectional views of the semiconductor device including a plurality of memory cells. FIG. 22A is the plan view of the semiconductor device. FIGS. 22B and 22C are the cross-sectional views of the semiconductor device. Here, FIG. 22B is the cross-sectional view taken along the dashed-dotted line B1-B2 in FIG. 22A. FIG. 22C is the cross-sectional view taken along the dashed-dotted line C1-C2 in FIG. 22A. Note that FIG. 22A illustrates four of the plurality of memory cells included in the semiconductor device.

The semiconductor device illustrated in FIGS. 22A to 22C includes the conductor 244 over a substrate (not illustrated), the transistor 200a over the conductor 244, the conductor 246a over the transistor 200a, the capacitor 300 over the transistor 200a, the conductor 245 over the capacitor 300, the transistor 200b over the conductor 245, the conductor 246b over the transistor 200b, and the conductor 262 over the transistor 200b.

An insulator 216a is provided over the substrate, an insulator 251a is provided over the insulator 216a, an insulator 274a is provided over the insulator 251a, and an insulator 278a is provided over the insulator 274a. An insulator 277a is provided over the conductor 246a, and the insulator 276a is provided in a region where the conductor 246a is divided. An insulator 314 is provided over the capacitor 300, an insulator 216b is provided over the insulator 314, an insulator 251b is provided over the insulator 216b, an insulator 274b is provided over the insulator 251b, and an insulator 278b is provided over the insulator 274b. An insulator 277b is provided over the conductor 246b, and the insulator 276b is provided in a region where the conductor 246b is divided. In addition, an insulator 285 is provided over the insulator 277b and the insulator 278b.

The insulators 216, 274, 276, 277, 278, 314, and 285 each function as an interlayer film.

For each of the insulators 216, 274, 276, 277, 278, 314, and 285, a material with a low dielectric constant described later is preferably used. In the case where a material with a low dielectric constant is used for an interlayer film, the parasitic capacitance generated between wirings can be reduced.

The insulator 251a includes an insulator 251a1 and an insulator 251a2 over the insulator 251a1. The insulator 251b includes an insulator 251b1 and an insulator 251b2 over the insulator 251b1. Hereinafter, the insulator 251a1 and the insulator 251b1 may be collectively referred to as an insulator 251_1. The insulator 251a2 and the insulator 251b2 may be collectively referred to as an insulator 251_2.

The conductor 244 is provided to be embedded in an opening of the insulator 216a.

In FIGS. 22B and 22C, the conductor 244 has a two-layer structure of a conductor 244a and a conductor 244b over the conductor 244a. The conductor 244a is provided in contact with the bottom and side surfaces of the opening of the insulator 216a. The conductor 244b is provided to be embedded in a depressed portion formed in the conductor 244a. Here, the top surface of the conductor 244b is level with the top surfaces of the conductor 244a and the insulator 216a.

Here, the conductor 244a is preferably formed using a conductive material having a function of inhibiting diffusion of oxygen (e.g., at least one of oxygen atoms, oxygen molecules, and the like). Alternatively, the conductor 244a is preferably formed using a conductive material having a function of inhibiting diffusion of impurities such as hydrogen atoms, hydrogen molecules, water molecules, nitrogen atoms, nitrogen molecules, nitrogen oxide molecules (e.g., N₂O, NO, and NO₂), and copper atoms.

When the conductor 244a is formed using a conductive material having a function of inhibiting oxygen, the conductivity of the conductor 244b can be inhibited from being lowered because of oxidation of the conductor 244b. As the conductive material having a function of inhibiting diffusion of oxygen, for example, titanium, titanium nitride, tantalum, tantalum nitride, ruthenium, or ruthenium oxide is preferably used. Thus, the conductor 244a can be a single layer or a stacked layer of the above conductive materials. For example, titanium nitride may be used for the conductor 244a.

The conductor 244b is preferably formed using a conductive material containing tungsten, copper, or aluminum as its main component. For example, the conductor 244b may be formed using tungsten.

The electric resistivity of the conductor 244 is designed in consideration of the potential applied to the conductor 244, and the thickness of the conductor 244 is determined in accordance with the electric resistivity. The thickness of the insulator 216a is substantially equal to that of the conductor 244. The conductor 244 and the insulator 216a are preferably as thin as possible in the allowable range of the design of the conductor 244. The insulator 216a with a reduced thickness contains a smaller absolute amount of impurities such as hydrogen, inhibiting the diffusion of the impurity into the oxide 230a.

Note that although the conductor 244 in FIG. 22B has a two-layer structure, the present invention is not limited thereto. For example, the conductor 244 may have a single-layer structure or a stacked-layer structure of three or more layers.

Note that the description in <Structure example of semiconductor device> above can be referred to for a material, a structure, and the like for the conductor 244. The conductor 244 may be formed using a conductive material that can be used for the conductor 242.

The conductor 245 is placed to be embedded in the insulator 216b. The top surface of the conductor 245 is level with the top surface of the insulator 216b.

The conductor 262 is placed to be embedded in the insulator 285. The top surface of the conductor 262 is level with the top surface of the insulator 285.

The conductor 262 preferably has a two-layer structure of a conductor 262a and a conductor 262b over the conductor 262a. For example, the conductor 262a is preferably placed to cover the bottom and side surfaces of the conductor 262b. Although the conductor 262 has a two-layer structure of the conductors 262a and 262b in FIG. 22B, the conductor 262 may have a single-layer structure or a stacked-layer structure of three or more layers.

The conductor 262a is preferably formed using a conductive material having a function of inhibiting diffusion of impurities such as hydrogen atoms, hydrogen molecules, water molecules, nitrogen atoms, nitrogen molecules, nitrogen oxide molecules, and copper atoms. Alternatively, the conductor 262a is preferably formed using a conductive material having a function of inhibiting diffusion of oxygen (e.g., at least one of oxygen atoms, oxygen molecules, and the like).

When the conductor 262a has a function of inhibiting diffusion of oxygen, the conductivity of the conductor 262b can be inhibited from being lowered because of oxidation of the conductor 262b due to oxygen contained in the insulator 285. As the conductive material having a function of inhibiting diffusion of oxygen, for example, titanium, titanium nitride, tantalum, tantalum nitride, ruthenium, or ruthenium oxide is preferably used.

The conductor 262 also functions as a wiring and thus is preferably formed using a conductor having high conductivity. For example, the conductor 262b can be formed using a conductive material containing tungsten, copper, or aluminum as its main component. The conductor 262b may have a stacked-layer structure, for example, a stacked-layer structure of titanium or titanium nitride and the above conductive material.

The memory cell of the semiconductor device includes the transistor 200a, the capacitor 300, and the transistor 200b. The memory cell illustrated in FIGS. 22A to 22C shows a detailed structure example of the memory cell 100 illustrated in FIGS. 12A to 12C.

As illustrated in FIGS. 22A to 22C, the transistor 200a includes the oxide 230a, the conductor 242a over the oxide 230a, the insulator 250a, and the conductor 260a over the insulator 250a. The transistor 200b includes the oxide 230b, the conductor 242b over the oxide 230b, the insulator 250b, and the conductor 260b over the insulator 250b. The capacitor 300 includes the conductor 311, a conductor 316 over the conductor 311, the insulator 313, an insulator 315 over the insulator 313, and the conductor 312.

As in the structure illustrated in FIG. 20A, the oxide 230a includes the oxide 230al, the oxide 230a2 over the oxide 230al, and the oxide 230a3 over the oxide 230a2. The oxide 230b includes the oxide 230b1, the oxide 230b2 over the oxide 230b1, and the oxide 230b3 over the oxide 230b2.

The insulator 250a includes an insulator 250a1 and an insulator 250a2 over the insulator 250a1. The insulator 250b includes an insulator 250b1 and an insulator 250b2 over the insulator 250b1. Hereinafter, the insulator 250a1 and the insulator 250b1 may be collectively referred to as an insulator 250_1. The insulator 250a2 and the insulator 250b2 may be collectively referred to as an insulator 250_2.

Here, FIG. 23A is a cross-sectional view taken along the XY plane including the oxide 230a2. FIG. 23A illustrates a structure in which the top surface of the oxide 230a2 has a hollow circular shape. Here, the insulator 250a1 is concentrically provided inside the oxide 230a2, the insulator 250a2 is concentrically provided inside the insulator 250al, and the conductor 260a is concentrically provided inside the insulator 250a2. The same applies to the oxide 230b2, the insulator 250b1, the insulator 250b2, and the conductor 260b.

Here, the width of the oxide 230_2 in the direction from the center of the hollow portion of the oxide 230_2 to the outer periphery of the cylindrical shape is a width H1. In other words, the width H1 is half of a difference between the outer diameter and the inner diameter of the hollow cylindrical shape.

In order to prevent contact between adjacent oxides 230_2, the width H1 needs to be smaller than half of the minimum feature size (F). Meanwhile, the width H1 needs to be large to some extent so that the oxide 230_2 having a hollow cylindrical shape is formed. In the case where the minimum feature size (F) is 15 nm, for example, the width H1 is preferably greater than or equal to 1 nm and less than or equal to 7 nm, further preferably greater than or equal to 1.5 nm and less than or equal to 6 nm, still further preferably greater than or equal to 2 nm and less than or equal to 5 nm. With such a structure, contact between adjacent oxides 230_2 can be prevented and at least the insulator 251a can be provided between the adjacent oxides 230_2. Note that the preferable range of the width H1 is not limited to the above range. The width H1 can be set as appropriate in consideration of the minimum feature size, the thickness of the insulator 251a, and the like.

The oxide 230a includes a region in contact with the conductor 244. Specifically, the oxide 230al is in contact with at least part of the top surface of the conductor 244. The oxide 230b includes a region overlapping with the conductor 245. Specifically, the oxide 230b1 is in contact with at least part of the top surface of the conductor 245.

The oxide 230 overlaps with the conductor 242. Specifically, the oxide 230_3 is in contact with the bottom surface of the conductor 242.

The top surface of the insulator 250a is level with the top surfaces of the insulator 251a and the insulator 274a. The top surface of the insulator 250b is level with the top surfaces of the insulator 251b and the insulator 274b.

The insulator 276 is provided over the insulator 250. The insulator 276 includes a region overlapping with the insulator 250.

Here, FIG. 23B is a cross-sectional view taken along the XY plane including the insulator 276a and the conductor 246a. Note that in FIG. 23B, the outline of the conductor 242a is indicated by a dotted line for easy understanding.

The insulator 276 has a cylindrical shape and has an opening. That is, the insulator 276 has a cylindrical shape provided with a hollow portion. In other words, the top surface of the insulator 276 has a hollow circular shape. The conductor 260 is provided in the hollow portion of the insulator 276. When the conductor 260 has a circular cross-sectional shape, the insulator 276 is concentrically provided outside the conductor 260.

In a plan view, the diameter of the hollow portion of the insulator 276 is preferably equal to or larger than the diameter of the depressed portion of the insulator 250. With such a structure, the conductor 260 can be embedded more surely in the depressed portion of the insulator 250.

In the plan view, the outer periphery of the insulator 276 is preferably aligned with the outline of the insulator 250. With such a structure, the contact area between the conductor 242 and the conductor 246 can be larger than that in the structure in which the outer periphery of the insulator 276 is positioned outward from the outline of the insulator 250. Moreover, the distance between the conductor 246a and one of the pair of electrodes of the capacitor 300 (the conductor 311 described later) and the distance between the conductor 262 and the conductor 246b can be larger than those in the structure in which the outer periphery of the insulator 276 is positioned inward from the outline of the insulator 250. Thus, a leakage current and a short circuit between the conductor 246a and the conductor 311 and between the conductor 262 and the conductor 246b can be prevented.

The insulator 276 preferably extends in the Z direction so that the top surface of the insulator 276 is positioned above the top surface of the conductor 246. In other words, the insulator 276 preferably extends in the Z direction so that the top surface of the conductor 246 is positioned above the bottom surface of the insulator 276 and positioned below the top surface of the insulator 276. This structure can prevent the conductor 246a and one of the pair of electrodes of the capacitor 300 (the conductor 311 described later) from being in contact with each other, and can prevent a leakage current and a short circuit between the conductor 246a and the conductor 311. Furthermore, this structure can prevent the conductor 262 and the conductor 246b from being in contact with each other, and can prevent a leakage current and a short circuit between the conductor 262 and the conductor 246b.

In the plan view, there is a region where end portions of the insulator 277 and the conductor 246 are aligned with each other.

In the transistor 200, a metal oxide functioning as a semiconductor (hereinafter such a metal oxide is also referred to as an oxide semiconductor) is preferably used for the oxide 230_2 including a channel formation region. Note that in each of the oxides 230_1 and 230_3, part of a region facing the conductor 260 with the insulator 250 therebetween functions as a channel formation region in some cases.

Although the transistor 200 illustrated in FIG. 22B includes the oxide 230 having a three-layer structure of the oxide 230_1, the oxide 230_2, and the oxide 230_3, the present invention is not limited thereto. For example, the oxide 230 may have a single-layer structure or a stacked-layer structure of two or four or more layers. The oxide 230a and the oxide 230b may have the same structure or different structures.

The conductor 242 overlaps with the oxide 230. Specifically, the conductor 242 is in contact with the top surface of the oxide 230_3.

In FIG. 22B, the conductor 242 is a single layer. Note that the present invention is not limited thereto, and the conductor 242 may have a stacked-layer structure of two or more layers. For example, the conductor 242 may have a two-layer structure of a first conductor over the oxide 230_3 and a second conductor over the first conductor.

The first conductor of the conductor 242 is preferably formed using a conductive material with a property of being less likely to be oxidized. This can inhibit the oxidation of the first conductor of the conductor 242 and a reduction in the conductivity of the conductor 242. Note that the first conductor of the conductor 242 may have such a property that hydrogen is easily absorbed (extracted) thereinto. Consequently, hydrogen in the oxide 230 can diffuse into the first conductor of the conductor 242, so that the hydrogen concentration in the oxide 230 can be reduced. Accordingly, the transistor 200 can have stable electric characteristics.

The second conductor of the conductor 242 is preferably formed using a conductive material having higher conductivity than the first conductor of the conductor 242. In this case, at least part of the second conductor of the conductor 242 includes a region having higher conductivity than the first conductor of the conductor 242. Alternatively, the second conductor of the conductor 242 is preferably formed using a conductive material having lower resistivity than the first conductor of the conductor 242. As a result, a semiconductor device with reduced wiring delay can be manufactured.

Note that the second conductor of the conductor 242 may have such a property that hydrogen is easily absorbed thereinto. Accordingly, hydrogen absorbed by the first conductor of the conductor 242 also diffuses into the second conductor of the conductor 242, so that the hydrogen concentration in the oxide 230 can be further reduced. Accordingly, the transistor 200 can have stable electric characteristics.

Here, for the first conductor and the second conductor of the conductor 242, conductive materials that have the same constituent element and have different chemical compositions are preferably used. In this case, the first conductor and the second conductor of the conductor 242 can be deposited successively without being exposed to the air. By the deposition without exposure to the atmosphere, impurities or moisture from the air can be prevented from being attached onto the surface of the first conductor of the conductor 242, so that the vicinity of the interface between the first conductor and the second conductor of the conductor 242 can be kept clean.

A nitride containing tantalum with a high atomic ratio of nitrogen to tantalum is preferably used for the first conductor of the conductor 242, and a nitride containing tantalum with a low atomic ratio of nitrogen to tantalum is preferably used for the second conductor of the conductor 242. For example, for the first conductor of the conductor 242, a nitride containing tantalum in which the atomic ratio of nitrogen to tantalum is greater than or equal to 1.0 and less than or equal to 2.0, preferably greater than or equal to 1.1 and less than or equal to 1.8, further preferably greater than or equal to 1.2 and less than or equal to 1.5 is used. For example, as the second conductor of the conductor 242, a nitride containing tantalum in which the atomic ratio of nitrogen to tantalum is greater than or equal to 0.3 and less than or equal to 1.5, preferably greater than or equal to 0.5 and less than or equal to 1.3, further preferably greater than or equal to 0.6 and less than or equal to 1.0 is used.

The high atomic ratio of nitrogen to tantalum in a nitride containing tantalum can inhibit oxidation of the nitride containing tantalum. In addition, the oxidation resistance of the nitride containing tantalum can be improved. Moreover, the diffusion of oxygen into the nitride containing tantalum can be inhibited. Hence, the nitride containing tantalum with a high atomic ratio of nitrogen to tantalum is preferably used for the first conductor of the conductor 242. It is thus possible to prevent an oxide layer from being formed between the first conductor of the conductor 242 and the oxide 230 or reduce the thickness of the oxide layer.

The low atomic ratio of nitrogen to tantalum in a nitride containing tantalum can reduce the resistivity of the nitride. Hence, the nitride containing tantalum with a low atomic ratio of nitrogen to tantalum is preferably used for the second conductor of the conductor 242. As a result, a semiconductor device with reduced wiring delay can be manufactured.

Note that the boundary between the first conductor and the second conductor of the conductor 242 is difficult to clearly detect in some cases. In the case where a nitride containing tantalum is used for the conductor 242, the tantalum concentration and the nitrogen concentration detected in each layer may gradually change within each layer and may also change continuously (or in a gradation manner) in a region between the first conductor and the second conductor. That is, the atomic ratio of nitrogen to tantalum is preferably higher in the region of the conductor 242 that is closer to the oxide 230. Thus, the atomic ratio of nitrogen to tantalum in a region positioned below the conductor 242 is preferably higher than the atomic ratio of nitrogen to tantalum in a region positioned above the conductor 242.

The thickness of the first conductor of the conductor 242 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In that case, at least part of the first conductor of the conductor 242 includes a region having the above-described thickness. The thickness of the first conductor of the conductor 242 is preferably smaller than that of the second conductor of the conductor 242. In this case, at least part of the first conductor of the conductor 242 includes a region having a thickness smaller than that of the second conductor of the conductor 242.

Note that in the example shown above, conductive materials having the same constituent element and having different chemical compositions are used for the first conductor and the second conductor of the conductor 242; however, one embodiment of the present invention is not limited thereto, and the first conductor and the second conductor of the conductor 242 may be formed using different conductive materials. For example, a nitride containing tantalum may be used for the first conductor of the conductor 242, and tungsten or a nitride containing titanium may be used for the second conductor of the conductor 242.

The insulator 250_1 is placed inside the openings of the oxide 230 and the conductor 242 (the hollow portions of the oxide 230 and the conductor 242). The insulator 250_1 functions as part of the gate insulator. The insulator 251_1 is placed outside the cylindrical shapes of the oxide 230 and the conductor 242.

Although the details are described later, the insulator 250_1 and the insulator 251_1 are formed in the same step. Thus, the insulator 251_1 contains the same insulating material as the insulator 250_1. The thickness of the insulator 251_1 is equal to that of the insulator 250_1.

The insulator 250_1 and the insulator 251_1 are provided in the same layer. In FIGS. 22B and 22C, the insulators 250a1 and 251a1 are provided over the insulator 216a and the conductor 244, and the insulators 250b1 and 251b1 are provided over the insulator 216b and the conductor 245.

As each of the insulators 250_1 and 251_1, a barrier insulating film against oxygen is preferably used. An insulator containing oxygen and one or both of aluminum and hafnium is preferably used as each of the insulators 250_1 and 251_1, for example. As the insulator, aluminum oxide, hafnium oxide, an oxide containing aluminum and hafnium (hafnium aluminate), an oxide containing hafnium and silicon (hafnium silicate), or the like can be used. In this embodiment, aluminum oxide is used as each of the insulators 250_1 and 251_1. In that case, the insulators 250_1 and 251_1 each contain at least oxygen and aluminum.

As illustrated in FIGS. 22B and 22C, the oxide 230 is surrounded by the insulators 250_1 and 251_1. With this structure, release of oxygen from the oxide 230 by heat treatment or the like can be prevented by the insulators 250_1 and 251_1 having a barrier property against oxygen. Thus, formation of oxygen vacancies in the oxide 230 can be inhibited. Therefore, oxygen vacancies and V_{O}H formed in the oxide 230 can be reduced. Accordingly, the electrical characteristics and reliability of the transistor 200 can be improved.

Even when the excess amount of oxygen is included in the insulator 274, the insulator 251_2, the insulator 250_2, or the like, supply of the oxygen to the oxide 230 can be inhibited. Thus, the oxides 230_1 and 230_3 are inhibited from being excessively oxidized, so that a reduction in the on-state current or field-effect mobility of the transistor 200 can be inhibited.

As illustrated in FIGS. 22B and 22C, the conductor 242 is surrounded by the insulators 250_1 and 251_1. This inhibits formation of an oxide film on the side surface of the conductor 242 by oxidization of the side surface. It is thus possible to inhibit a reduction in the on-state current or field-effect mobility of the transistor 200.

When aluminum oxide is used for each of the insulators 250_1 and 251_1, aluminum may be added to a region in contact with the insulator 250_1 and the vicinity thereof and a region in contact with the insulator 251_1 and the vicinity thereof in the oxide 230_2. For example, in the case where IGZO is used for the oxide 230_2, indium, gallium, aluminum, and zinc are contained in the region in contact with the insulator 250_1 and the vicinity thereof and the region in contact with the insulator 251_1 and the vicinity thereof in the oxide 230_2.

As illustrated in FIG. 22B or the like, the insulator 250_1 formed using aluminum oxide or the like is provided in contact with the side surface of the opening of the oxide 230_2, whereby indium contained in the oxide 230_2 is unevenly distributed, in some cases, at the interface between the oxide 230_2 and the insulator 250_1 and in its vicinity. Accordingly, the vicinity of the surface of the oxide 230_2 on the opening side comes to have an atomic ratio close to that of indium oxide or that of In—Zn oxide. Such an increase in the atomic ratio of indium in the vicinity of the surface of the oxide 230_2, especially the vicinity of the surface of the oxide 230_2 on the opening side, can increase the field-effect mobility of the transistor 200.

The insulator 250_1 needs to be provided in the openings of the conductor 242 and the oxide 230, together with the insulator 250_2 and the conductor 260. The thickness of the insulator 250_1 is preferably small for miniaturization of the transistor 200. The thickness of the insulator 250_1 is greater than or equal to 0.1 nm and less than or equal to 5.0 nm, preferably greater than or equal to 0.5 nm and less than or equal to 3.0 nm, further preferably greater than or equal to 1.0 nm and less than 3.0 nm. In that case, at least part of the insulator 250_1 includes a region having the above-described thickness. The thickness of the insulator 250_1 is preferably smaller than that of the insulator 250_2. In that case, at least part of the insulator 250_1 includes a region having a thickness smaller than that of the insulator 250_2.

To reduce the thickness of the insulator 250_1 as described above, the insulator 250_1 is preferably deposited by an ALD method. As the ALD method, a thermal ALD method, in which a precursor and a reactant react with each other only by a thermal energy, a plasma-enhanced ALD (PEALD) method, in which a reactant excited by plasma is used, and the like can be used. The use of plasma is sometimes preferable because deposition at a lower temperature is possible in a PEALD method.

An ALD method enables a single atomic layer to be formed at a time, and has various advantages such as deposition of an extremely thin film, deposition on a component with a high aspect ratio, deposition of a film with a small number of defects such as pinholes, deposition with excellent coverage, and low-temperature deposition. Thus, the insulator 250_1 can be deposited on the side surface of the opening portion in the conductor 242 and the oxide 230 to have a small thickness as described above and to have excellent coverage.

Note that a precursor used in the ALD method sometimes contains carbon or the like. Thus, a film formed by the ALD method may contain impurities such as carbon in a larger amount than a film formed by another deposition method. Note that impurities can be quantified by secondary ion mass spectrometry (SIMS), X-ray photoelectron spectroscopy (XPS), or auger electron spectroscopy (AES).

The insulator 250_2 is placed in the depressed portion of the insulator 250_1. The insulator 250_2 functions as part of the gate insulator. The insulator 251_2 is placed in contact with the top surface of the insulator 251_1.

Although the details are described later, the insulator 250_2 and the insulator 251_2 are formed in the same step. Thus, the insulator 251_2 contains the same insulating material as the insulator 250_2. The thickness of the insulator 251_2 is equal to that of the insulator 250_2.

In FIG. 22B, the insulator 250_2 is provided over the insulator 250_1, and the insulator 251_2 is provided over the insulator 251_1. As described above, the insulator 250_1 and the insulator 251_1 are provided in the same layer, so that the insulator 250_2 and the insulator 251_2 can be regarded as being provided in the same layer.

Note that the description of the insulator 250 in <Structure example of semiconductor device> above can be referred to for materials, structures, and the like for the insulators 250_2 and 251_2. In this embodiment, hafnium oxide is used as each of the insulators 250_2 and 251_2. In that case, the insulators 250_2 and 251_2 each contain at least oxygen and hafnium.

The conductor 260 is placed in the depressed portion of the insulator 250. The conductor 260 is formed in a self-aligned manner to fill the openings of the oxide 230 and the conductor 242.

In FIG. 22B, the conductor 260 is a single layer. Note that the present invention is not limited thereto, and the conductor 260 may have a stacked-layer structure of two or more layers.

The conductor 246 is placed over the conductor 242. The conductor 246 is placed in contact with at least part of the top surface of the conductor 242. A region of the conductor 246 that overlaps with the conductor 242 has a protruding portion.

The conductor 262 is placed over the conductor 260b. The conductor 262 is placed in contact with the top surface of the conductor 260b. In the plan view, the conductor 262 does not overlap with the conductor 246b. The conductor 262 is positioned over the insulator 276b. At least part of the bottom surface of the conductor 262 is in contact with the top surface of the insulator 276b. That is, the insulator 276b is provided between the insulator 250b and the conductor 262. The insulator 276b includes a region in contact with the bottom surface of the conductor 262.

In the capacitor 300, the conductors 311 and 316 function as one of the pair of electrodes, the conductor 312 functions as the other of the pair of electrodes, and the insulators 313 and 315 function as dielectrics.

The conductor 311 includes a region in contact with the top surface of the conductor 260a and a region in contact with the bottom surface of the conductor 316. The conductor 316 includes a region in contact with the top surface of the conductor 311 and a region in contact with at least part of the bottom surface of the conductor 245. In the plan view, the conductor 316 overlaps with the conductor 311.

In FIG. 22B, the conductor 311 has a two-layer structure of a first conductor and a second conductor over the first conductor. The conductor 316 has a two-layer structure of a first conductor and a second conductor over the first conductor.

For each of the first conductor of the conductor 311 and the first conductor of the conductor 316, a conductive material that can be used for the conductor 244a can be used. For each of the second conductor of the conductor 311 and the second conductor of the conductor 316, a conductive material that can be used for the conductor 244b can be used.

Note that although the conductors 311 and 316 in FIG. 22B each have a two-layer structure, the present invention is not limited thereto. For example, the conductors 311 and 316 may each have a single-layer structure or a stacked-layer structure of three or more layers.

The insulator 313 is provided over the insulators 277a and 278a. The insulator 313 has an opening overlapping with the conductor 311. The insulator 315 is provided over the insulator 313 and has an opening overlapping with the opening of the insulator 313.

Note that the description of the insulator 313 in <Structure example of semiconductor device> above can be referred to for materials, structures, and the like for the insulators 313 and 315.

Here, FIG. 23C is a cross-sectional view taken along the XY plane including the conductor 312. FIG. 23C illustrates a structure in which the conductor 312 has a circular opening. Here, the insulator 313 is concentrically provided inside the conductor 312, the first conductor of the conductor 311 is concentrically provided inside the insulator 313, and the second conductor of the conductor 311 is concentrically provided inside the first conductor of the conductor 311.

The conductor 312 is provided over the insulator 313. The conductor 312 includes a region facing the conductors 311 and 316 with the insulators 313 and 315 therebetween. The description with reference to FIG. 11 and FIGS. 12A to 12C can be referred to for the shape of the conductor 312.

Here, FIG. 23D is a plan view of the semiconductor device illustrated in FIGS. 22A to 22C. Note that for easy understanding, FIG. 23D illustrates the oxide 230b, the conductor 245, and the conductor 316. As illustrated in FIG. 23D, in the plan view, the conductor 245 includes a region overlapping with the oxide 230b and a region overlapping with the conductor 316. Specifically, the conductor 245 includes a region in contact with at least part of the top surface of the conductor 316 and a region in contact with at least part of the bottom surface of the oxide 230b1.

The conductor 245 has a two-layer structure of the first conductor and the second conductor over the first conductor. For the first conductor of the conductor 245, a conductive material that can be used for the conductor 244a can be used. For the second conductor of the conductor 245, a conductive material that can be used for the conductor 244b can be used.

Note that although the conductor 245 in FIG. 22B has a two-layer structure, the present invention is not limited thereto. For example, the conductor 245 may have a single-layer structure or a stacked-layer structure of three or more layers.

In FIG. 22B, a conductor 317 is provided inside an opening of the insulator 314. The conductor 317 includes a region in contact with the conductor 312. In the case where the conductor 317 functions as a wiring and the conductor 312 functions as the other of the pair of electrodes of the capacitor 300, the conductor 312 does not require a large thickness. Thus, the deposition time of the conductor 312 can be shortened and the productivity can be improved.

The description with reference to FIG. 2C can be referred to for the length L and the length H312 in FIG. 22C.

### [Material for Semiconductor Device]

Materials that can be used for the semiconductor device will be described below.

### [Substrate]

As a substrate where the transistor 200 is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example is any of the above semiconductor substrates provided with an insulator region, such as a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. An insulator substrate provided with a conductor or a semiconductor, a semiconductor substrate provided with a conductor or an insulator, a conductor substrate provided with a semiconductor or an insulator, or the like may be used. Alternatively, these substrates provided with elements may be used. Examples of the element provided over the substrate include a capacitor, a resistor, a switching element, a light-emitting element, and a memory element.

### [Insulator]

Examples of an insulator include an insulating oxide, an insulating nitride, an insulating oxynitride, an insulating nitride oxide, an insulating metal oxide, an insulating metal oxynitride, and an insulating metal nitride oxide.

With miniaturization and higher integration of transistors, for example, a problem such as generation of a leakage current may arise because of a thinner gate insulator. When a high dielectric constant (high-k) material is used for the insulator functioning as a gate insulator, the voltage at the time of operation of the transistor can be reduced while the physical thickness is maintained. By contrast, when a low-dielectric-constant material is used for the insulator functioning as an interlayer film, parasitic capacitance generated between wirings can be reduced. Thus, a material is preferably selected depending on the function of an insulator.

Examples of a high dielectric constant material include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a low-dielectric-constant material include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin. Examples of the resin include polyester, polyolefin, polyamide (e.g., nylon and aramid), polyimide, polycarbonate, and acrylic.

A transistor including a metal oxide can have stable electrical characteristics when surrounded by an insulator having a function of inhibiting the passage of oxygen and impurities such as hydrogen. The insulator having a function of inhibiting the passage of oxygen and impurities such as hydrogen can have, for example, a single-layer structure or a stacked-layer structure of an insulator containing boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum. Specifically, as the insulator having a function of inhibiting the passage of oxygen and impurities such as hydrogen, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

The insulator functioning as a gate insulator preferably includes a region containing oxygen that is released by heating. For example, silicon oxide or silicon oxynitride that includes a region containing oxygen that is released by heating is provided in contact with the oxide 230 to compensate for the oxygen vacancies in the oxide 230.

### [Conductor]

For the conductor, it is preferable to use a metal element selected from aluminum, chromium, copper, silver, gold, platinum, tantalum, nickel, cobalt, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Tantalum nitride, titanium nitride, a nitride containing titanium and aluminum, a nitride containing tantalum and aluminum, ruthenium oxide, ruthenium nitride, an oxide containing strontium and ruthenium, and an oxide containing lanthanum and nickel are preferable because they are oxidation-resistant conductive materials or materials that maintain their conductivity even after absorbing oxygen. Alternatively, a semiconductor having high electric conductivity, typified by polycrystalline silicon containing an impurity element such as phosphorus, or silicide such as nickel silicide may be used.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

When an oxide is used for the channel formation region of the transistor, the conductor functioning as the gate electrode preferably has a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductor functioning as the gate electrode, a conductive material containing oxygen and a metal element contained in a metal oxide in which the channel is formed. A conductive material containing any of the above metal elements and nitrogen may also be used. For example, a conductive material containing nitrogen, such as titanium nitride or tantalum nitride, may be used. Any of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide in which the channel is formed can be captured in some cases. Hydrogen entering from a surrounding insulator or the like can also be captured in some cases.

### [Method 1 for Manufacturing Semiconductor Device]

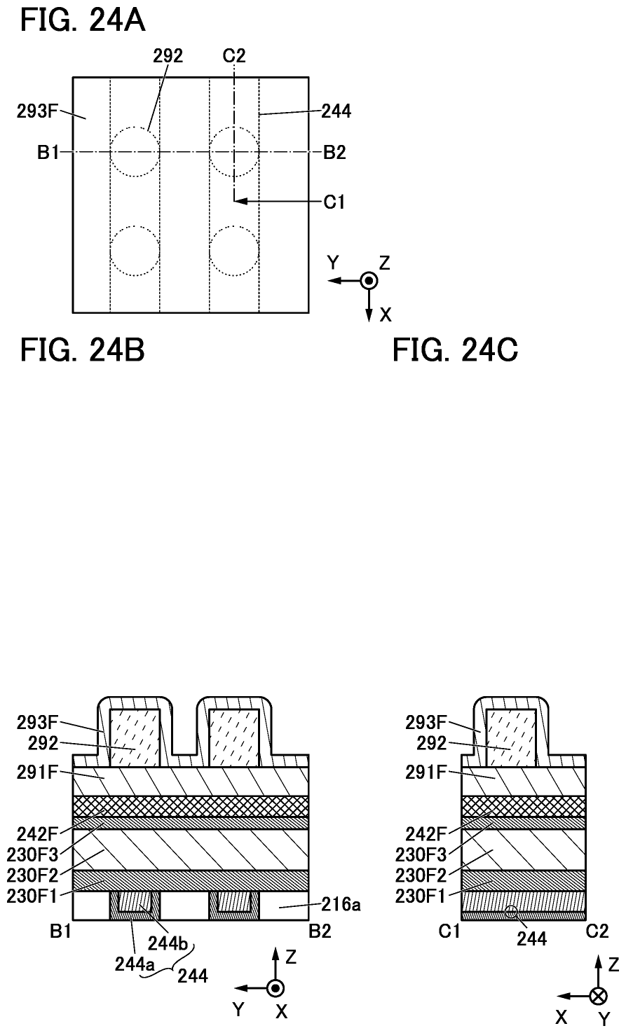

Next, an example of a method for manufacturing the semiconductor device illustrated in FIGS. 22A to 22C will be described with reference to FIGS. 24A to 24C, FIGS. 25A to 25C, FIGS. 26A to 26C, FIGS. 27A to 27C, FIGS. 28A to 28C, FIGS. 29A to 29C, FIGS. 30A to 30C, FIGS. 31A to 31C, FIGS. 32A to 32C, FIGS. 33A to 33C, FIGS. 34A to 34C, FIGS. 35A to 35C, FIGS. 36A to 36C, FIGS. 37A to 37C, FIGS. 38A to 38C, FIGS. 39A to 39C, FIGS. 40A to 40C, FIGS. 41A to 41C, FIGS. 42A to 42C, FIGS. 43A to 43C, and FIGS. 44A to 44C.

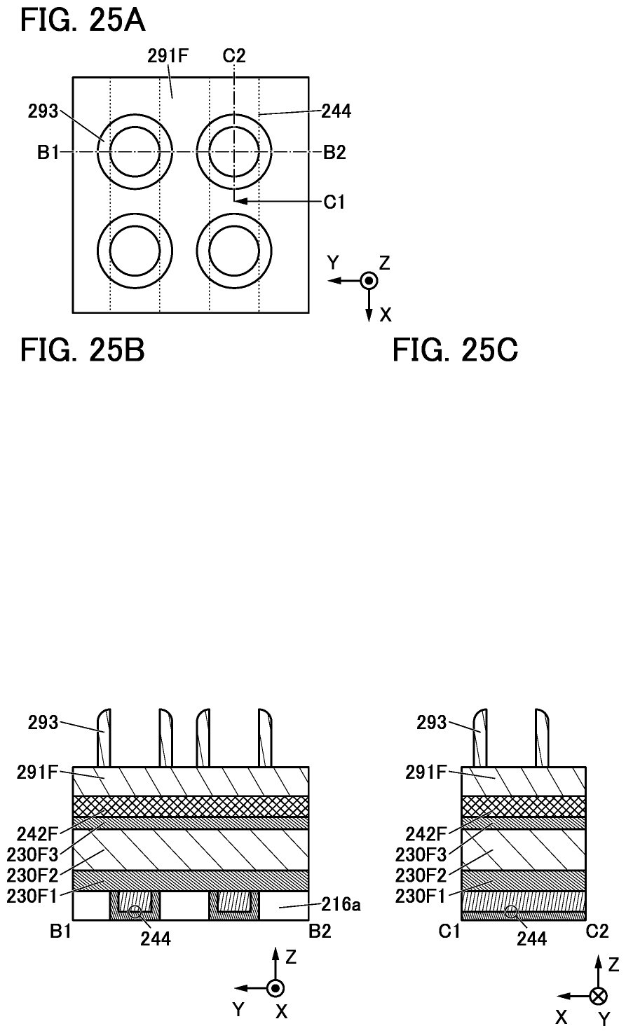

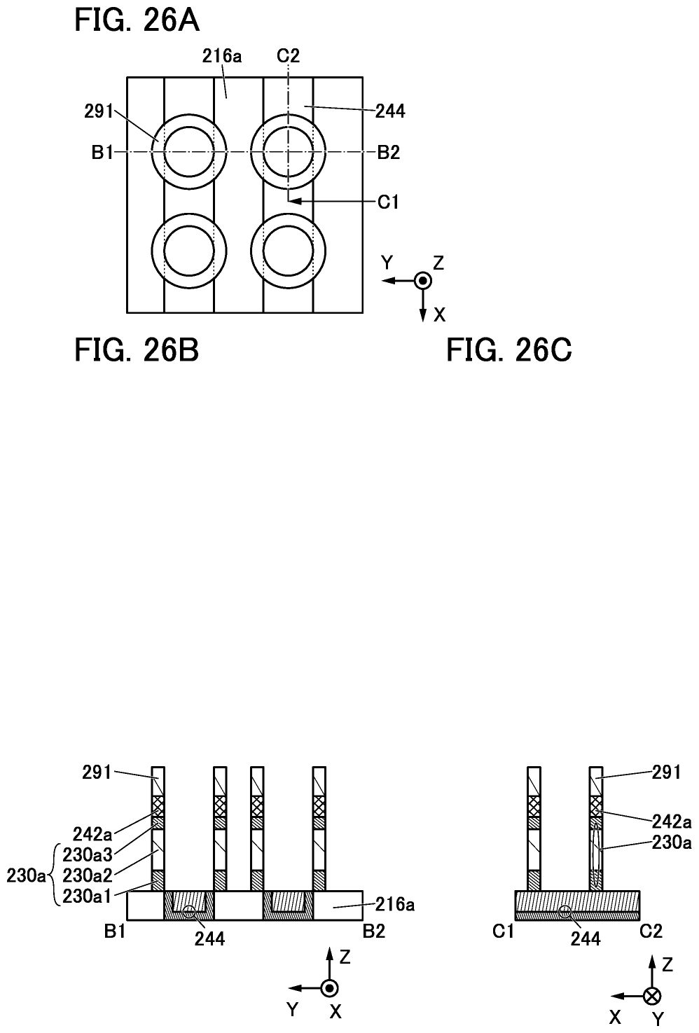

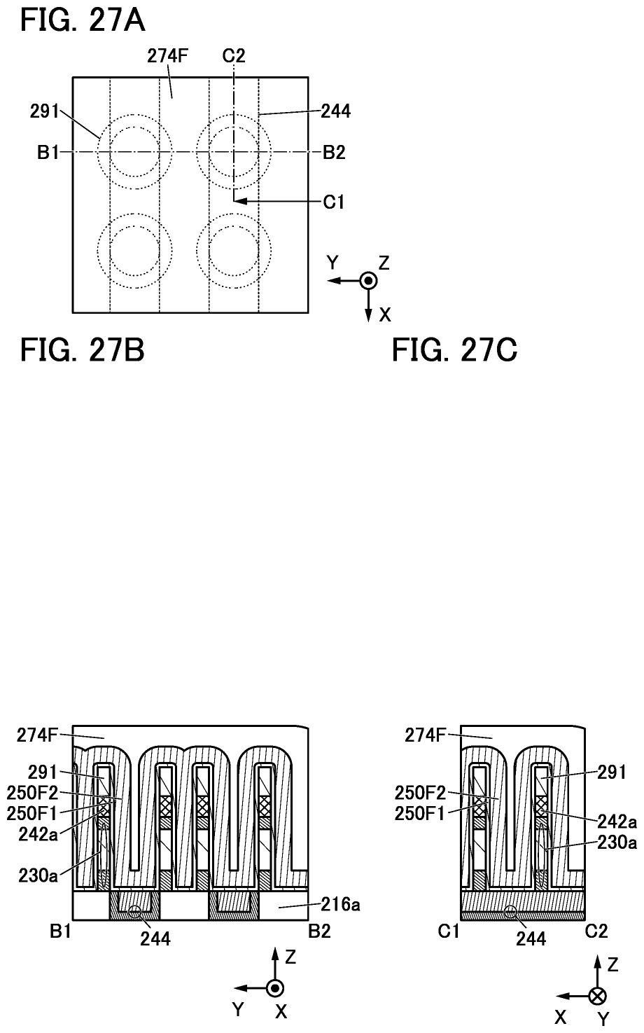

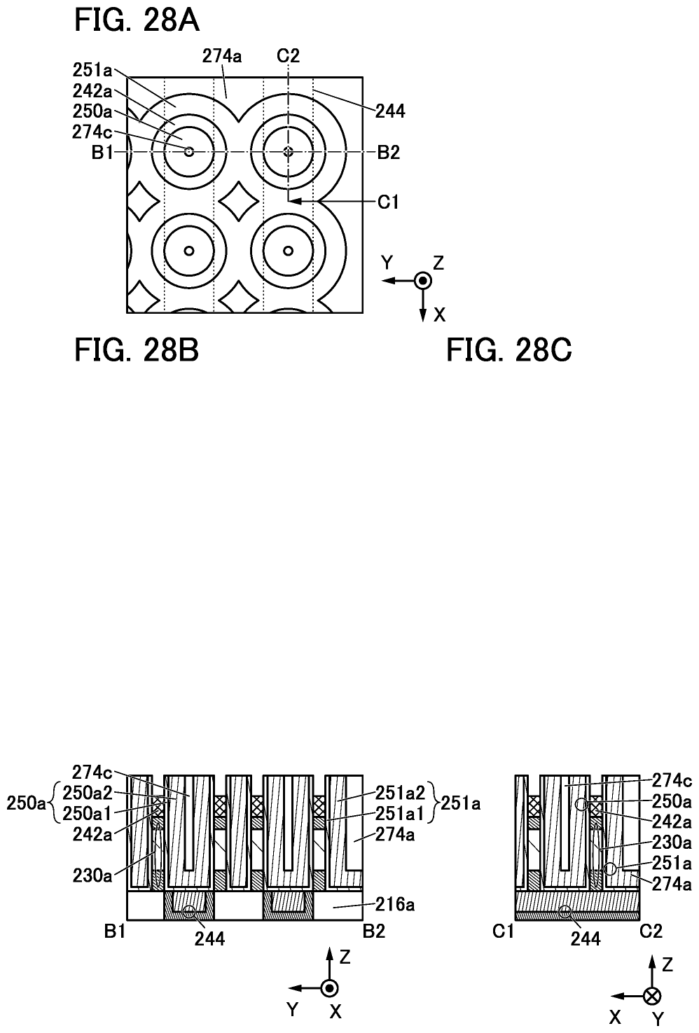

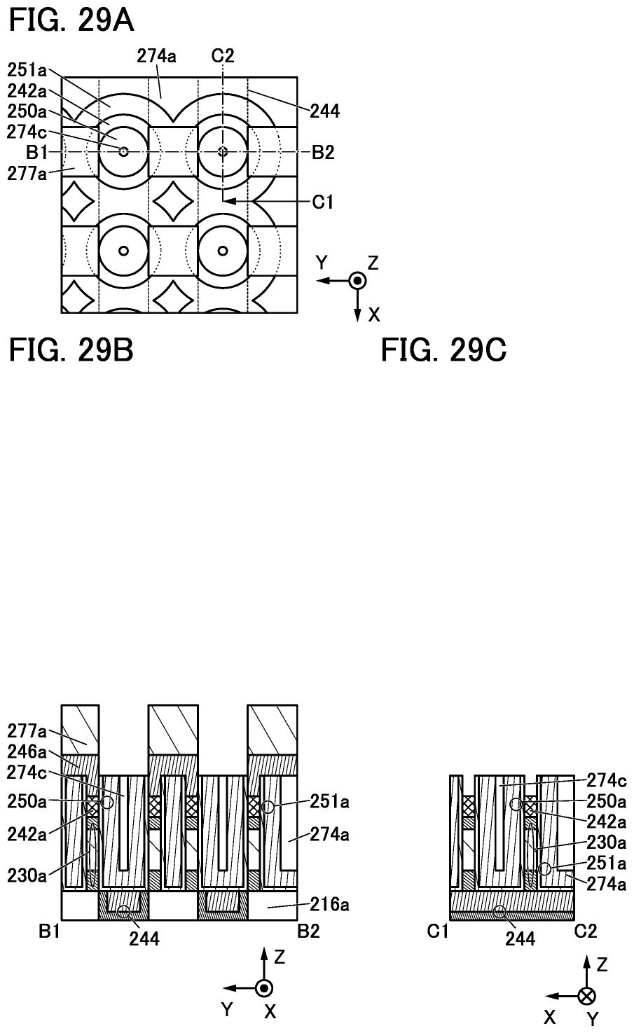

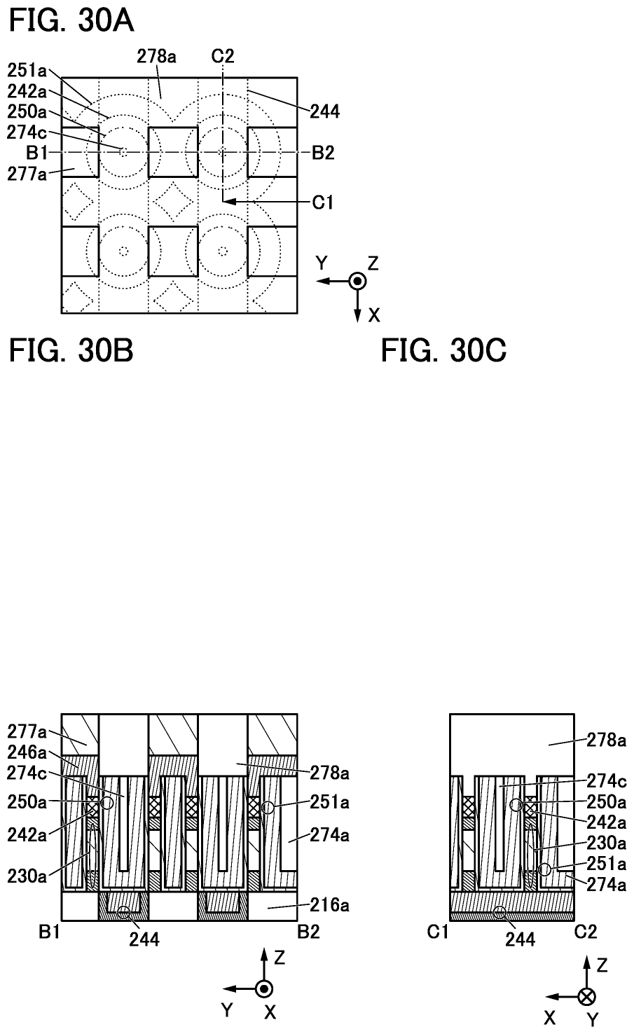

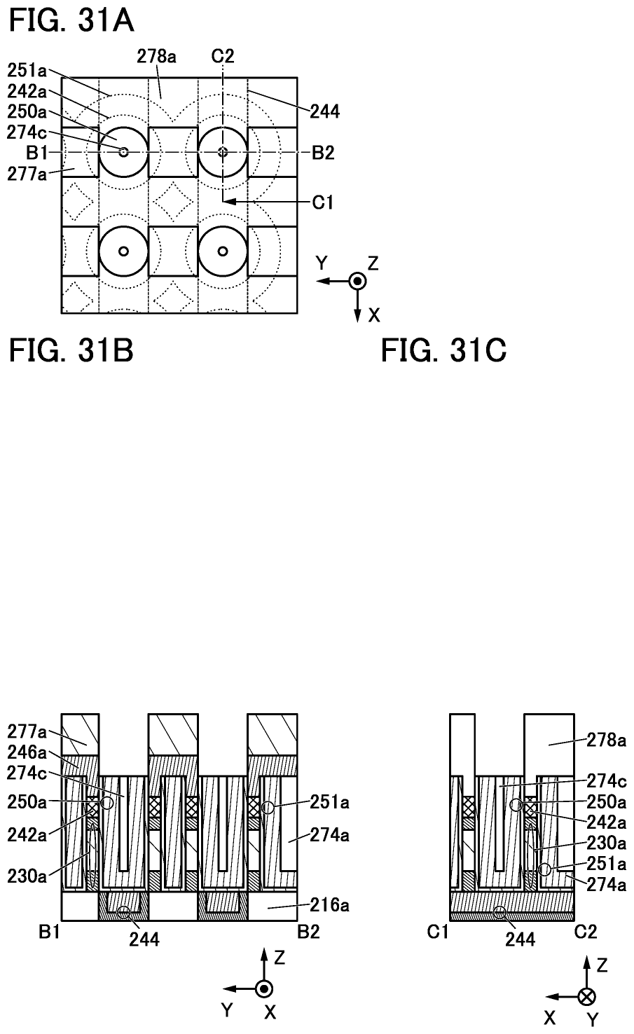

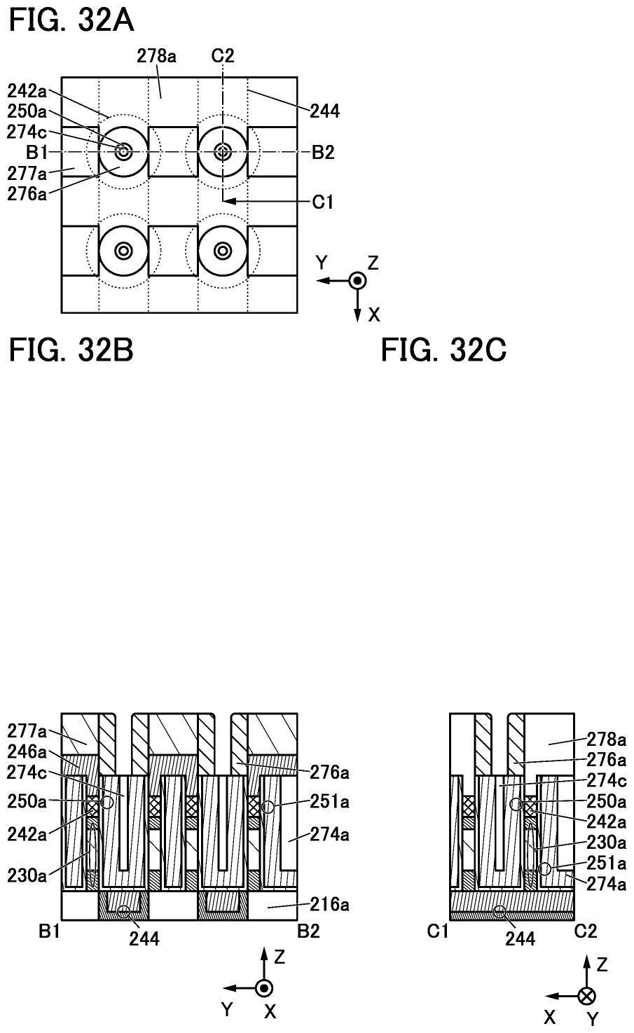

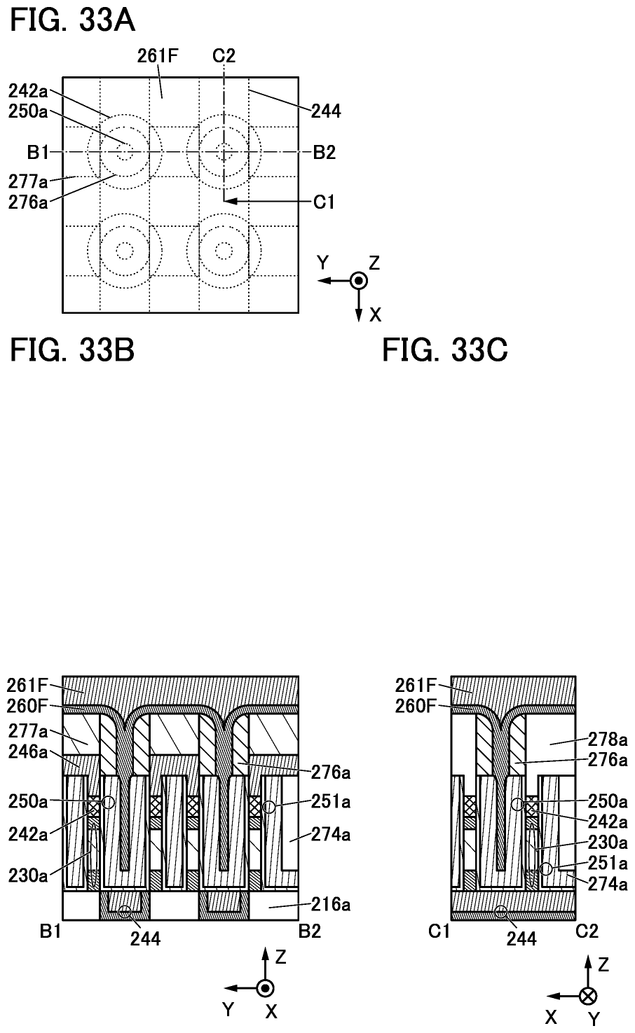

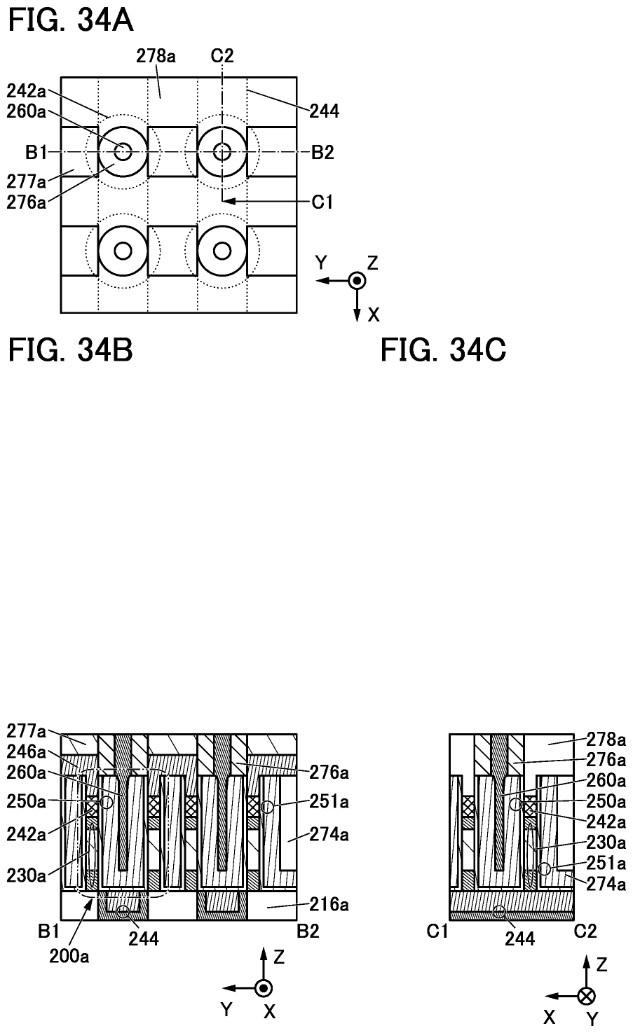

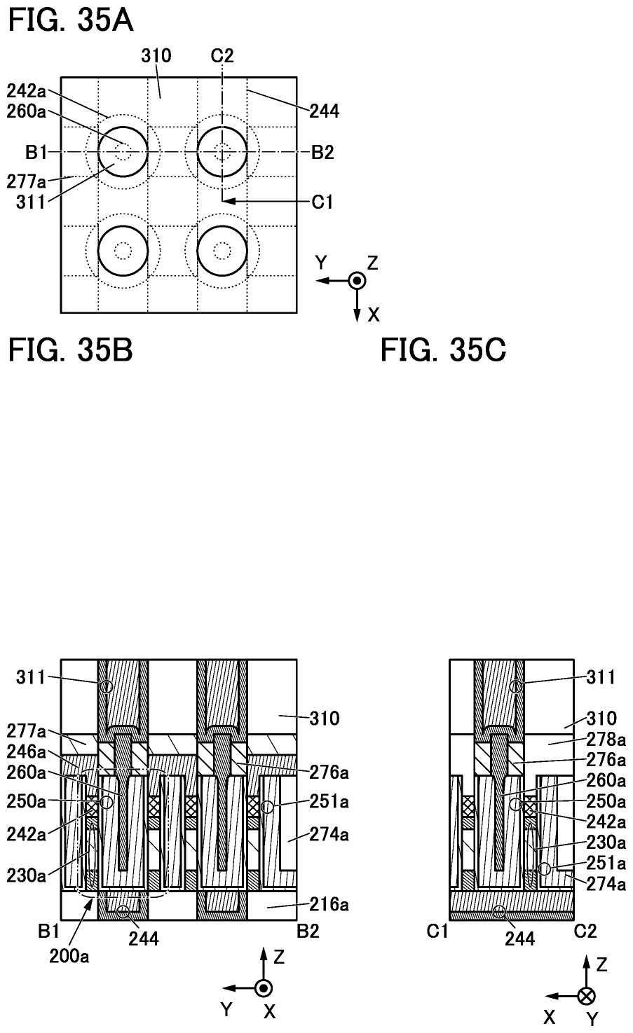

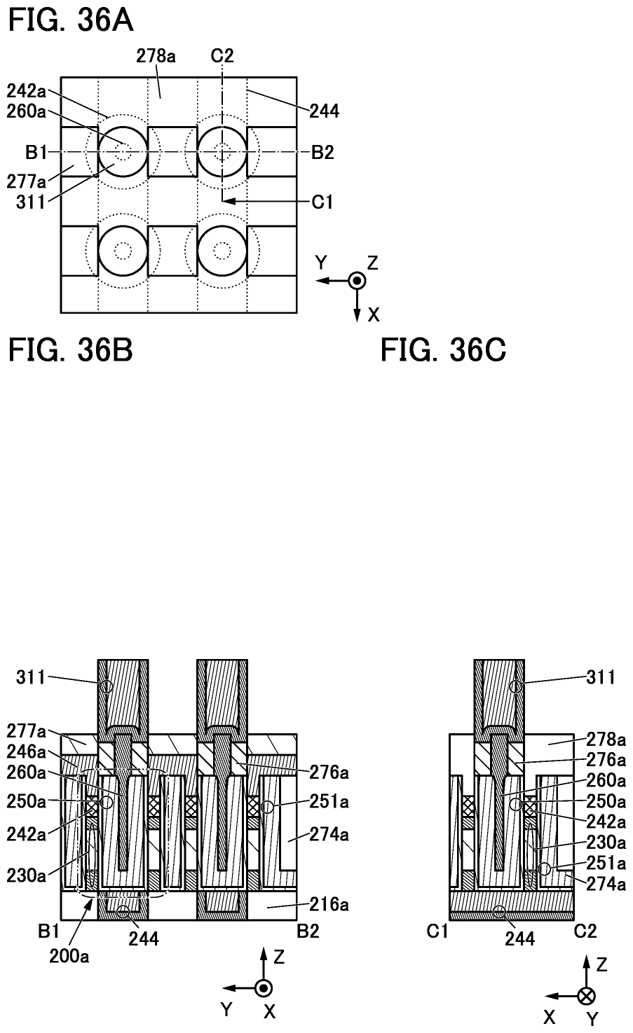

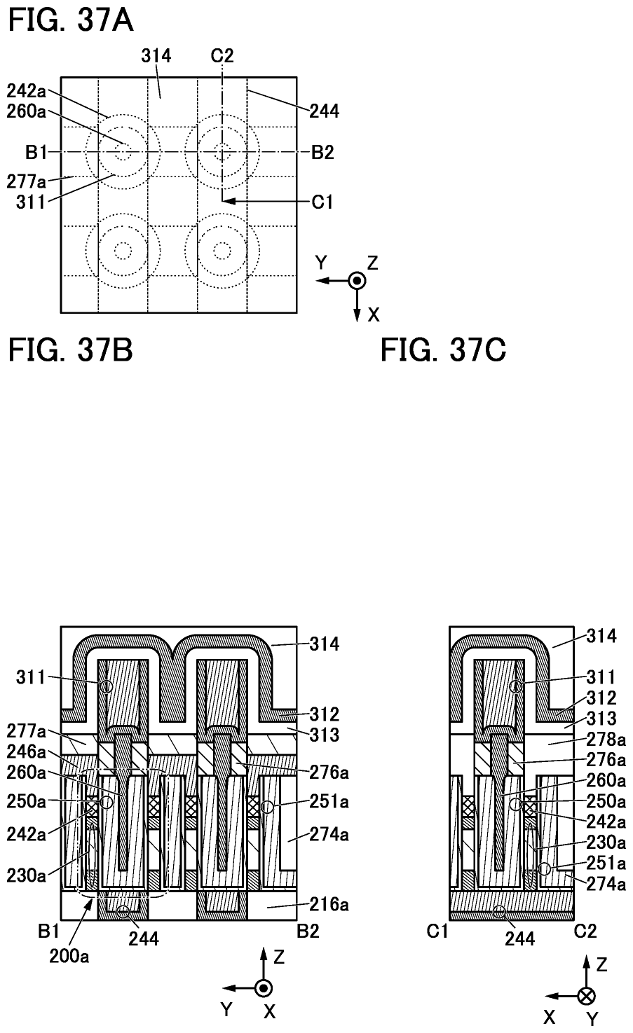

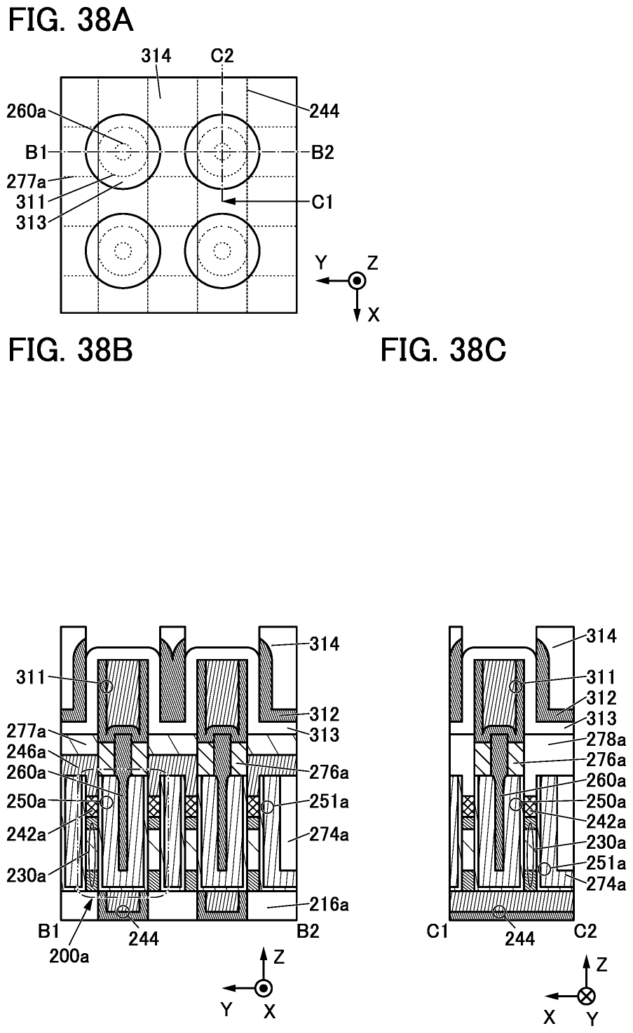

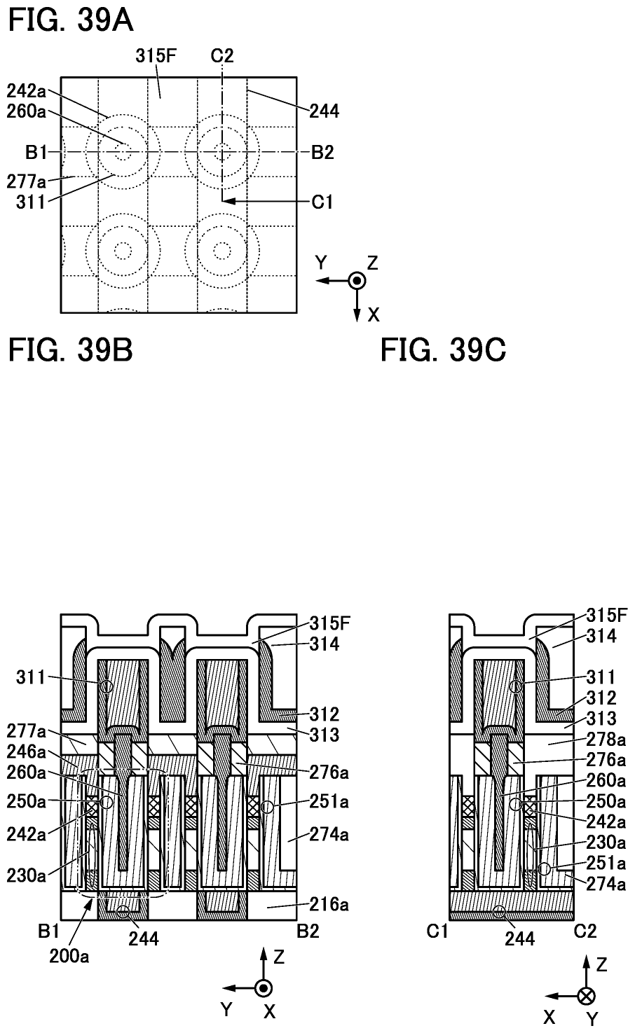

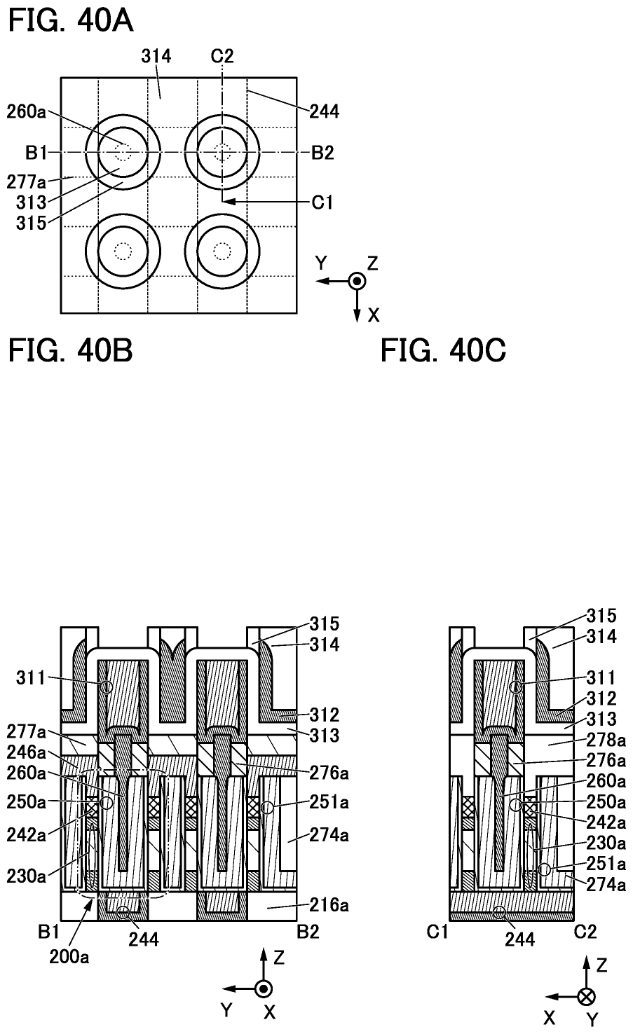

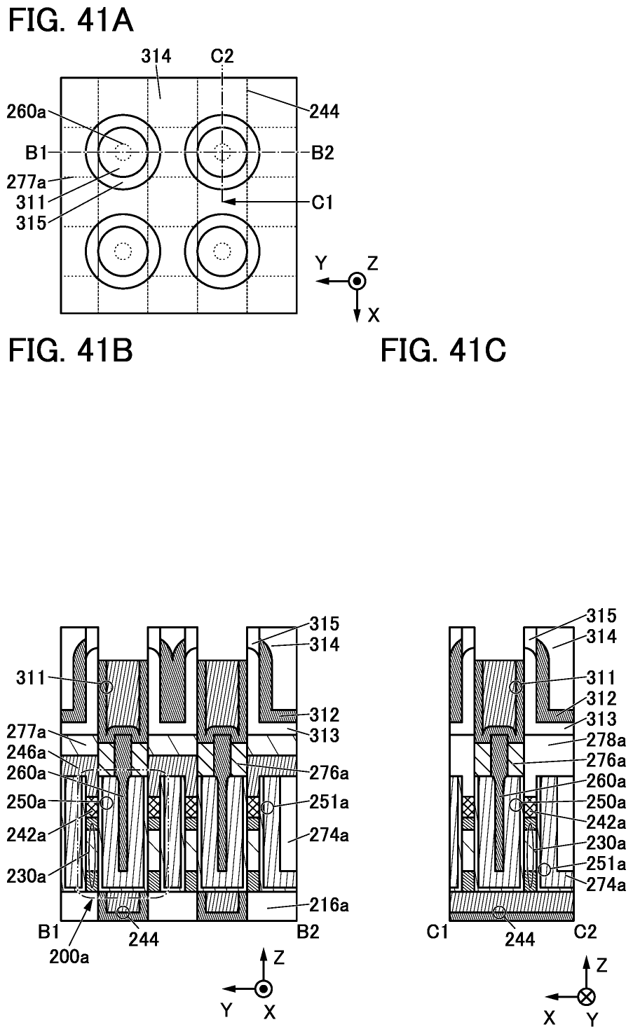

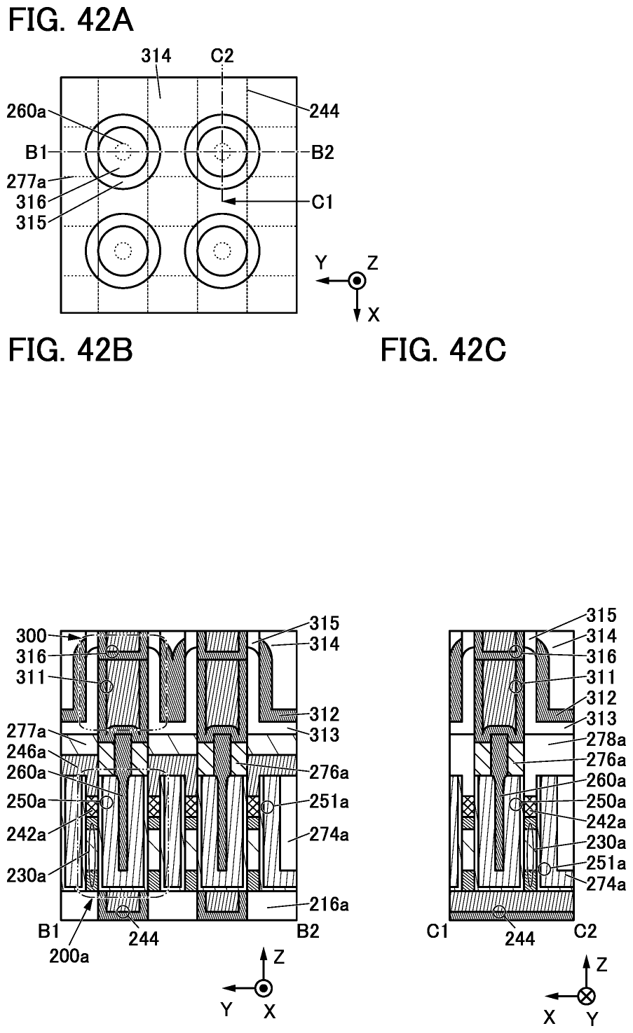

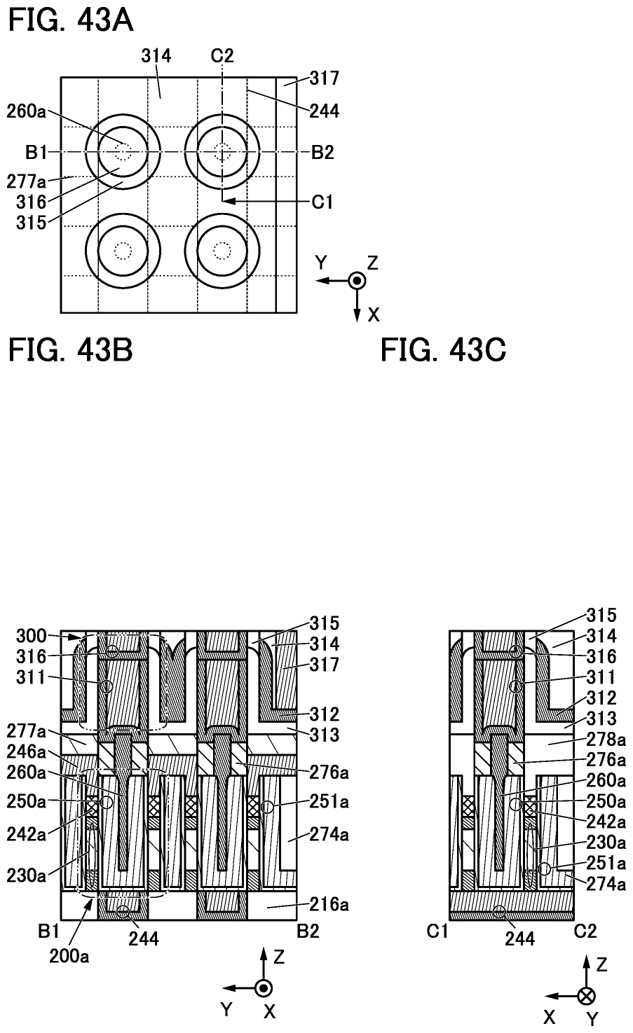

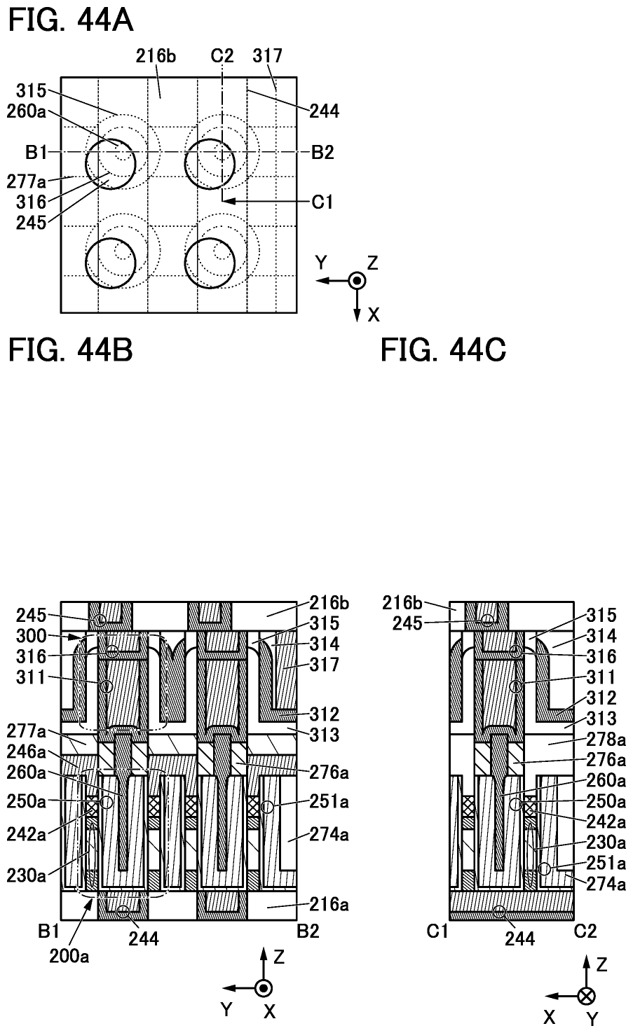

In FIG. 24A to FIG. 44C, FIG. 24A, FIG. 25A, FIG. 26A, FIG. 27A, FIG. 28A, FIG. 29A, FIG. 30A, FIG. 31A, FIG. 32A, FIG. 33A, FIG. 34A, FIG. 35A, FIG. 36A, FIG. 37A, FIG. 38A, FIG. 39A, FIG. 40A, FIG. 41A, FIG. 42A, FIG. 43A, and FIG. 44A are plan views. FIG. 24B, FIG. 25B, FIG. 26B, FIG. 27B, FIG. 28B, FIG. 29B, FIG. 30B, FIG. 31B, FIG. 32B, FIG. 33B, FIG. 34B, FIG. 35B, FIG. 36B, FIG. 37B, FIG. 38B, FIG. 39B, FIG. 40B, FIG. 41B, FIG. 42B, FIG. 43B, and FIG. 44B are cross-sectional views taken along dashed-dotted lines B1-B2 in FIG. 24A, FIG. 25A, FIG. 26A, FIG. 27A, FIG. 28A, FIG. 29A, FIG. 30A, FIG. 31A, FIG. 32A, FIG. 33A, FIG. 34A, FIG. 35A, FIG. 36A, FIG. 37A, FIG. 38A, FIG. 39A, FIG. 40A, FIG. 41A, FIG. 42A, FIG. 43A, and FIG. 44A, respectively. FIG. 24C, FIG. 25C, FIG. 26C, FIG. 27C, FIG. 28C, FIG. 29C, FIG. 30C, FIG. 31C, FIG. 32C, FIG. 33C, FIG. 34C, FIG. 35C, FIG. 36C, FIG. 37C, FIG. 38C, FIG. 39C, FIG. 40C, FIG. 41C, FIG. 42C, FIG. 43C, and FIG. 44C are cross-sectional views taken along dashed-dotted lines C1-C2 in FIG. 24A, FIG. 25A, FIG. 26A, FIG. 27A, FIG. 28A, FIG. 29A, FIG. 30A, FIG. 31A, FIG. 32A, FIG. 33A, FIG. 34A, FIG. 35A, FIG. 36A, FIG. 37A, FIG. 38A, FIG. 39A, FIG. 40A, FIG. 41A, FIG. 42A, FIG. 43A, and FIG. 44A, respectively.

In the following steps, an insulating material for forming an insulator, a conductive material for forming a conductor, and a semiconductor material for forming a semiconductor can be deposited by a plating method, a sputtering method, a CVD method, an MBE method, a PLD method, an ALD method, or the like as appropriate.

Examples of the sputtering method include an RF sputtering method in which a high-frequency power source is used for a sputtering power supply and a DC sputtering method in which a DC power source is used. The DC sputtering method includes a pulsed DC sputtering method in which a voltage is applied while being changed in a pulsed manner. The RF sputtering method is mainly used in the case where an insulating film is deposited, and the DC sputtering method is mainly used in the case where a metal conductive film is deposited. The pulsed DC sputtering method is mainly used in the case where a compound such as an oxide, a nitride, or a carbide is deposited by a reactive sputtering method.

Note that CVD methods can be classified into a plasma enhanced CVD (PECVD) method using plasma, a thermal CVD (TCVD) method using heat, a photo CVD method using light, and the like. Moreover, CVD methods can be classified into a metal CVD (MCVD) method and a metal organic CVD (MOCVD) method according to a source gas.

A high-quality film can be obtained at a relatively low temperature through a PECVD method. A thermal CVD method does not use plasma and thus causes less plasma damage to an object. For example, a wiring, an electrode, an element (e.g., a transistor or a capacitor), or the like included in a semiconductor device may be charged up by receiving charge from plasma. In that case, accumulated charge may break the wiring, electrode, element, or the like included in the semiconductor device. A thermal CVD method, which does not use plasma, does not cause such plasma damage, and thus can increase the yield of the semiconductor device. A thermal CVD method yields a film with few defects because of no plasma damage during deposition.

As the ALD method, a thermal ALD method, in which a precursor and a reactant react with each other only by a thermal energy, a PEALD method, in which a reactant excited by plasma is used, and the like can be used.

Methods of CVD and ALD differ from a sputtering method by which particles ejected from a target or the like are deposited. Thus, a CVD method and an ALD method can provide good step coverage, almost regardless of the shape of an object. In particular, an ALD method allows excellent step coverage and excellent thickness uniformity and can be suitably used to cover a surface of an opening portion with a high aspect ratio, for example. Note that an ALD method has a relatively low deposition rate; hence, in some cases, an ALD method is preferably combined with another deposition method with a high deposition rate, such as a CVD method.

By a CVD method, a film with a certain composition can be deposited by adjusting the flow rate ratio of the source gases. For example, a CVD method enables a film with a gradually-changed composition to be deposited by changing the flow rate ratio of the source gases during deposition. In the case where a film is deposited while the flow rate ratio of the source gases is changed, as compared to the case where a film is deposited using a plurality of deposition chambers, the time taken for the deposition can be shortened because the time taken for transfer and pressure adjustment is omitted. Hence, the productivity of the semiconductor device can be improved in some cases.

An ALD method, with which a plurality of different kinds of precursors are introduced at a time, enables deposition of a film with desired composition. In the case where a plurality of different kinds of precursors are introduced, the cycle number of precursor deposition is controlled, whereby a film with desired composition can be deposited.

First, a substrate (not illustrated) is prepared, and the insulator 216a is deposited over the substrate. The insulator 216a is preferably deposited by a sputtering method. Since a molecule containing hydrogen is not used for a deposition gas in the sputtering method, the concentration of hydrogen in the insulator 216a can be reduced.

In this embodiment, as the insulator 216a, a silicon oxide film is deposited by a pulsed DC sputtering method using a silicon target in an atmosphere containing an oxygen gas. The use of the pulsed DC sputtering method can achieve more uniform film thickness and improve the sputtering rate, deposition rate, and film quality.

Then, an opening is formed in the insulator 216a. Examples of the opening include a groove and a slit. A region where the opening is formed may be referred to as an opening portion. Wet etching can be used for the formation of the opening; however, dry etching is preferable for microfabrication.

As a dry etching apparatus, a capacitively coupled plasma (CCP) etching apparatus including parallel plate electrodes can be used. The capacitively coupled plasma etching apparatus including parallel plate electrodes may have a structure in which a high-frequency voltage is applied to one of the parallel plate electrodes. Alternatively, different high-frequency voltages may be applied to one of the parallel plate electrodes. Further alternatively, high-frequency voltages with the same frequency may be applied to the parallel plate electrodes. Still further alternatively, high-frequency voltages with different frequencies may be applied to the parallel plate electrodes. A dry etching apparatus including a high-density plasma source can be used. As the dry etching apparatus including a high-density plasma source, an inductively coupled plasma (ICP) etching apparatus can be used, for example.

Note that an insulator that functions as an etching stopper film used in forming the opening by etching the insulator 216a is preferably provided in contact with the bottom surface of the insulator 216a. For example, in the case where silicon oxide or silicon oxynitride is used as the insulator 216a in which the opening is to be formed, the insulator that functions as an etching stopper film is preferably silicon nitride, aluminum oxide, or hafnium oxide.

After the formation of the opening, a conductive film to be the conductor 244a is deposited. The conductive film preferably contains a conductor that has a function of inhibiting the passage of oxygen. For example, tantalum nitride, tungsten nitride, or titanium nitride can be used. Alternatively, a stacked-layer film of the conductor that has a function of inhibiting the passage of oxygen and tantalum, tungsten, titanium, molybdenum, aluminum, copper, or a molybdenum-tungsten alloy can be used.

In this embodiment, a titanium nitride film is deposited as the conductive film to be the conductor 244a. When such a metal nitride is provided under the conductor 244b described later, oxidation of the conductor 244b by the insulator 216a or the like can be inhibited. Furthermore, even when a metal that easily diffuses, such as copper, is used as the conductor 244b, the metal can be prevented from diffusing to the outside through the conductor 244a.

Next, a conductive film to be the conductor 244b is deposited. The conductive film can be deposited using tantalum, tungsten, titanium, molybdenum, aluminum, copper, a molybdenum-tungsten alloy, or the like. In this embodiment, a tungsten film is deposited as the conductive film.

Next, the conductive film to be the conductor 244a and the conductive film to be the conductor 244b are partly removed by CMP treatment to expose the insulator 216a. As a result, the conductor 244a and the conductor 244b remain only in the opening portion formed in the insulator 216a, so that the conductor 244 (the conductor 244a and the conductor 244b) is formed. Note that the insulator 216a is partly removed by the CMP treatment in some cases.

Next, an oxide film 230F1, an oxide film 230F2, and an oxide film 230F3 are deposited in this order over the insulator 216a and the conductor 244 (see FIGS. 24A to 24C). Note that it is preferable to deposit the oxide film 230F1, the oxide film 230F2, and the oxide film 230F3 successively without exposure to the air. By the deposition without exposure to the air, impurities or moisture from the air can be prevented from being attached to the top surfaces of the oxide film 230F1 and the oxide film 230F2, so that an interface between the oxide film 230F1 and the oxide film 230F2 and the vicinity of the interface and an interface between the oxide film 230F2 and the oxide film 230F3 and the vicinity of the interface can be kept clean.

For example, in the case where the oxide films 230F1, 230F2, and 230F3 are deposited by a sputtering method, oxygen or a mixed gas of oxygen and a noble gas is used as a sputtering gas. An increase in the proportion of oxygen in the sputtering gas can increase the amount of excess oxygen contained in the oxide film to be deposited. Moreover, when the oxide films are deposited by a sputtering method, a target of the In-M-Zn oxide or the like can be used.

Note that in the case where a metal oxide film to which nitrogen is added is deposited by a sputtering method as each of the oxide films 230F1 and 230F3, even if a target does not contain nitrogen, a metal oxide film to which nitrogen is added can be deposited by using a sputtering gas containing a nitrogen gas. In the case where a metal oxide film is deposited by adding a nitrogen gas, the higher the nitrogen flow rate ratio is, the higher the carrier mobility of the metal oxide film can be.

The nitrogen flow rate ratio can be set as appropriate in a range of 10% to 100% in accordance with characteristics needed for the oxide 230al and the oxide 230a3. At this time, for example, the sputtering gas can be a mixed gas of a nitrogen gas and an argon gas. The sputtering gas may be a mixed gas of a nitrogen gas and an oxygen gas or a mixed gas of a nitrogen gas, an oxygen gas, and an argon gas.

Note that in the case where a target including nitrogen is used as a sputtering target, even a sputtering gas including no nitrogen can be used to deposit a metal oxide film to which nitrogen is added.

In the case where the sputtering gas for the oxide film 230F1 contains an oxygen gas, part of oxygen contained in the sputtering gas may be supplied to the insulator 216a. Therefore, the proportion of oxygen in the sputtering gas may be 70% or higher, preferably 80% or higher, further preferably 100%.

The sputtering gas preferably has high purity. For example, as an oxygen gas, a nitrogen gas, or an argon gas used for a sputtering gas, a gas which is highly purified to have a dew point of −40° C. or lower, preferably −80° C. or lower, further preferably −100° C. or lower, still further preferably −120° C. or lower is used, whereby entry of moisture and the like into the metal oxide film can be minimized.

When the oxide film 230F2 is formed by a sputtering method and the proportion of oxygen in the sputtering gas is higher than 30% and lower than or equal to 100%, preferably higher than or equal to 70% and lower than or equal to 100%, an oxygen-excess oxide semiconductor is formed. A transistor including an oxygen-excess oxide semiconductor in a channel formation region can have relatively high reliability. However, one embodiment of the present invention is not limited thereto. When the oxide film 230F2 is formed by a sputtering method and the proportion of oxygen in the sputtering gas is higher than or equal to 1% and lower than or equal to 30%, preferably higher than or equal to 5% and lower than or equal to 20%, an oxygen-deficient oxide semiconductor is formed. A transistor including an oxygen-deficient oxide semiconductor in a channel formation region can have relatively high field-effect mobility. In addition, when the oxide film is deposited while the substrate is being heated, the crystallinity of the oxide film can be improved.

The method for depositing the oxide film 230F1 can be referred to for the method for depositing the oxide film 230F3.

Note that the oxide films 230F1, 230F2, and 230F3 are preferably deposited by a sputtering method without exposure to the air. For example, a multi-chamber deposition apparatus is used. In this manner, hydrogen can be inhibited from entering the oxide films 230F1, 230F2, and 230F3 between deposition steps.

In the case where a metal oxide film to which nitrogen is added is deposited as each of the oxide films 230F1 and 230F3 by a sputtering method and a metal oxide film is deposited as the oxide film 230F2 by a sputtering method, after the oxide film 230F1 is deposited, the kinds of gases introduced into a sputtering apparatus are switched, i.e., introduction of nitrogen is stopped, and then the oxide film 230F2 is deposited. Furthermore, after the oxide film 230F2 is deposited, the kinds of gases introduced into the sputtering apparatus are switched, i.e., introduction of nitrogen is restarted, and then the oxide film 230F3 is deposited. Thus, the oxide film 230F1, the oxide film 230F2, and the oxide film 230F3 can be successively deposited, leading to high mass productivity.

In this embodiment, a metal oxide film to which nitrogen is added is deposited as each of the oxide films 230F1 and 230F3 by a sputtering method. In addition, the oxide film 230F2 is deposited by a sputtering method using an oxide target having an atomic ratio of In:Ga:Zn=4:2:4.1, 1:1:1, 1:1:1.2, or 1:1:2. Note that each of the oxide films can be formed to have characteristics required for the oxide 230al, the oxide 230a2, and the oxide 230a3 by selecting the deposition conditions and the atomic ratios as appropriate.

Next, heat treatment is preferably performed. The heat treatment is performed at a temperature higher than or equal to 250° C. and lower than or equal to 650° C., preferably higher than or equal to 400° C. and lower than or equal to 600° C. so that the oxide films 230F1, 230F2, and 230F3 do not become polycrystal. Note that the heat treatment is performed in a nitrogen gas atmosphere, an inert gas atmosphere, or an atmosphere containing an oxidizing gas at 10 ppm or more, 1% or more, or 10% or more. For example, in the case where the heat treatment is performed in an atmosphere of mixing a nitrogen gas and an oxygen gas, the proportion of the oxygen gas is preferably approximately 20%. The heat treatment may be performed under a reduced pressure. Alternatively, it is also possible that heat treatment is performed in an atmosphere of a nitrogen gas or an inert gas, and then another heat treatment is performed in an atmosphere containing an oxidizing gas at 10 ppm or more, 1% or more, or 10% or more in order to compensate for released oxygen.

The gas used in the above heat treatment preferably has high purity. For example, the amount of moisture contained in the gas used in the above heat treatment can be 1 ppb or less, preferably 0.1 ppb or less, further preferably 0.05 ppb or less. The heat treatment using a highly purified gas can prevent the entry of moisture or the like into the oxide films 230F1, 230F2, and 230F3 and the like as much as possible.

In this embodiment, heat treatment at 400° C. for one hour is performed with a flow rate ratio of a nitrogen gas to an oxygen gas that is 4:1. With the heat treatment using the above-described oxygen gas, impurities such as carbon, water, and hydrogen in the oxide film 230F2 can be reduced. Impurities in the film are reduced in the above manner, whereby the crystallinity of the oxide film 230F2 can be improved and a dense structure can be obtained. Accordingly, the crystal region in the oxide film 230F2 can be increased, and an in-plane variation in the oxide film 230F2 can be reduced. Thus, an in-plane variation in electrical characteristics of the transistor can be reduced.

Performing the heat treatment can reduce the hydrogen concentration in the insulator 216a and the oxide film 230F2. In particular, the oxide 230a2 formed using the oxide film 230F2 functions as the channel formation region of the transistor 200a. Thus, the transistor 200a preferably includes the oxide 230a2 with a reduced hydrogen concentration because favorable reliability can be obtained.

Next, a conductive film 242F is deposited over the oxide film 230F3 (see FIG. 24A to FIG. 24C). For example, a tantalum nitride film can be deposited as the conductive film 242F by a sputtering method. Note that heat treatment may be performed before the deposition of the conductive film 242F. The heat treatment may be performed under a reduced pressure, and the conductive film 242F may be successively deposited without exposure to the air. By such treatment, moisture and hydrogen adsorbed on the surface of the oxide film 230F3 can be removed, and the moisture concentration and the hydrogen concentration in the oxide films 230F1, 230F2, and 230F3 can be reduced. The temperature of the heat treatment is preferably higher than or equal to 100° C. and lower than or equal to 400° C. In this embodiment, the temperature of the heat treatment is 200° C.

Next, an insulating film 291F is deposited over the conductive film 242F (see FIG. 24A to FIG. 24C). The insulating film 291F is preferably an insulating film having a function of inhibiting the passage of oxygen. For example, an aluminum oxide film or a silicon nitride film can be deposited as the insulating film 291F by a sputtering method.

Note that the conductive film 242F and the insulating film 291F are preferably deposited by a sputtering method without exposure to the air. For example, a multi-chamber deposition apparatus is used. As a result, the amount of hydrogen in the deposited conductive film 242F and insulating film 291F can be reduced, and furthermore, entry of hydrogen in the films between deposition steps can be inhibited. In the case where a hard mask is provided over the insulating film 291F, a film to be the hard mask may be successively deposited without exposure to the air.

Next, the oxide film 230F1, the oxide film 230F2, the oxide film 230F3, the conductive film 242F, and the insulating film 291F are processed into hollow cylindrical shapes by a lithography method, so that the oxide 230a (the oxide 230al, the oxide 230a2, and the oxide 230a3), the conductor 242a, and an insulator 291 are formed. Here, the oxide 230al, the oxide 230a2, the oxide 230a3, the conductor 242a, and the insulator 291 are formed to overlap with the conductor 244 at least partly. The processing can be performed by a dry etching method or a wet etching method.

In the lithography method, first, a resist is exposed to light through a mask. Next, a region exposed to light is removed or left using a developing solution, so that a resist mask is formed. Then, etching is conducted with the resist mask, whereby a conductor, a semiconductor, an insulator, or the like can be processed into a desired shape. The resist mask can be formed, for example, by exposing the resist to KrF excimer laser light, ArF excimer laser light, or EUV light. A liquid immersion technique may be employed in which a portion between a substrate and a projection lens is filled with a liquid (e.g., water) to perform light exposure. An electron beam or an ion beam may be used instead of the above-mentioned light. Note that a photomask is not necessary in the case of using an electron beam or an ion beam. To remove the resist mask, dry etching treatment such as ashing or wet etching treatment can be used. Alternatively, wet etching treatment can be performed after dry etching treatment, or dry etching treatment can be performed after wet etching treatment.

A hard mask formed of an insulator or a conductor may be used under the resist mask. In the case of using a hard mask, a hard mask with a desired shape can be formed in the following manner: an insulating film or a conductive film that is the material of the hard mask is formed over the conductive film 242F, a resist mask is formed thereover, and then the hard mask material is etched. The etching of the conductive film 242F and the like may be performed after or without removal of the resist mask. In the latter case, the resist mask sometimes disappears during the etching. The hard mask may be removed by etching after the etching of the conductive film 242F and the like. The hard mask does not need to be removed when the hard mask material does not affect the following process or can be utilized in the following process. In this embodiment, the insulator 291 is used as a hard mask.

Hereinafter, an example of a method for forming the oxide 230a, the conductor 242a, and the insulator 291 each having a hollow cylindrical shape by a lithography method is described.

First, a resist mask 292 is formed over the insulating film 291F (see FIGS. 24A to 24C). At least part of the resist mask 292 is provided in a region overlapping with the conductor 244.

Note that although the top surface of the resist mask 292 has a circular shape, the present invention is not limited thereto. For example, the top surface may have an elliptical shape or a polygonal shape such as a triangular shape or a quadrangular shape. When the top surface has a polygonal shape, corners thereof may be rounded.

A resist is exposed to light through a mask, and then a region exposed to light is removed or left using a developing solution, so that the resist mask 292 can be formed, for example. The resist mask 292 may be shrunk by anisotropic etching using oxygen plasma. Shrinkage of the resist mask is referred to as resist slimming or resist trimming in some cases. By being shrunk, the resist mask 292 can be miniaturized.

Alternatively, the resist mask 292 may be formed in the following manner, for example: a resist is exposed to light through a mask with which a line pattern can be formed, the resist is exposed to light again through the mask that is rotated 90° around the Z axis, and a region exposed to light is removed or left using a developing solution. The top surface of the resist mask 292 processed in such a manner has a shape with rounded corners or a circular shape.

The above-described multi-patterning technique is preferably employed for forming the resist mask 292. The resist mask 292 may be formed in the following manner, for example: a line-patterned resist mask extending in the X direction is formed by the multi-patterning technique, and then a line-patterned resist mask extending in the Y direction is formed by the multi-patterning technique so that the line-patterned resist mask extending in the X direction is processed. The top surface of the resist mask 292 processed in such a manner has a shape with rounded corners or a circular shape.

Next, an insulating film 293F is deposited over the resist mask 292 (see FIGS. 24A to 24C). The thickness of the insulating film 293F corresponds to the width H1 in FIG. 23A. Thus, the thickness of the insulating film 293F can be set as appropriate in accordance with the design of the transistor 200.

Next, the insulating film 293F is subjected to anisotropic etching to form an insulator 293. For the anisotropic etching of the insulating film 293F, for example, a dry etching method is employed. The insulating film 293F is subjected to anisotropic etching, whereby the insulator 293 is formed on the side surface of the resist mask 292. That is, the insulator 293 can be rephrased as a sidewall.

Next, the resist mask 292 is removed (see FIGS. 25A to 25C). After the resist mask 292 is removed, the insulator 293 remains over the insulating film 291F. Note that the top surface shape of the opening of the insulator 293 corresponds to the top surface shape of the resist mask 292. For example, in the case where the top surface of the resist mask 292 has a circular shape, the top surface of the insulator 293 has a hollow cylindrical shape as illustrated in FIG. 25A. In the case where the top surface of the resist mask 292 has the above-described elliptical shape, the top surface of the insulator 293 has a hollow elliptical shape. In the case where the top surface of the resist mask 292 has a polygonal shape with rounded corners, the top surface of the insulator 293 has a hollow polygonal shape with rounded corners.

Next, using the insulator 293 as a hard mask, part of the insulating film 291F, part of the conductive film 242F, part of the oxide film 230F3, part of the oxide film 230F2, and part of the oxide film 230F1 are processed until the top surfaces of the insulator 216a and the conductor 244 are exposed. The processing can be performed by a dry etching method or a wet etching method. A dry etching method is suitable for microfabrication. The insulating film 291F, the conductive film 242F, the oxide film 230F3, the oxide film 230F2, and the oxide film 230F1 may be processed under different conditions.

By the processing, the insulator 291, the conductor 242a, and the oxide 230a (the oxide 230al, the oxide 230a2, and the oxide 230a3) each having the same or substantially the same top surface shape as the insulator 293 are formed (see FIGS. 26A to 26C). That is, in the plan view, end portions of the insulator 291, the conductor 242a, and the oxide 230a are aligned with each other. The oxide 230a, the conductor 242a, and the insulator 291 each have a hollow cylindrical shape. As described above, the top surface shapes of the oxide 230a, the conductor 242a, and the insulator 291 correspond to the top surface shape of the resist mask 292. Thus, the hollow cylindrical shape can be rephrased as appropriate in accordance with the top surface shape of the resist mask 292.

The above is the example of a method for forming the oxide 230a, the conductor 242a, and the insulator 291 each having a hollow cylindrical shape by a lithography method.

Note that the side surfaces of the oxide 230a and the conductor 242a are preferably perpendicular to the top surface of the insulator 216a. With such a structure, a plurality of transistors 200a can be provided with high density in a small area.

Note that the present invention is not limited to the above structure. As described with reference to FIG. 19A, the side surfaces of the oxide 230a and the conductor 242a may each have a tapered shape. With such tapered side surfaces, the coverage with, for example, an insulating film to be the insulators 250a1 and 251a1 can be improved in a later step, so that the number of defects such as voids can be reduced.

Next, the insulator 293 is removed (see FIGS. 26A to 26C).

Through the above steps, in some cases, impurities are attached to the side surfaces of the oxide 230a, the conductor 242a, and the insulator 291 and diffuse therein. A step of removing the impurities may be performed. Examples of the impurities include hafnium, aluminum, silicon, tantalum, fluorine, and chlorine.

In order to remove the impurities attached to the side surface of the oxide 230a in the etching step, cleaning treatment may be performed. Examples of the cleaning include wet cleaning using a cleaning solution or the like (also referred to as wet etching treatment), plasma treatment using plasma, and cleaning by heat treatment, and any of these cleanings may be performed in combination as appropriate.

The wet cleaning may be performed using an aqueous solution in which ammonia water, oxalic acid, phosphoric acid, hydrofluoric acid, or the like is diluted with carbonated water or pure water; pure water; or carbonated water, for example. Alternatively, ultrasonic cleaning using such an aqueous solution, pure water, or carbonated water may be performed. Further alternatively, such cleaning methods may be performed in combination as appropriate.

Note that in this specification and the like, in some cases, an aqueous solution in which hydrofluoric acid is diluted with pure water is referred to as diluted hydrofluoric acid, and an aqueous solution in which ammonia water is diluted with pure water is referred to as diluted ammonia water. The concentration, temperature, and the like of the aqueous solution can be adjusted as appropriate in accordance with an impurity to be removed, the structure of a semiconductor device to be cleaned, or the like. The concentration of ammonia in the diluted ammonia water can be higher than or equal to 0.01% and lower than or equal to 5%, preferably higher than or equal to 0.1% and lower than or equal to 0.5%. The concentration of hydrogen fluoride in the diluted hydrofluoric acid can be higher than or equal to 0.01 ppm and lower than or equal to 100 ppm, preferably higher than or equal to 0.1 ppm and lower than or equal to 10 ppm.

A frequency greater than or equal to 200 kHz, preferably greater than or equal to 900 kHz is preferably used for the ultrasonic cleaning. Damage to the oxide 230a and the like can be reduced with this frequency.

The cleaning treatment may be performed plural times, and the cleaning solution may be changed in every cleaning treatment. For example, the first cleaning treatment may use diluted hydrofluoric acid or diluted ammonia water and the second cleaning treatment may use pure water or carbonated water.

After the etching or the cleaning, heat treatment may be performed. The heat treatment may be performed at a temperature higher than or equal to 100° C. and lower than or equal to 450° C., preferably higher than or equal to 350° C. and lower than or equal to 400° C. Note that the heat treatment is performed in a nitrogen gas atmosphere, an inert gas atmosphere, or an atmosphere containing an oxidizing gas at 10 ppm or more, 1% or more, or 10% or more. For example, the heat treatment is preferably performed in an oxygen atmosphere. Accordingly, oxygen can be supplied to the oxide 230a2 to reduce oxygen vacancies. In addition, the crystallinity of the oxide 230a2 can be improved by the heat treatment. The heat treatment may be performed under a reduced pressure. Alternatively, the heat treatment may be performed in such a manner that heat treatment is performed in an oxygen atmosphere, and then another heat treatment is successively performed in a nitrogen atmosphere without exposure to the air.

Note that the cleaning treatment and the heat treatment may be performed before the insulator 293 is removed.

Next, an insulating film 250F1 is deposited over the insulator 216a, the conductor 244, and the insulator 291 (see FIGS. 27A to 27C). In other words, the insulating film 250F1 is deposited to cover the oxide 230a, the conductor 242a, and the insulator 291.

The insulating film 250F1 is preferably deposited by an ALD method. As described above, it is preferable to deposit the insulating film 250F1 to have a small thickness, and an unevenness of the thickness needs to be reduced. In the ALD method, a precursor and a reactant (such as oxidizer) are alternately introduced to deposit a film, and the film thickness can be adjusted by the number of repetition times of the sequence of the gas introduction; thus, accurate control of the film thickness is possible. Furthermore, as illustrated in FIGS. 27A to 27C, the insulating film 250F1 needs to be deposited on the side surface of the opening formed in the oxide 230a, the conductor 242a, and the insulator 291, the outer side surfaces of the oxide 230a, the conductor 242a, and the insulator 291, and the top surfaces of the conductor 244 and the insulator 216a so as to have good coverage. In particular, it is preferable that the insulating film 250F1 be deposited on the side surfaces of the oxide 230a and the conductor 242a so as to have good coverage. In the ALD method, one atomic layer can be deposited at a time on the bottom and side surfaces of the opening, whereby the insulating film 250F1 can be deposited in the opening with good coverage.

When the insulating film 250F1 is deposited by an ALD method, ozone (O₃), oxygen (O₂), water (H₂O), or the like is used as the oxidizer. When an oxidizer without hydrogen, such as ozone (O₃) or oxygen (O₂), is used, the amount of hydrogen diffusing into the oxide 230a can be reduced.

The insulating film 250F1 is preferably an insulating film having a function of inhibiting the passage of oxygen. As the insulating film 250F1, for example, an aluminum oxide film can be deposited by an ALD method. In this manner, the oxide 230a and the conductor 242a can be covered with the insulating film 250F1 having a function of inhibiting diffusion of oxygen. This can inhibit direct diffusion of oxygen from the insulator 274a and the like into the oxide 230a and the conductor 242a in a later step.

Next, microwave treatment may be performed in an atmosphere containing oxygen. Here, the microwave treatment refers to, for example, treatment using an apparatus including a power source for generating high-density plasma using microwaves. In this specification and the like, a microwave refers to an electromagnetic wave having a frequency greater than or equal to 300 MHz and less than or equal to 300 GHz.

The microwave treatment is preferably performed with a microwave treatment apparatus including a power source for generating high-density plasma using microwaves, for example. Here, the frequency of the microwave treatment apparatus can be set to greater than or equal to 300 MHz and less than or equal to 300 GHz, preferably greater than or equal to 2.4 GHz and less than or equal to 2.5 GHZ, for example, 2.45 GHz. Oxygen radicals at a high density can be generated with high-density plasma. The electric power of the power source that applies microwaves of the microwave treatment apparatus can be set to higher than or equal to 1000 W and lower than or equal to 10000 W, preferably higher than or equal to 2000 W and lower than or equal to 5000 W. A power source may be provided to the microwave treatment apparatus to apply RF to the substrate side. Furthermore, application of RF to the substrate side allows oxygen ions generated by the high-density plasma to permeate the oxide 230a2 efficiently.

The microwave treatment is preferably performed under reduced pressure, and the pressure can be higher than or equal to 10 Pa and lower than or equal to 1000 Pa, preferably higher than or equal to 300 Pa and lower than or equal to 700 Pa. The treatment temperature can be lower than or equal to 750° C., preferably lower than or equal to 500° C., and can be approximately 400° C., for example. The oxygen plasma treatment may be followed successively by heat treatment without exposure to air. For example, the temperature can be higher than or equal to 100° C. and lower than or equal to 750° C., preferably higher than or equal to 300° C. and lower than or equal to 500° C.

Furthermore, the microwave treatment is performed using an oxygen gas and an argon gas, for example. Here, the oxygen flow rate ratio (O₂/(O₂+Ar)) can be higher than 0% and lower than or equal to 100%, preferably higher than 0% and lower than or equal to 50%, further preferably higher than or equal to 10% and lower than or equal to 40%, still further preferably higher than or equal to 10% and lower than or equal to 30%. The carrier concentration in the oxide 230a2 can be reduced by thus performing the microwave treatment in an atmosphere containing oxygen. In addition, the carrier concentrations in the oxide 230al and the oxide 230a3 can be prevented from being excessively reduced by preventing an excessive amount of oxygen from being introduced into the chamber in the microwave treatment.

The microwave treatment in an oxygen-containing atmosphere converts an oxygen gas into plasma using a high-frequency wave such as a microwave or RF, and applies the oxygen plasma to the oxide 230a2. At this time, the oxide 230a2 can be irradiated with the high-frequency wave such as the microwave or RF. In other words, the microwave, the high-frequency wave such as RF, the oxygen plasma, and the like can be applied to the oxide 230a2. The effect of the plasma, the microwave, and the like enables VoH in the oxide 230a2 to be cut off, and hydrogen to be removed from the oxide 230a2. That is, the V_{O}H in the oxide 230a2 can be reduced. As a result, oxygen vacancies and VoH in the oxide 230a2 can be reduced to lower the carrier concentration. In addition, oxygen radicals generated by the oxygen plasma or oxygen contained in the insulator 250a1 can be supplied to oxygen vacancies formed in the oxide 230a2, thereby further reducing oxygen vacancies and lowering the carrier concentration in the oxide 230a2.

Furthermore, the insulating film 250F1 having a barrier property against oxygen is provided in contact with the side surface of the conductor 242a. Thus, formation of an oxide film on the side surface of the conductor 242a by the microwave treatment can be inhibited.

In addition, the insulating film 250F1 can have improved film quality, which increases the reliability of the transistor 200a.

Next, an insulating film 250F2 is deposited over the insulating film 250F1 (see FIGS. 27A to 27C). The insulating film 250F2 is preferably formed using an insulator having a function of inhibiting the diffusion of oxygen. Owing to this structure, oxidation of the conductor 260a due to oxygen contained in the oxide 230a can be inhibited. As the insulating film 250F2, for example, a hafnium oxide film can be deposited by a thermal ALD method. Note that hafnium oxide is also a high permittivity material. Thus, when a hafnium oxide film is deposited as the insulating film 250F2, the equivalent oxide thickness of the insulator functioning as the gate insulator can be reduced. Therefore, the breakdown voltage of the insulator 250a can be increased.

In the case where the microwave treatment is not performed after the insulating film 250F1 is deposited, the insulating film 250F1 and the insulating film 250F2 are preferably deposited successively without being exposed to the air. By the deposition without exposure to the air, impurities or moisture from the air can be prevented from being attached onto the insulating film 250F1, so that an interface between the insulating film 250F1 and the insulating film 250F2 and the vicinity of the interface can be kept clean.

Next, an insulating film 274F is deposited over the insulating film 250F2 (see FIGS. 27A to 27C). For example, a silicon oxide film can be deposited as the insulating film 274F by a sputtering method. Since a molecule containing hydrogen is not used for a deposition gas in the sputtering method, the concentration of hydrogen in the insulating film 274F can be reduced. Note that heat treatment may be performed before the deposition of the insulating film 274F. In this embodiment, as the insulating film 274F, a silicon oxide film is deposited by a CVD method.

Next, CMP treatment is performed to remove part of the insulating film 274F, part of the insulating film 250F2, and part of the insulating film 250F1, so that the insulator 291 is exposed. The insulator 274a, an insulator 274c, the insulator 250a (the insulator 250a1 and the insulator 250a2), and the insulator 251a (the insulator 251a1 and the insulator 251a2) are formed by the CMP treatment. Specifically, the insulators 274a and 274c are formed using the insulating film 274F, the insulators 250a2 and 251a2 are formed using the insulating film 250F2, and the insulators 250a1 and 251a1 are formed using the insulating film 250F1 (see FIGS. 28A to 28C).

As described above, the oxide 230a, the conductor 242a, and the insulator 291 each have a hollow cylindrical shape. That is, the stack of the oxide 230a, the conductor 242a, and the insulator 291 has a hollow cylindrical shape. The insulator 250a1 is provided in contact with the inner wall of the hollow portion of the stack, the top surface of the insulator 216a, and the top surface of the conductor 244; the insulator 250a2 is provided in contact with the inner wall and the bottom surface of a depressed portion formed in the insulator 250al; and the insulator 274c is provided to fill a depressed portion formed in the insulator 250a2.

The insulator 251a1 is provided in contact with the outer side surface of the stack, the top surface of the insulator 216a, and the top surface of the conductor 244. The insulator 251a2 is provided in contact with the top surface of the insulator 251al, and the insulator 274a is provided in contact with the top surface of the insulator 251a2.

The top surface of the insulator 291 is partly removed by the CMP treatment in some cases.

The top surface of the insulator 274a is level with the top surface of the insulator 274c. The uppermost portions of the insulators 250a1, 250a2, 251al, and 251a2 are level with each other.

Next, the insulator 291 is removed to expose the top surface of the conductor 242a (see FIGS. 28A to 28C). A dry etching method or a wet etching method is preferably employed for the removal of the insulator 291.

By removing the insulator 291, the top surface of the conductor 242a can be exposed in a self-aligned manner. Thus, the conductor 246a formed later can surely be placed to be in contact with the conductor 242a without alignment. Note that in the removal of the insulator 291 by etching, an etching condition with high selectivity is preferably employed so that the insulator 274c is not removed by the etching. By employing such a condition, after the insulator 291 is removed, the insulator 274c can remain.

Next, a conductive film to be the conductor 246a and an insulating film to be the insulator 277a are deposited in this order. Then, part of the conductive film and part of the insulating film are processed by a lithography method (see FIGS. 29A to 29C). By the processing, the conductor 246a and the insulator 277a can be formed. At this time, a protruding portion is formed in a region of the conductor 246a that overlaps with the conductor 242a. Wet etching may be used for the processing; however, dry etching is preferable for microfabrication.

Next, an insulating film to be the insulator 278a is deposited over the insulators 250a, 277a, 274c, and the like. The insulating film may be deposited using a material that is the same as or different from the material of the insulating film to be the insulator 277a.

Then, the insulating film to be the insulator 278a is partly removed by CMP treatment to expose the insulator 277a. The insulator 278a having a flat top surface is formed by the CMP treatment (see FIGS. 30A to 30C). Note that the top surface of the insulator 277a is partly removed by the CMP treatment in some cases.

Next, an opening is formed in a region of the insulator 278a that overlaps with the insulators 274c and 250a (see FIGS. 31A to 31C). Note that in the case where the resist mask 292 is formed by the above-described multi-patterning technique, the opening of the insulator 278a is also formed by the above-described multi-patterning technique.

Next, an insulating film to be the insulator 276a is deposited over the insulators 274c, 250a, 277a, and 278a. The insulating film is preferably deposited by an ALD method. The insulating film needs to be deposited on the bottom and side surfaces of the opening formed in the insulator 278a so as to have good coverage. In the ALD method, one atomic layer can be deposited at a time on the bottom and side surfaces of the opening, whereby the insulating film can be deposited in the opening with good coverage. In this embodiment, a silicon nitride film is deposited as the insulating film by a PEALD method.

Next, the insulating film to be the insulator 276a is subjected to anisotropic etching to form the insulator 276a (see FIGS. 32A to 32C). After the insulator 276a is formed, part of the top surface of the insulator 250a2 and the top surface of the insulator 274c are exposed.

For the anisotropic etching, for example, a dry etching method is employed. With the insulator 276a on the side surface of the opening portion, the conductor 246a and the conductor 260a that is formed later can be physically apart from each other. Thus, establishment of electrical continuity between the conductor 246a and the conductor 260a can be prevented. In other words, the conductor 246a and the conductor 260a can be prevented from being electrically connected to each other.

Then, the insulator 274c is removed. A dry etching method or a wet etching method is preferably employed for the removal of the insulator 274c. Note that in the removal of the insulator 274c by etching, an etching condition with high selectivity is preferably employed so that the insulator 250a and the insulator 276a are not removed by the etching. By employing such a condition, after the insulator 274c is removed, the insulator 250a and the insulator 276a can remain.

Next, a conductive film 260F and a conductive film 261F are deposited in this order (see FIGS. 33A to 33C). In this embodiment, a titanium nitride film is deposited by an ALD method as the conductive film 260F and a tungsten film is deposited by a CVD method as the conductive film 261F.

Next, part of the conductive film 260F and part of the conductive film 261F are removed by CMP treatment to expose the insulators 276a, 277a, and 278a. The conductor 260a is formed by the CMP treatment (see FIGS. 34A to 34C). Accordingly, the conductor 260a is placed to fill the opening of the insulator 276a and the depressed portion of the insulator 250a. That is, the conductor 260a is placed to fill the opening formed in the oxide 230a with the insulator 250a therebetween.

Note that although the conductor 260a is part of the conductive film 260F remaining in the opening of the insulator 276a and the depressed portion of the insulator 250a in FIGS. 34B and 34C, the present invention is not limited thereto. Depending on the conditions for the CMP treatment or the size, depth, or the like of the opening of the insulator 276a, part of the conductive film 260F and part of the conductive film 261F may remain in the opening of the insulator 276a and the depressed portion of the insulator 250a. In this case, the conductor 260a has a stacked-layer structure of a first conductor formed using the conductive film 260F and a second conductor formed using the conductive film 261F. As illustrated in FIGS. 34B and 34C, in the case where only the conductive film 260F remains in the opening of the insulator 276a and the depressed portion of the insulator 250a, the conductive film 261F is sometimes not necessarily deposited.

By the CMP treatment, part of the insulator 277a and part of the insulator 278a are removed in some cases.

Next, an insulator 310 is deposited over the conductor 260a, the insulator 276a, the insulator 277a, and the insulator 278a. The description of the deposition of the insulator 216a can be referred to for the deposition of the insulator 310.

Next, an opening is formed in a region of the insulator 310 that overlaps with the conductor 260a. Note that the insulator 276a may be partly removed when the opening is formed.

Next, the conductor 311 is formed to fill the opening formed in the insulator 310 (see FIGS. 35A to 35C). The description of the formation of the conductor 244 can be referred to for the formation of the conductor 311; thus, the detailed description thereof is omitted. Note that the insulator 310 may be partly removed when the conductor 311 is formed.

Next, the insulator 310 is removed (see FIGS. 36A to 36C). A dry etching method or a wet etching method is preferably employed for the removal of the insulator 310.

Next, the insulator 313, the conductor 312, and the insulator 314 are deposited in this order (see FIGS. 37A to 37C).

The insulator 313 and the conductor 312 are preferably deposited by an ALD method. The insulator 313 and the conductor 312 need to be deposited on the top and side surfaces of the conductor 311 so as to have good coverage. In the ALD method, one atomic layer can be deposited at a time on the top and side surfaces of the conductor 311, whereby the insulator 313 and the conductor 312 can be deposited with good coverage.

The top surface of the insulator 314 is preferably planarized by CMP treatment.

Next, an opening overlapping with the conductor 311 is formed in the insulator 314 and the conductor 312 (see FIGS. 38A to 38C). In the plan view, the area of the opening is preferably larger than the area of the conductor 311. With such a structure, the conductor 311 and the conductor 316 that is formed later can be in contact with each other inside the opening.

Next, an insulating film 315F is deposited over the insulator 313 and the insulator 314 (see FIGS. 39A to 39C). The thickness of the insulating film 315F is preferably equal to the thickness of the insulator 313. The insulating film 315F is preferably formed using the same material as the insulator 313. The insulator 313 and the insulator 315 formed using the insulating film 315F function as dielectrics of the capacitor 300. Thus, with such a structure, the distance between the pair of the electrodes of the capacitor 300 is kept constant in the Z direction, so that a variation in capacitance between the capacitors 300 can be reduced.

Next, the insulating film 315F is subjected to anisotropic etching to form the insulator 315 (see FIGS. 40A to 40C). After the insulator 315 is formed, part of the top surface of the insulator 313 is exposed. In addition, the insulator 315 is formed on the side surface of the opening formed in the insulator 314 and the conductor 312. That is, the insulator 315 can be rephrased as a sidewall.

Next, an opening reaching the conductor 311 is formed in the insulator 313 (see FIGS. 41A to 41C).

In the case where the insulating film 315F and the insulator 313 are formed using the same material, part of the top surface of the insulator 313 may also be removed in the anisotropic etching of the insulating film 315F. At this time, the insulator 315 and the opening of the insulator 313 that reaches the conductor 311 can be formed at the same time.

Next, the conductor 316 is formed to fill the opening formed in the insulators 315 and 313 (see FIGS. 42A to 42C). The description of the formation of the conductor 244 can be referred to for the formation of the conductor 316; thus, the detailed description thereof is omitted. Note that the insulators 314 and 315 may be partly removed when the conductor 316 is formed.

Note that an opening reaching the conductor 312 may be formed in the insulator 314 and the conductor 317 may be formed to fill the opening (see FIGS. 43A to 43C). Here, by making the conductor 317 to function as a wiring, the conductor 312 can be thinned. Thus, the time for depositing the conductor 312 by an ALD method is shortened, so that the productivity of the semiconductor device can be improved.

Next, the insulator 216b is formed over the conductor 316, the insulator 315, and the insulator 314. Then, an opening is formed in a region of the insulator 216b that overlaps with the conductor 316, and the conductor 245 is formed to fill the opening (see FIGS. 44A to 44C). The description of the formation of the insulator 216a and the description of the formation of the conductor 244 can be respectively referred to for the formation of the insulator 216b and the formation of the conductor 245; thus, the detailed description thereof is omitted.

Then, the transistor 200b is formed. The description with reference to FIGS. 24A to 24C, FIGS. 25A to 25C, FIGS. 26A to 26C, FIGS. 27A to 27C, FIGS. 28A to 28C, FIGS. 29A to 29C, FIGS. 30A to 30C, FIGS. 31A to 31C, FIGS. 32A to 32C, FIGS. 33A to 33C, and FIGS. 34A to 34C can be referred to for a method for forming the transistor 200b (a method for forming the components from the oxide 230b to the conductor 260b); thus, the detailed description thereof is omitted.

Next, the insulator 285 is formed over the conductor 260b, the insulator 276b, the insulator 277b, and the insulator 278b (see FIGS. 22A to 22C). The insulator 285 is preferably deposited by a sputtering method. Since a molecule containing hydrogen is not used for a deposition gas in the sputtering method, the concentration of hydrogen in the insulator 285 can be reduced. In this embodiment, a silicon oxide film is deposited as the insulator 285 by a sputtering method.

Next, an opening is formed in the insulator 285 (see FIGS. 22A to 22C). By forming the opening, at least the top surface of the conductor 260b and the top surface of the insulator 276b are exposed. Wet etching can be used for the formation of the opening; however, dry etching is preferable for microfabrication. Note that the insulator 276b may be partly removed when the opening is formed in the insulator 285.

Next, a conductive film to be the conductor 262a and a conductive film to be the conductor 262b are deposited in this order. In this embodiment, a titanium nitride film is deposited by an ALD method as the conductive film to be the conductor 262a and a tungsten film is deposited by a CVD method as the conductive film to be the conductor 262b.

Next, the conductive film to be the conductor 262a and the conductive film to be the conductor 262b are partly removed by CMP treatment to expose the insulator 285. The conductor 262 (the conductor 262a and the conductor 262b) is formed by the CMP treatment (see FIGS. 22A to 22C).

Through the above steps, the semiconductor device illustrated in FIGS. 22A to 22C can be manufactured.

### Variation Example 1

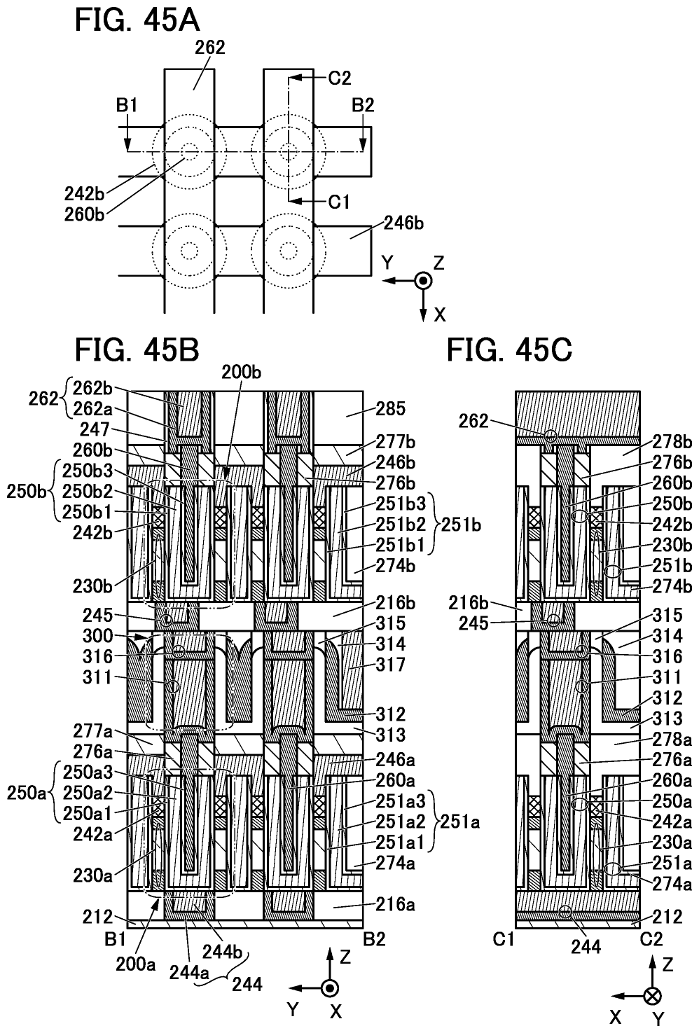

Hereinafter, an example of a structure different from that of the semiconductor device illustrated in FIGS. 22A to 22C will be described with reference to FIGS. 45A to 45C.

FIGS. 45A to 45C illustrate a variation example of the semiconductor device illustrated in FIGS. 22A to 22C. FIG. 45A is a plan view of the semiconductor device. FIGS. 45B and 45C are cross-sectional views of the semiconductor device. Here, FIG. 45B is the cross-sectional view taken along the dashed-dotted line B1-B2 in FIG. 45A. FIG. 45C is the cross-sectional view taken along the dashed-dotted line C1-C2 in FIG. 45A. Note that FIG. 45A illustrates four of the plurality of memory cells included in the semiconductor device.

The semiconductor device illustrated in FIGS. 45A to 45C is different from the semiconductor device illustrated in FIGS. 22A to 22C in that the insulator 250 and the insulator 251 each have a three-layer structure. In addition, the semiconductor device illustrated in FIGS. 45A to 45C is different from the semiconductor device illustrated in FIGS. 22A to 22C in including an insulator 212 and an insulator 247. Differences from the semiconductor device illustrated in FIGS. 22A to 22C will be mainly described below, and the description of portions similar to those in FIGS. 22A to 22C is omitted.

The insulator 250a has a three-layer structure of the insulator 250al, the insulator 250a2 over the insulator 250al, and an insulator 250a3 over the insulator 250a2. The insulator 250a3 is provided between the insulator 250a2 and the conductor 260a. The insulator 250b has a three-layer structure of the insulator 250b1, the insulator 250b2 over the insulator 250b1, and an insulator 250b3 over the insulator 250b2. The insulator 250b3 is provided between the insulator 250b2 and the conductor 260b. Hereinafter, the insulator 250a3 and the insulator 250b3 may be collectively referred to as an insulator 250_3.

The insulator 251a has a three-layer structure of the insulator 251al, the insulator 251a2 over the insulator 251al, and an insulator 251a3 over the insulator 251a2. The insulator 251a3 is provided between the insulator 251a2 and the insulator 274a. The insulator 251b has a three-layer structure of the insulator 251b1, the insulator 251b2 over the insulator 251b1, and an insulator 251b3 over the insulator 251b2. The insulator 251b3 is provided between the insulator 251b2 and the insulator 274b. Hereinafter, the insulator 251a3 and the insulator 251b3 may be collectively referred to as an insulator 251_3.

The insulator 250_3 functions as part of the gate insulator. As the insulator 250_3, a barrier insulating film against hydrogen is preferably used. This can inhibit diffusion of impurities contained in the conductor 260, such as hydrogen, into the oxide 230_2. Silicon nitride is preferably used for the insulator 250_3, for example. Silicon nitride deposited by a PEALD method is preferably used for the insulator 250_3, for example. In that case, the insulator 250_3 contains at least nitrogen and silicon. Alternatively, for the insulator 250_3, aluminum oxide, magnesium oxide, hafnium oxide, gallium oxide, indium gallium zinc oxide, or silicon nitride oxide may be used, for example.

Furthermore, the insulator 250_3 may also have a barrier property against oxygen. In this case, oxygen contained in the insulator 250_2 can be inhibited from diffusing into the conductor 260.

The insulator 250_3 needs to be provided in the openings of the oxide 230 and the conductor 242, together with the insulator 250_1, the insulator 250_2, and the conductor 260. The thickness of the insulator 250_3 is preferably small for miniaturization of the transistor 200. The thickness of the insulator 250_3 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In that case, at least part of the insulator 250_3 includes a region having the above-described thickness. The thickness of the insulator 250_3 is preferably smaller than that of the insulator 250_2. In that case, at least part of the insulator 250_3 includes a region having a thickness smaller than that of the insulator 250_2.

The insulator 250_3 and the insulator 251_3 are formed in the same step. Thus, the insulator 251_3 contains the same insulating material as the insulator 250_3. The thickness of the insulator 251_3 is equal to that of the insulator 250_3.

The insulator 247 is positioned between the conductor 262 and the insulators 277b, 278b, and 285. The insulator 247 is provided in contact with the side surface of the conductor 262.

The insulator 247 preferably functions as a barrier insulating film for inhibiting diffusion of impurities such as water and hydrogen into the conductor 262. This can inhibit diffusion of impurities contained in the insulator 285, such as hydrogen, into the oxide 230_2 through the conductor 262. Any of the insulators that can be used as the insulator 250_3 is used as the insulator 247. For example, silicon nitride deposited by a PEALD method is used for the insulator 247. In that case, the insulator 247 contains at least nitrogen and silicon.

Note that an insulator formed of the same material as the insulator 247 is sometimes formed to cover the side surface of a region of the conductor 260b that is exposed from the insulator 276b.

The insulator 212 is provided over a substrate (not illustrated) and is provided below the insulator 216a and the conductor 244.

The insulator 212 functions as an interlayer film. The insulator 212 preferably functions as a barrier insulating film for inhibiting diffusion of impurities such as water and hydrogen into the transistor 200a from the substrate side. Providing the insulator 212 can inhibit diffusion of impurities such as water and hydrogen to the transistor 200a side from the substrate side.

Any of the above-described insulators that can be used as the insulator 250_3 is used as the insulator 212. For example, the insulator 212 is preferably formed using a nitride containing silicon, such as silicon nitride or silicon nitride oxide. Specifically, a silicon nitride film deposited by a sputtering method is used for the insulator 212. When the insulator 212 is deposited by a sputtering method, a high-density silicon nitride film can be obtained. To obtain the insulator 212, a silicon nitride film deposited by a PEALD method or a CVD method may be stacked over a silicon nitride film deposited by a sputtering method.

### Variation Example 2

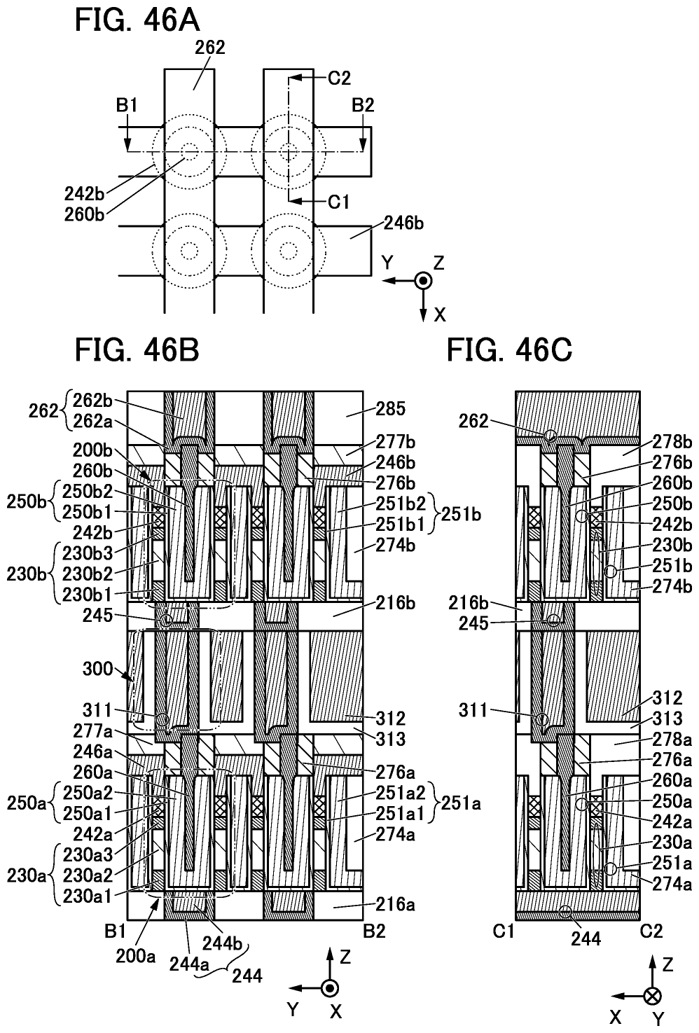

Hereinafter, examples of a structure and a manufacturing method different from those of the semiconductor device illustrated in FIGS. 22A to 22C will be described with reference to FIGS. 46A to 46C, FIGS. 47A to 47C, and FIGS. 48A to 48C.

FIGS. 46A to 46C illustrate a variation example of the semiconductor device illustrated in FIGS. 22A to 22C. FIG. 46A is a plan view of the semiconductor device. FIGS. 46B and 46C are cross-sectional views of the semiconductor device. Here, FIG. 46B is the cross-sectional view taken along the dashed-dotted line B1-B2 in FIG. 46A. FIG. 46C is the cross-sectional view taken along the dashed-dotted line C1-C2 in FIG. 46A. Note that FIG. 46A illustrates four of the plurality of memory cells included in the semiconductor device.

The semiconductor device illustrated in FIGS. 46A to 46C is different from the semiconductor device illustrated in FIGS. 22A to 22C in not including the insulator 314, the insulator 315, the conductor 316, and the conductor 317. Differences from the semiconductor device illustrated in FIGS. 22A to 22C will be mainly described below, and the description of portions similar to those in FIGS. 22A to 22C is omitted.

The memory cell of the semiconductor device illustrated in FIGS. 46A to 46C shows a detailed structure example of the memory cell 100 illustrated in FIGS. 10A to 10C.

In the semiconductor device illustrated in FIGS. 46A to 46C, the top surface of the conductor 311 is level with the top surfaces of the conductor 312 and the insulator 313.

The structure not including the insulator 314, the insulator 315, the conductor 316, and the conductor 317 shortens the manufacturing process of the semiconductor device and can increase the productivity of the semiconductor device.

In the plan view, end portions of the conductor 245 and the conductor 311 are preferably aligned with each other. Alternatively, the outline of the conductor 245 is preferably positioned inward from the outline of the conductor 311. This structure can prevent the conductor 245 and the conductor 312 from being in contact with each other, and can prevent a leakage current and a short circuit between the conductor 245 and the conductor 312.

In the plan view, the center of the conductor 311 and the center of the conductor 260a may be shifted from each other as long as the conductor 311 and the conductor 260a overlap with each other. With such a structure, the conductor 260a, the conductor 311, the conductor 245, and the oxide 230b can be connected to each other without shifting the center of the transistor 200a and the center of the transistor 200b from each other. Thus, the area occupied by the memory cell can be reduced and the memory density can be improved. In addition, the transistor 200a and the transistor 200b can be formed using the same mask, which can reduce the manufacturing cost.

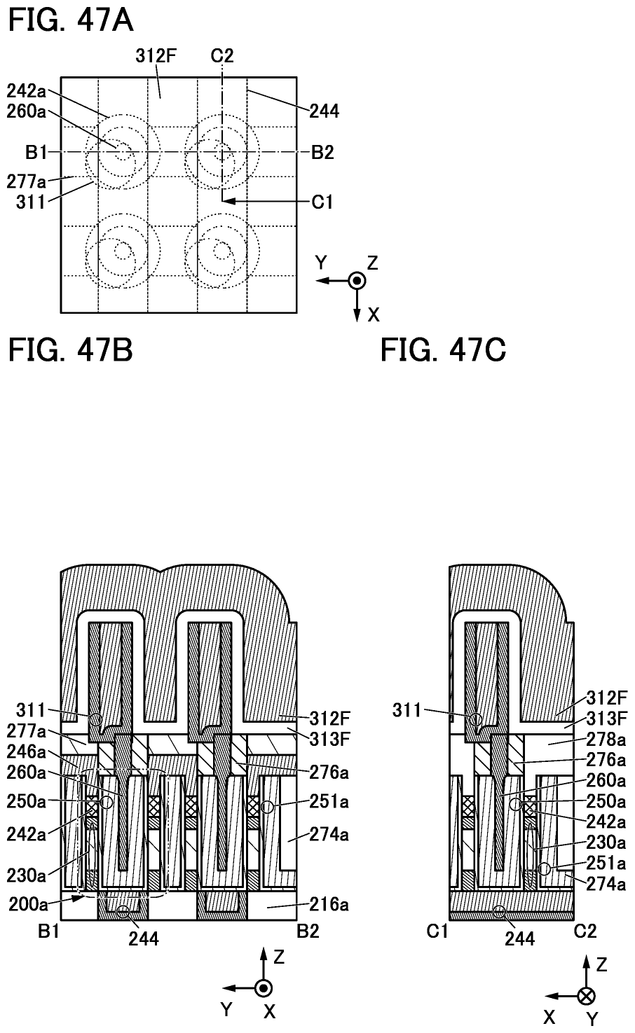

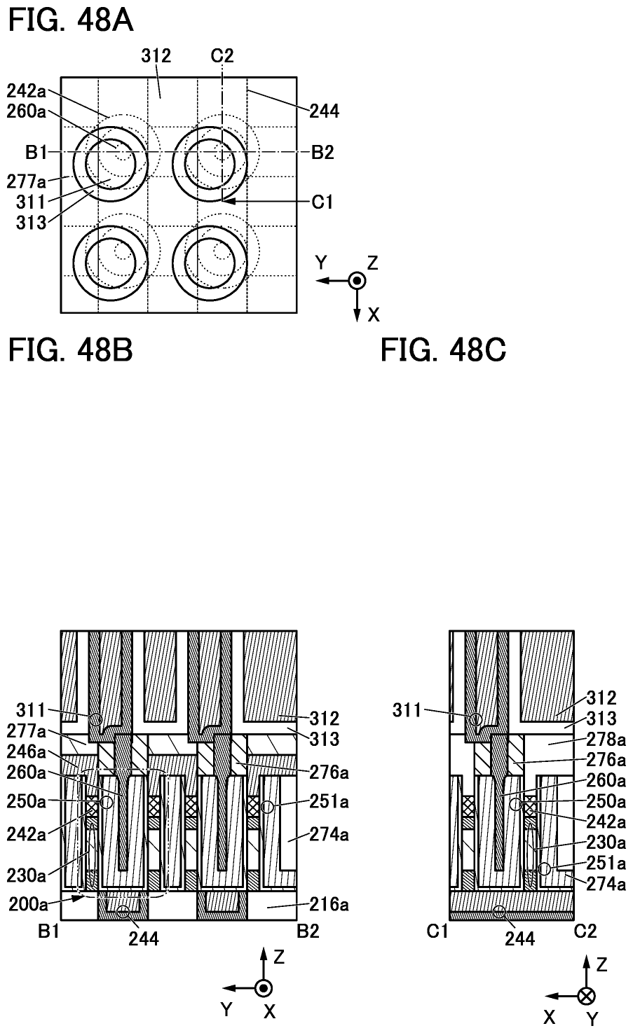

Next, a method for manufacturing the semiconductor device illustrated in FIGS. 46A to 46C will be described with reference to FIGS. 47A to 47C and FIGS. 48A to 48C.

In FIG. 47A to FIG. 48C, FIG. 47A and FIG. 48A are plan views. FIG. 47B and FIG. 48B are cross-sectional views taken along dashed-dotted lines B1-B2 in FIG. 47A and FIG. 48A, respectively. FIG. 47C and FIG. 48C are cross-sectional views taken along dashed-dotted lines C1-C2 in FIG. 47A and FIG. 48A, respectively.

The description with reference to FIG. 24A to FIG. 36C can be referred to for the manufacturing method up to the formation of the conductor 311; thus, the detailed description thereof is omitted.

Next, an insulating film 313F and a conductive film 312F are deposited in this order over the conductor 311, the insulator 276a, the insulator 277a, and the insulator 278a (see FIGS. 47A to 47C). The description of the deposition of the insulator 313 and the conductor 312 can be referred to for the deposition of the insulating film 313F and the conductive film 312F, respectively.

Note that the conductive film 312F may have a two-layer structure of a first conductive film and a second conductive film over the first conductive film. Here, for example, a titanium nitride film may be deposited by an ALD method as the first conductive film of the conductive film 312F, and a tungsten film may be deposited by a CVD method as the second conductive film of the conductive film 312F.

Next, part of the conductive film 312F and part of the insulating film 313F are removed by CMP treatment to expose the conductor 311. The conductor 312 and the insulator 313 are formed by the CMP treatment (see FIGS. 48A to 48C).

The description in [Method 1 for manufacturing semiconductor device] above can be referred to for the method for forming the insulator 216 and the conductor 245, the method for forming the transistor 200b, and the method for forming the insulator 285 and the conductor 262; thus, the detailed description thereof is omitted.

Through the above steps, the semiconductor device illustrated in FIGS. 46A to 46C can be manufactured.

### Variation Example 3

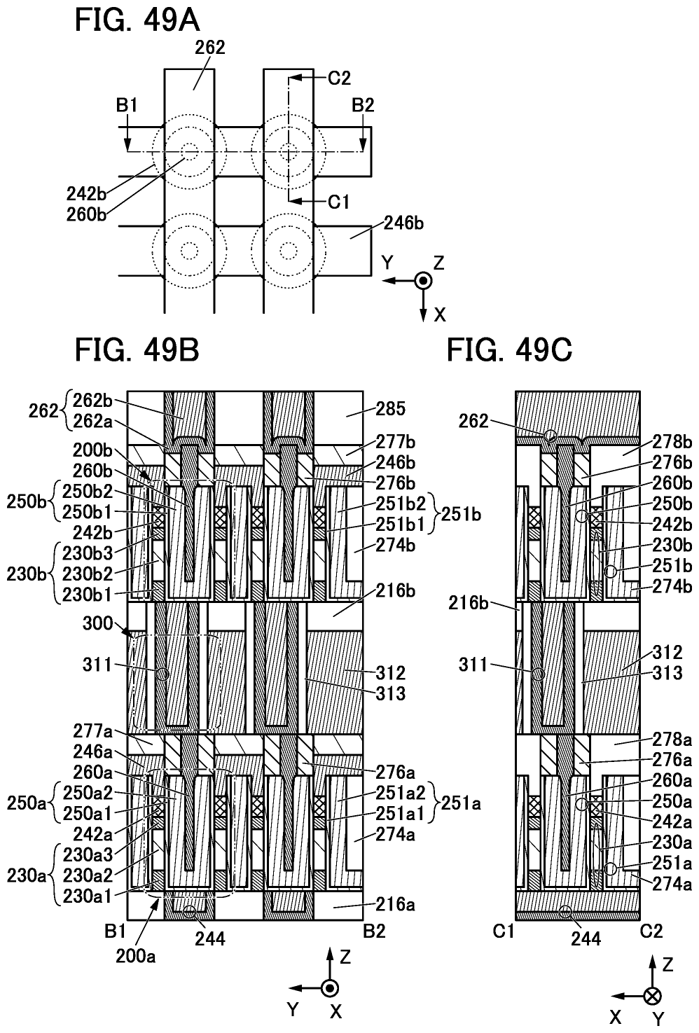

Hereinafter, examples of a structure and a manufacturing method different from those of the semiconductor device illustrated in FIGS. 22A to 22C and the semiconductor device illustrated in FIGS. 46A to 46C will be described with reference to FIGS. 49A to 49C, FIGS. 50A to 50C, FIGS. 51A to 51C, FIGS. 52A to 52C, FIGS. 53A to 53C, FIGS. 54A to 54C, and FIGS. 55A to 55C.

FIGS. 49A to 49C illustrate a variation example of the semiconductor device illustrated in FIGS. 22A to 22C and the semiconductor device illustrated in FIGS. 46A to 46C. FIG. 49A is a plan view of the semiconductor device. FIGS. 49B and 49C are cross-sectional views of the semiconductor device. Here, FIG. 49B is the cross-sectional view taken along the dashed-dotted line B1-B2 in FIG. 49A. FIG. 49C is the cross-sectional view taken along the dashed-dotted line C1-C2 in FIG. 49A. Note that FIG. 49A illustrates four of the plurality of memory cells included in the semiconductor device.

The semiconductor device illustrated in FIGS. 49A to 49C is different from the semiconductor device illustrated in FIGS. 22A to 22C in not including the insulator 314, the insulator 315, the conductor 316, the conductor 317, and the conductor 245. In addition, the semiconductor device illustrated in FIGS. 49A to 49C is different from the semiconductor device illustrated in FIGS. 46A to 46C in not including the conductor 245. Differences from the semiconductor device illustrated in FIGS. 22A to 22C and the semiconductor device illustrated in FIGS. 46A to 46C will be mainly described below, and the description of portions similar to those in FIGS. 22A to 22C and FIGS. 46A to 46C is omitted.

The memory cell of the semiconductor device illustrated in FIGS. 49A to 49C shows a detailed structure example of the memory cell 100 illustrated in FIGS. 17A to 17C.

The conductor 312 is provided over the insulators 276a, 277a, and 278a, and the insulator 216b is provided over the conductor 312. An opening is formed in a region of the insulator 216b and a region of the conductor 260a that overlap with the conductor 312. The insulator 313 is provided in contact with the side surface of the opening formed in the insulator 216b and the conductor 312, and the conductor 311 is provided inward from the insulator 313.

The conductor 311 includes a region in contact with the top surface of the conductor 260a and a region in contact with at least part of the bottom surface of the oxide 230b. The top surface of the conductor 311 is level with the top surfaces of the insulator 313 and the insulator 216b.

The structure not including the insulator 314, the insulator 315, the conductor 316, the conductor 317, and the conductor 245 shortens the manufacturing process of the semiconductor device and can increase the productivity of the semiconductor device.

In the plan view, the center of the conductor 311 and the center of the conductor 260a may be shifted from each other as long as the conductor 311 and the conductor 260a overlap with each other. With such a structure, the conductor 260a, the conductor 311, and the oxide 230b can be connected to each other without shifting the center of the transistor 200a and the center of the transistor 200b from each other. Thus, the area occupied by the memory cell can be reduced and the memory density can be improved. In addition, the transistor 200a and the transistor 200b can be formed using the same mask, which can reduce the manufacturing cost.

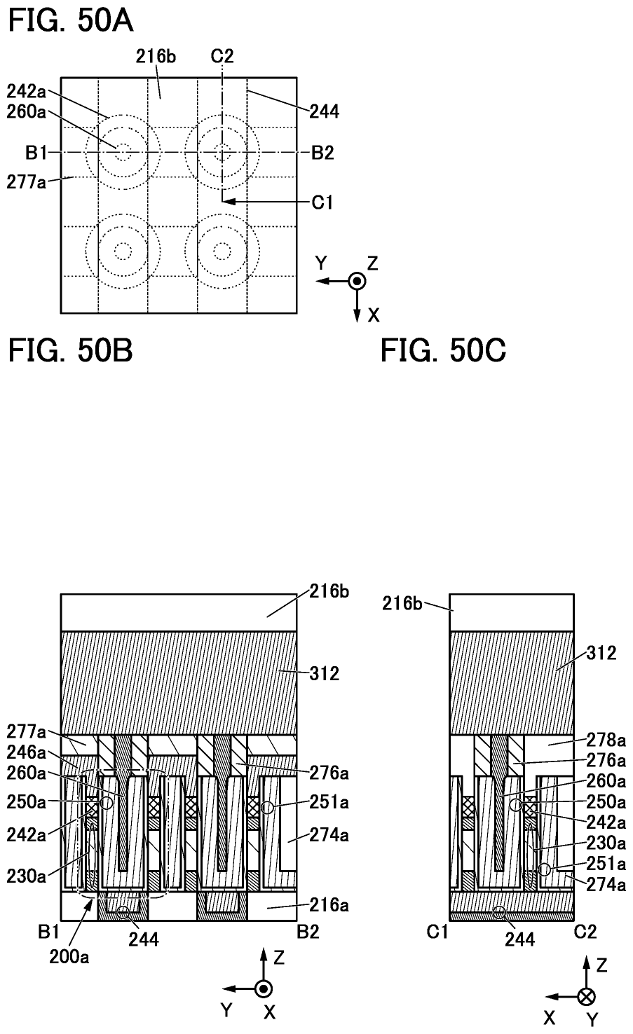

Next, a method for manufacturing the semiconductor device illustrated in FIGS. 49A to 49C will be described with reference to FIGS. 50A to 50C, FIGS. 51A to 51C, FIGS. 52A to 52C, and FIGS. 53A to 53C.

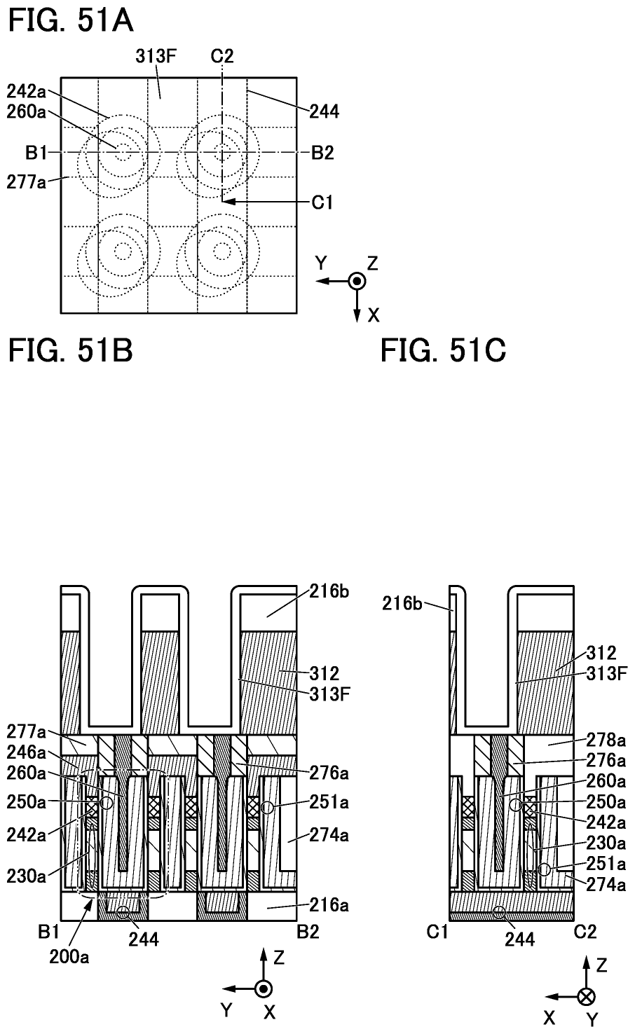

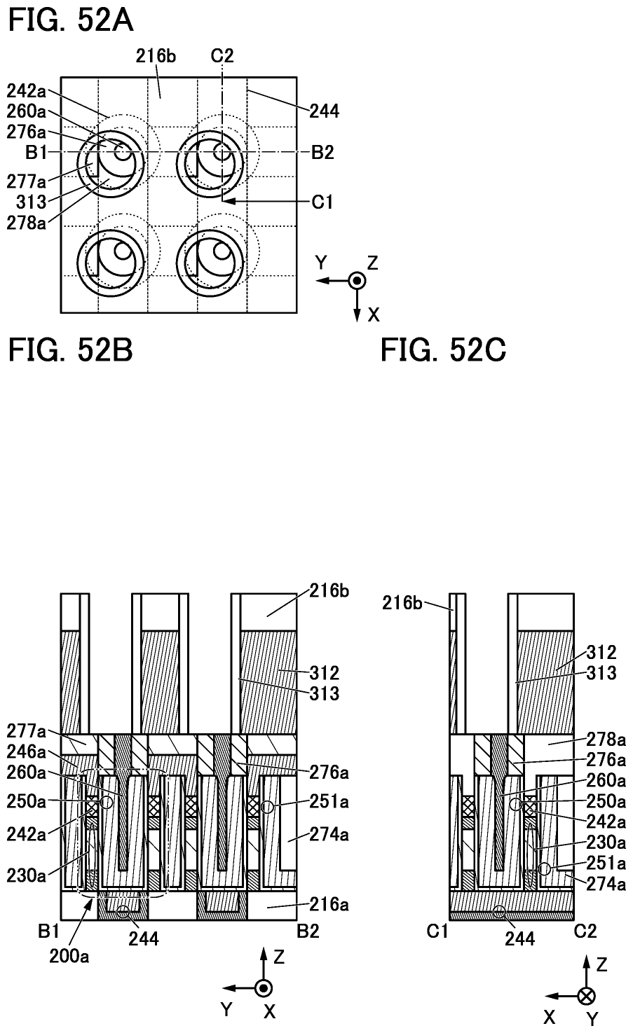

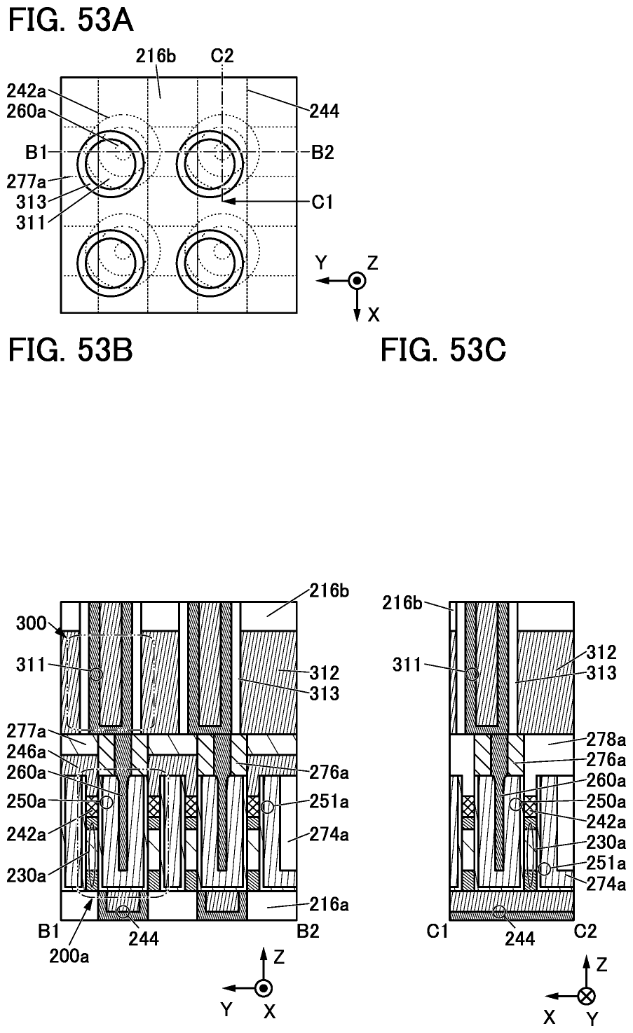

In FIG. 50A to FIG. 53C, FIG. 50A, FIG. 51A, FIG. 52A, and FIG. 53A are plan views. FIG. 50B, FIG. 51B, FIG. 52B, and FIG. 53B are cross-sectional views taken along dashed-dotted lines B1-B2 in FIG. 50A, FIG. 51A, FIG. 52A, and FIG. 53A, respectively. FIG. 50C, FIG. 51C, FIG. 52C, and FIG. 53C are cross-sectional views taken along dashed-dotted lines C1-C2 in FIG. 50A, FIG. 51A, FIG. 52A, and FIG. 53A, respectively.

The description with reference to FIG. 24A to FIG. 34C can be referred to for the manufacturing method up to the formation of the conductor 260a; thus, the detailed description thereof is omitted.

Next, the conductor 312 and the insulator 216b are deposited in this order over the conductor 260a, the insulator 276a, the insulator 277a, and the insulator 278a (see FIGS. 50A to 50C). The description of the deposition of the conductive film 312F and the insulator 216a can be referred to for the deposition of the conductor 312 and the insulator 216b, respectively.

Next, an opening is formed in the insulator 216b and the conductor 312 (see FIGS. 51A to 51C). The opening is formed to overlap with the conductor 260a. Although not illustrated, part of the insulator 276a, part of the insulator 277a, and part of the insulator 278a may be removed by the formation of the opening.

Next, the insulating film 313F is deposited (see FIGS. 51A to 51C). The description of the deposition of the insulator 313 can be referred to for the deposition of the insulating film 313F; thus, the detailed description thereof is omitted.

Next, the insulating film 313F is subjected to anisotropic etching to form the insulator 313 (see FIGS. 52A to 52C). After the formation of the insulator 313, the top surface of the conductor 260a is exposed. In addition, the insulator 313 is formed on the side surface of the opening formed in the insulator 216b and the conductor 312. That is, the insulator 313 can be rephrased as a sidewall.

Next, the conductor 311 is formed to fill the opening, which is formed in the insulator 216b and the conductor 312, with the insulator 313 therebetween (see FIGS. 53A to 53C). The description of the formation of the conductor 244 can be referred to for the formation of the conductor 311; thus, the detailed description thereof is omitted. Note that the insulator 216b may be partly removed when the conductor 311 is formed.

The description of the method for manufacturing the semiconductor device illustrated in FIGS. 22A to 22C or the description of the method for manufacturing the semiconductor device illustrated in FIGS. 46A to 46C can be referred to for the subsequent steps in the manufacturing method; thus, the detailed description thereof is omitted.

Through the above steps, the semiconductor device illustrated in FIGS. 49A to 49C can be manufactured.

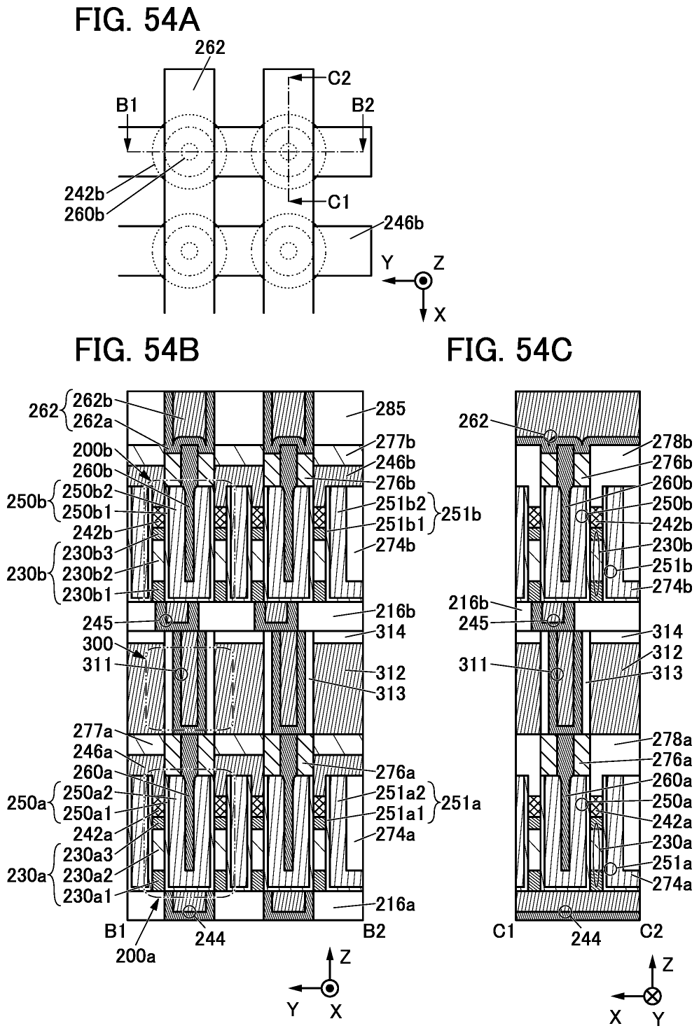

Although FIGS. 49A to 49C illustrate a structure in which the conductor 311 and the oxide 230b are in contact with each other, the present invention is not limited thereto. For example, as illustrated in FIGS. 54A to 54C, the conductor 245 may be provided, and the conductor 311 and the oxide 230b may be connected to each other through the conductor 245. In this case, the center of the conductor 311 and the center of the conductor 260a may be aligned or not aligned with each other in a plan view.

In FIGS. 54B and 54C, the insulator 314 is provided over the conductor 312, and the insulator 313 and the conductor 311 are provided inside the opening formed in the insulator 314 and the conductor 312. The insulator 216b is provided over the conductor 311, the insulator 313, and the insulator 314, and the conductor 245 is provided inside the opening formed in the insulator 216b.

The memory cell of the semiconductor device illustrated in FIGS. 54A to 54C shows a detailed structure example of the memory cell 100 illustrated in FIGS. 6A to 6C. Note that in FIGS. 54A to 54C, the conductor 312 is provided to have a planar shape.

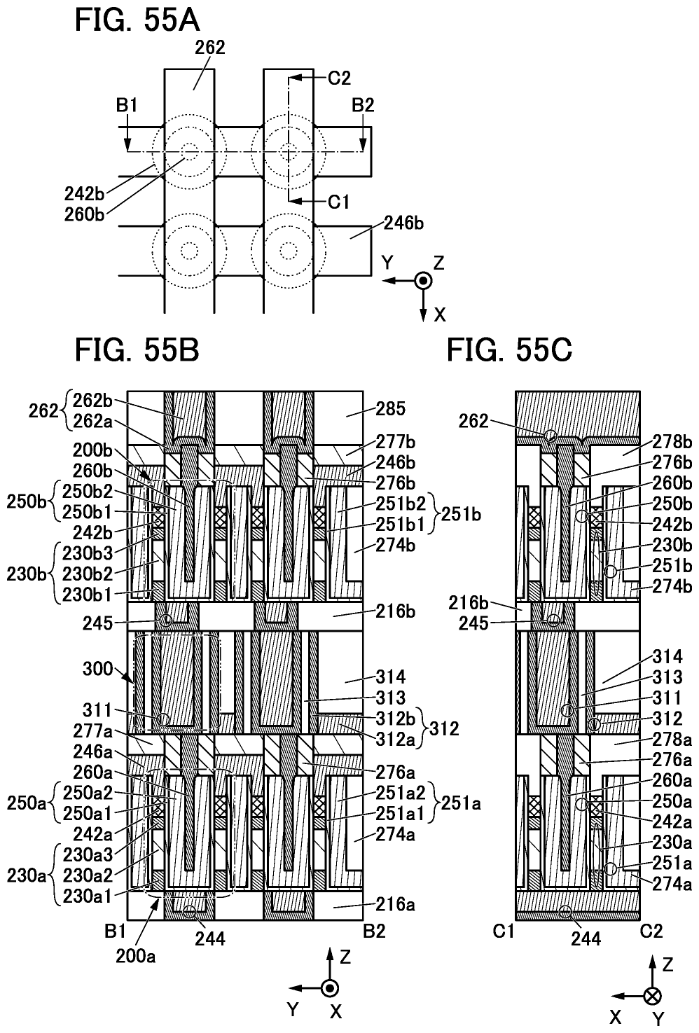

Note that although FIGS. 54A to 54C illustrate a structure in which the insulator 313 and the conductor 311 are provided inside the opening formed in the insulator 314 and the conductor 312, the present invention is not limited thereto. For example, as illustrated in FIGS. 55A to 55C, the conductor 312b may be provided inside the opening. In this case, the conductor 312b is provided between the insulator 313 and the side surface of the opening formed in the insulator 314 and the conductor 312a.

The memory cell of the semiconductor device illustrated in FIGS. 55A to 55C shows a detailed structure example of the memory cell 100 illustrated in FIGS. 13A to 13C.

In the above structure, the conductor 312 includes the conductor 312a and the conductor 312b. The conductor 312a functions as a wiring, and the conductor 312b functions as the other of the pair of electrodes of the capacitor 300. With the above structure, the area of a region where the pair of electrodes of the capacitor 300 face each other can be increased without increasing the thickness of the conductor 312a. Thus, the capacitance of the capacitor 300 can be increased.

### Specific Structure Example 2 of Semiconductor Device

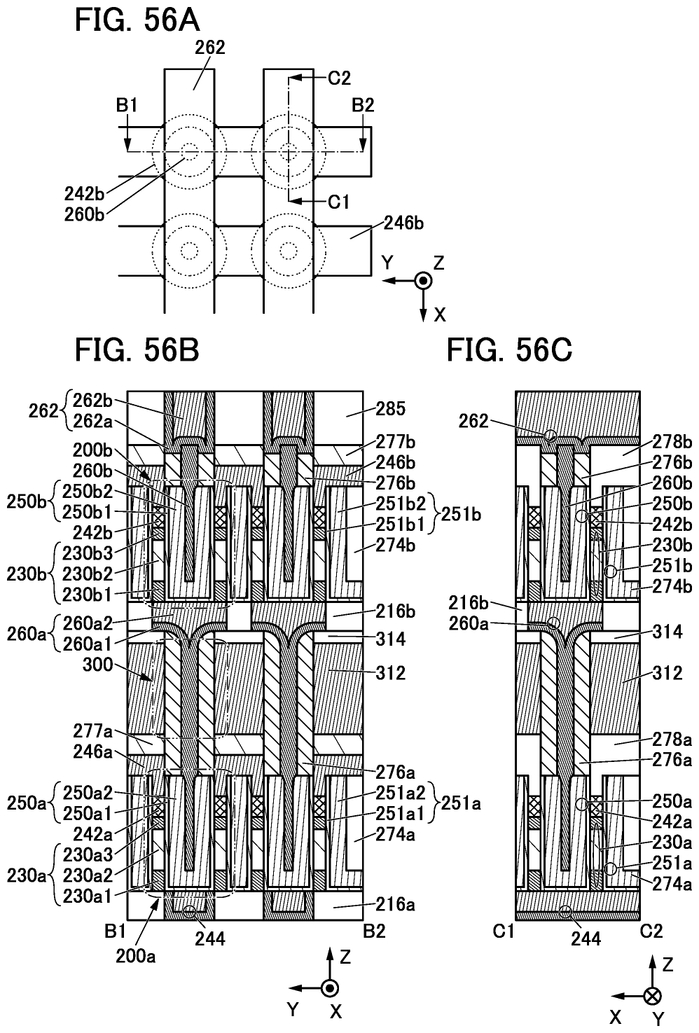

An example of a specific structure of a semiconductor device of one embodiment of the present invention is described below with reference to FIGS. 56A to 56C. Note that in the semiconductor device described below, components having the same functions as the components in the semiconductor device described in <Structure example of semiconductor device> or <Specific structure example 1 of semiconductor device> above are denoted by the same reference numerals. Differences from the semiconductor device described in <Structure example of semiconductor device> or <Specific structure example 1 of semiconductor device> above will be mainly described below, and the description of portions similar to those in the above example is omitted.

FIGS. 56A to 56C are a plan view and cross-sectional views of a semiconductor device including a plurality of memory cells. FIG. 56A is the plan view of the semiconductor device. FIGS. 56B and 56C are the cross-sectional views of the semiconductor device. Here, FIG. 56B is the cross-sectional view taken along the dashed-dotted line B1-B2 in FIG. 56A. FIG. 56C is the cross-sectional view taken along the dashed-dotted line C1-C2 in FIG. 56A. Note that FIG. 56A illustrates four of the plurality of memory cells included in the semiconductor device.

The semiconductor device illustrated in FIGS. 56A to 56C is different from the semiconductor device illustrated in FIGS. 22A to 22C in not including the conductor 311, the insulator 313, the insulator 314, the insulator 315, the conductor 316, the conductor 317, and the conductor 245. The semiconductor device illustrated in FIGS. 56A to 56C is different from the semiconductor device illustrated in FIGS. 49A to 49C in not including the conductor 311 and the insulator 313. The semiconductor device illustrated in FIGS. 56A to 56C is different from the semiconductor device illustrated in FIGS. 22A to 22C and the semiconductor device illustrated in FIGS. 49A to 49C in the shape of the conductor 260a.

The memory cell of the semiconductor device illustrated in FIGS. 56A to 56C shows a detailed structure example of the memory cell 100 illustrated in FIGS. 18A to 18C. Note that in FIGS. 56A to 56C, the conductor 312 is provided to have a planar shape.

An opening is formed in the insulator 314, the conductor 312, and the insulator 278a in a region overlapping with the insulator 250a, and the insulator 276a and part of the conductor 260a are provided inside the opening. Inside the opening, the insulator 276a includes a region in contact with the side surface of the insulator 314, a region in contact with the side surface of the conductor 312, and a region in contact with the side surface of the insulator 278a.

The conductor 260a is provided to fill the opening. The conductor 260a includes a region in contact with part of the top surface of the insulator 314, a region in contact with the side surface of the insulator 216b, and a region in contact with at least part of the bottom surface of the oxide 230b1. The conductor 260a includes a region facing the oxide 230a with the insulator 250a therebetween and a region facing the conductor 312 with the insulator 276a therebetween. The top surface of the conductor 260a is level with the top surface of the insulator 216b.

In the conductor 260a, the region facing the oxide 230a with the insulator 250a therebetween functions as the gate electrode of the transistor 200a, and the region facing the conductor 312 with the insulator 276a therebetween functions as one of the pair of electrodes of the capacitor 300. In the insulator 276a, a region interposed between the conductor 260a and the conductor 312 functions as a dielectric of the capacitor 300.

With the above structure, the conductor 260a can function as one of the pair of electrodes of the capacitor 300; thus, it is not necessary to provide the conductor 311. Moreover, the insulator 276a can function as a dielectric of the capacitor 300; thus, the insulator 313 is not necessarily provided. Therefore, the number of steps for forming the conductor 311 and the insulator 313 can be reduced and the manufacturing cost of the semiconductor device can be reduced.

In the plan view, the area of the conductor 260a above the insulator 314 is preferably larger than the area of the conductor 260a inside the opening of the insulator 276a. With such a structure, the conductor 260a and the oxide 230b can be connected to each other without shifting the center of the transistor 200a and the center of the transistor 200b from each other. Thus, the area occupied by the memory cell can be reduced and the memory density can be improved.

Note that in the plan view, the area of the conductor 260a above the insulator 314 may be smaller than or equal to the area of the conductor 260a inside the insulator 276a. In this case, the conductor 260a and the oxide 230b can be connected to each other without shifting the center of the transistor 200a and the center of the transistor 200b from each other.

In the semiconductor device illustrated in FIGS. 56A to 56C, the conductor 260a has a two-layer structure of a conductor 260al and a conductor 260a2 over the conductor 260al. The conductors 260al and 260a2 are each preferably formed using a conductive material that can be used for each of the conductors 262a and 262b.

Note that although the conductor 260a in FIGS. 56A to 56C has a two-layer structure, the present invention is not limited thereto. For example, the conductor 260a may have a single-layer structure or a stacked-layer structure of three or more layers.

### [Method 2 for Manufacturing Semiconductor Device]

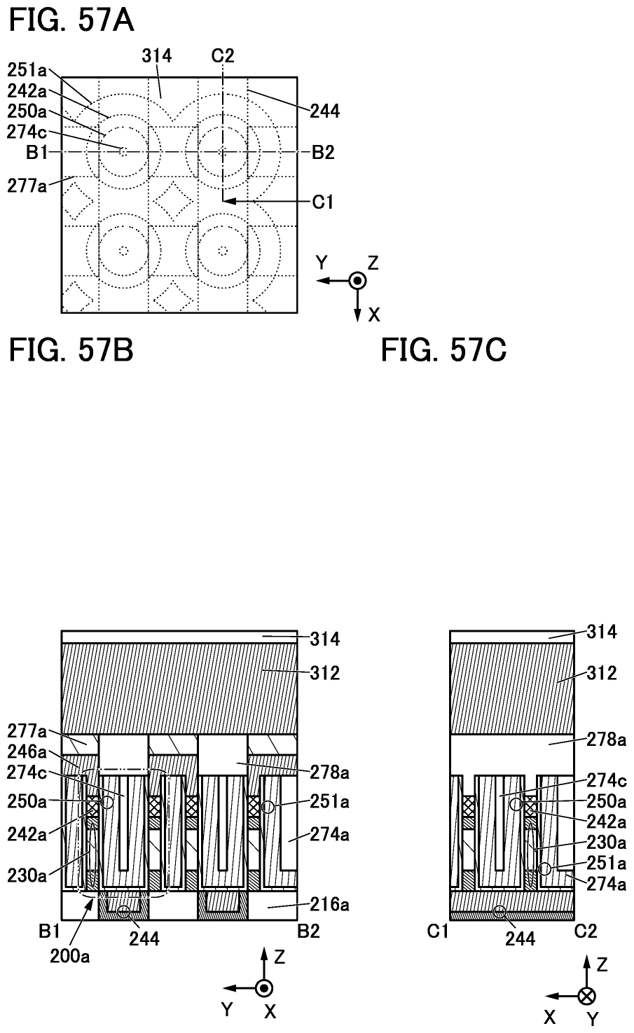

Next, a method for manufacturing the semiconductor device illustrated in FIGS. 56A to 56C will be described with reference to FIGS. 57A to 57C, FIGS. 58A to 58C, FIGS. 59A to 59C, FIGS. 60A to 60C, FIGS. 61A to 61C, and FIGS. 62A to 62C.

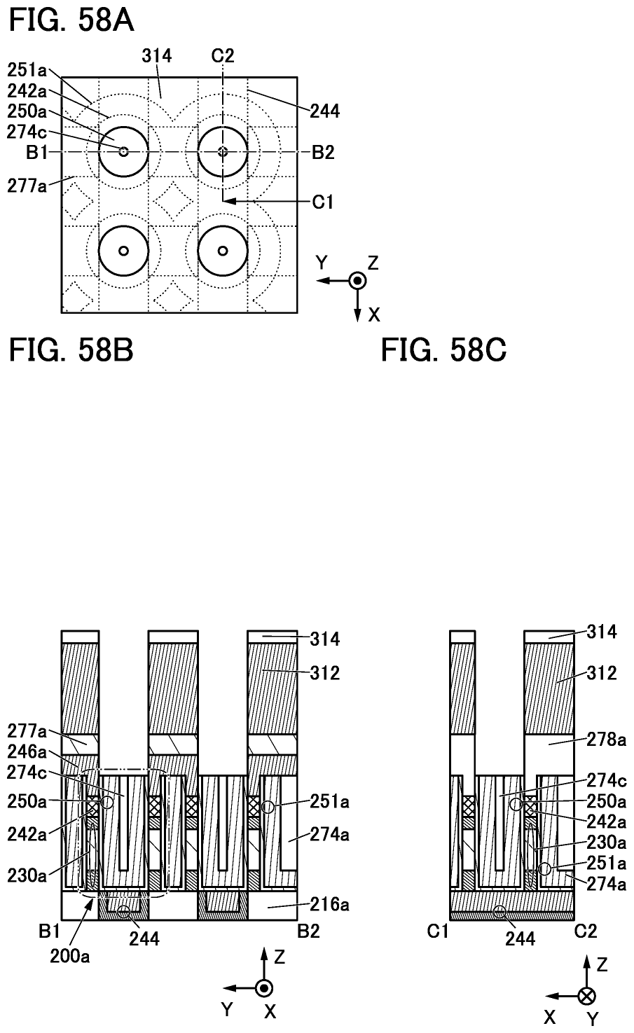

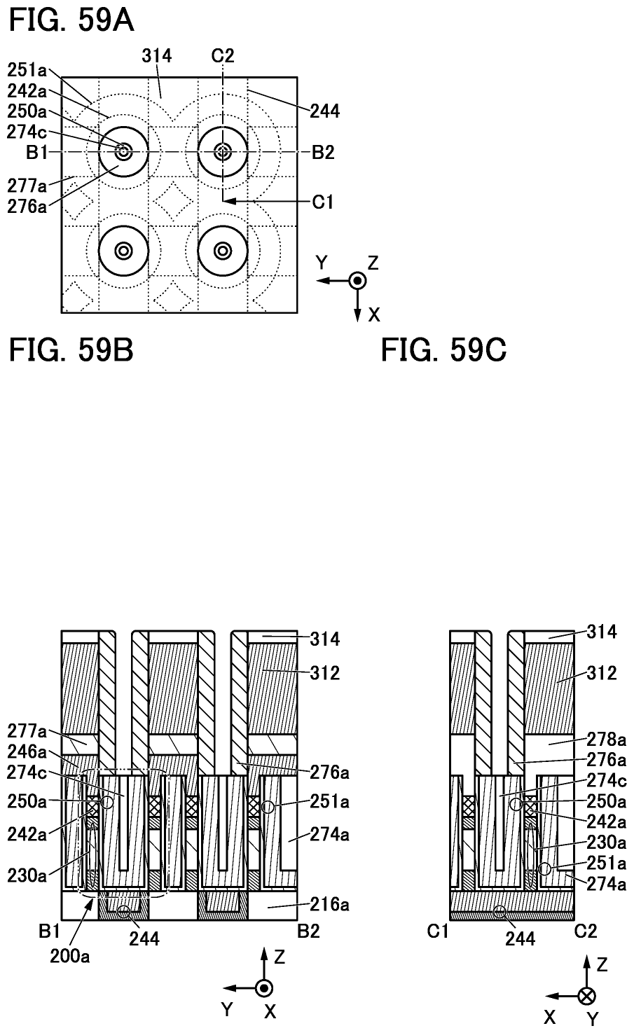

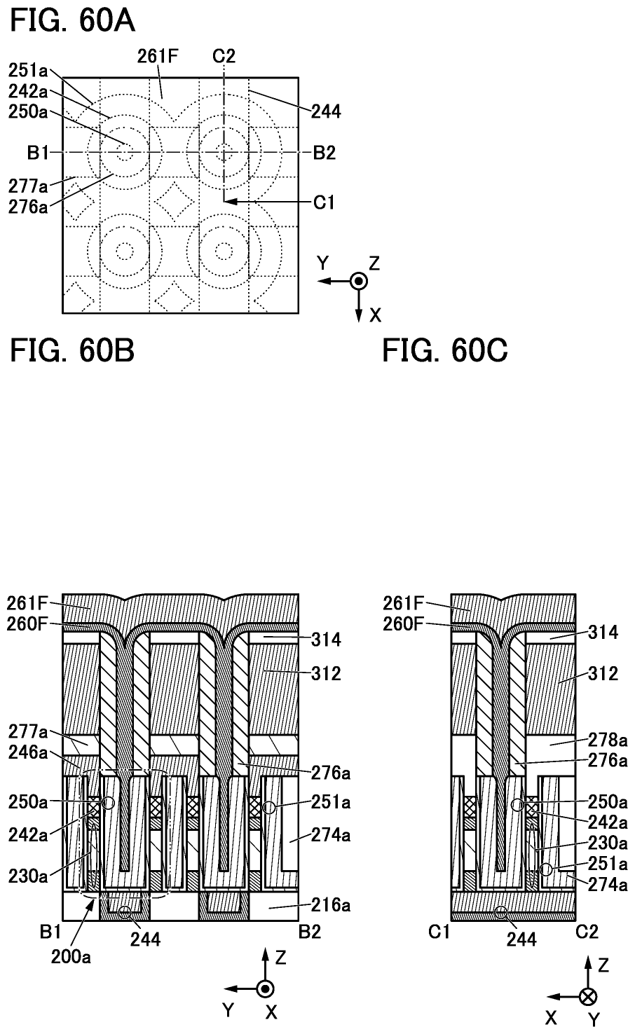

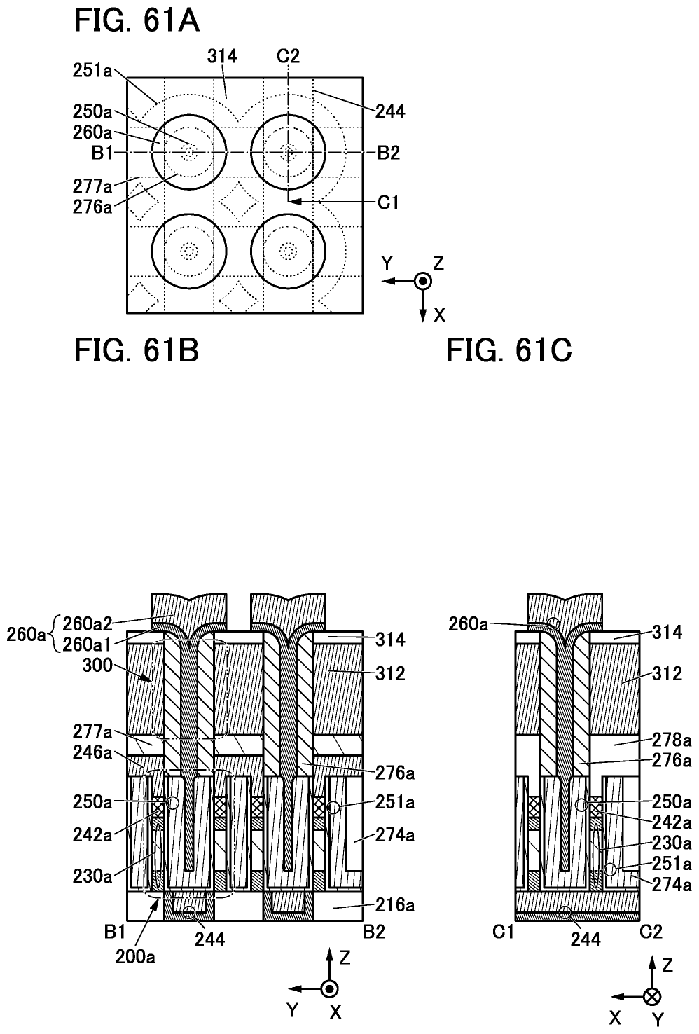

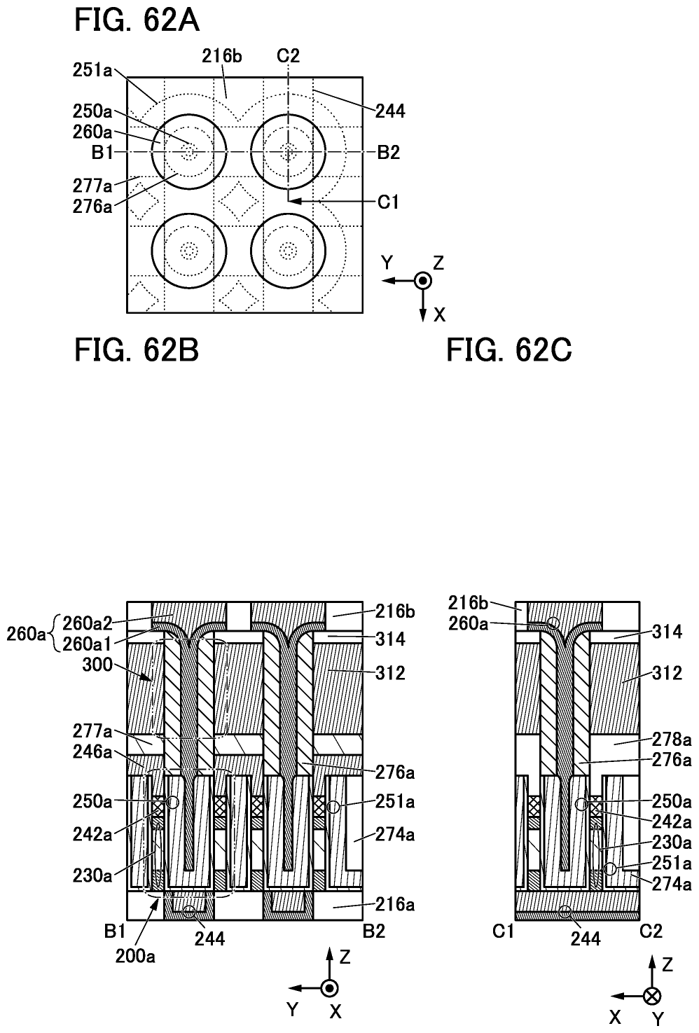

In FIG. 57A to FIG. 62C, FIG. 57A, FIG. 58A, FIG. 59A, FIG. 60A, FIG. 61A, and FIG. 62A are plan views. FIG. 57B, FIG. 58B, FIG. 59B, FIG. 60B, FIG. 61B, and FIG. 62B are cross-sectional views taken along dashed-dotted lines B1-B2 in FIG. 57A, FIG. 58A, FIG. 59A, FIG. 60A, FIG. 61A, and FIG. 62A, respectively. FIG. 57C, FIG. 58C, FIG. 59C, FIG. 60C, FIG. 61C, and FIG. 62C are cross-sectional views taken along dashed-dotted lines C1-C2 in FIG. 57A, FIG. 58A, FIG. 59A, FIG. 60A, FIG. 61A, and FIG. 62A, respectively.

The description with reference to FIG. 24A to FIG. 30C can be referred to for the manufacturing method up to the formation of the insulator 278a; thus, the detailed description thereof is omitted.

Next, the conductor 312 and the insulator 314 are deposited in this order over the insulator 277a and the insulator 278a (see FIGS. 57A to 57C). The above description of the deposition of the conductive film 312F and the insulator 314 can be referred to for the deposition of the conductor 312 and the insulator 314, respectively.

Next, an opening is formed in the insulator 314, the conductor 312, and the insulator 278a (see FIGS. 58A to 58C). The opening is formed to overlap with the insulators 250a and 274c. Note that in the case where the resist mask 292 is formed by the above-described multi-patterning technique, the opening is also formed by the above-described multi-patterning technique.

Next, an insulating film to be the insulator 276a is formed over the insulators 274c, 250a, and 314, and then the insulating film is subjected to anisotropic etching to form the insulator 276a (see FIGS. 59A to 59C). The description in [Method 1 for manufacturing semiconductor device] above can be referred to for the formation of the insulator 276a; thus, the detailed description thereof is omitted.

Then, the insulator 274c is removed. The description in [Method 1 for manufacturing semiconductor device] above can be referred to for the removal of the insulator 274c; thus, the detailed description thereof is omitted.

Next, the conductive film 260F and the conductive film 261F are deposited in this order (see FIGS. 60A to 60C). The description in [Method 1 for manufacturing semiconductor device] above can be referred to for the deposition of the conductive film 260F and the conductive film 261F; thus, the detailed description thereof is omitted.

Next, the conductive film 260F and the conductive film 261F are processed to form the conductor 260al and the conductor 260a2 (see FIGS. 61A to 61C). Note that when the conductive film 260F and the conductive film 261F are processed, part of the insulator 314 in a region not overlapping with the conductor 260a is removed in some cases.

Next, an insulating film to be the insulator 216b is deposited over the conductor 260a and the insulator 314. Next, the insulating film is processed by CMP treatment until the conductor 260a is exposed, whereby the insulator 216b is formed (see FIGS. 62A to 62C). At this time, the top surface of the conductor 260a is planarized. Planarization of the top surfaces of the conductor 260a and the insulator 216b facilitates a later step and the yield of the memory cell can be increased.

Next, the transistor 200b and the conductor 262 are formed. The description in [Method 1 for manufacturing semiconductor device] above can be referred to for the method for forming the transistor 200b and the conductor 262; thus, the detailed description thereof is omitted.

Through the above steps, the semiconductor device illustrated in FIGS. 56A to 56C can be manufactured.

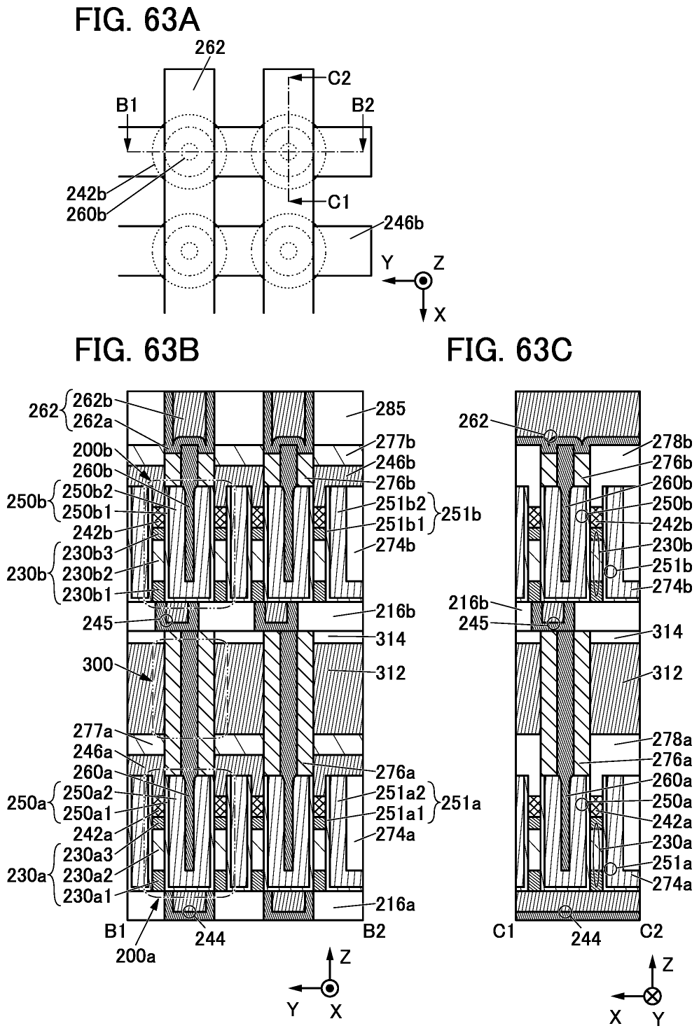

Although FIGS. 56A to 56C illustrate a structure in which the conductor 260a and the oxide 230b are in contact with each other, the present invention is not limited thereto. For example, as illustrated in FIGS. 63A to 63C, the conductor 245 may be provided, and the conductor 260a and the oxide 230b may be connected to each other through the conductor 245.

The memory cell of the semiconductor device illustrated in FIGS. 63A to 63C shows a detailed structure example of the memory cell 100 illustrated in FIGS. 15A to 15C. Note that in FIGS. 63A to 63C, the conductor 312 is provided to have a planar shape.

One embodiment of the present invention can provide a semiconductor device that can be miniaturized or highly integrated. One embodiment of the present invention can provide a semiconductor device with a small variation in electrical characteristics of transistors. One embodiment of the present invention can provide a highly reliable semiconductor device. One embodiment of the present invention can provide a semiconductor device with favorable electrical characteristics. One embodiment of the present invention can provide a semiconductor device having a high on-state current.

This embodiment can be combined with any of the other embodiments as appropriate. In this specification, in the case where a plurality of structure examples are shown in one embodiment, the structure examples can be combined as appropriate.

### Embodiment 2

In this embodiment, a semiconductor device 900 of one embodiment of the present invention will be described. The semiconductor device 900 can function as a memory device.

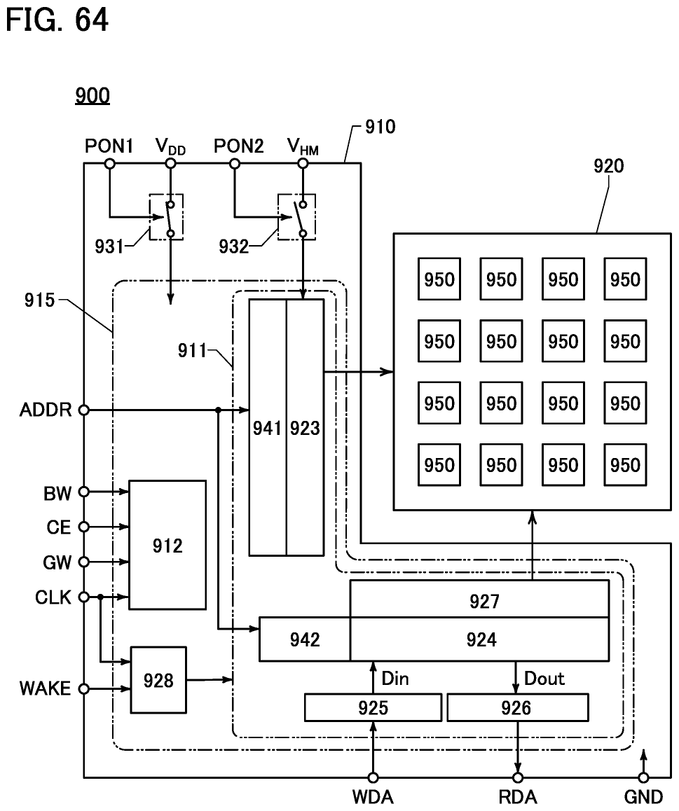

FIG. 64 is a block diagram illustrating a structure example of the semiconductor device 900. The semiconductor device 900 illustrated in FIG. 64 includes a driver circuit 910 and a memory array 920. The memory array 920 includes at least one memory cell 950. FIG. 64 illustrates an example in which the memory array 920 includes a plurality of memory cells 950 arranged in a matrix.

The semiconductor device exemplified in the above embodiment can be used for the memory cell 950.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is applied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925 (Input Cir.), an output circuit 926 (Output Cir.), and a sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, reading data from the memory cell 950, and retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling the supply of V_{DD} to the peripheral circuit 915. The PSW 932 has a function of controlling the supply of V_{HM} to the row driver 923. Here, in the semiconductor device 900, a high power supply voltage is V_{DD} and a low power supply voltage is GND (ground potential). In addition, V_{HM} is a high power supply voltage used for setting a word line to high level, and is higher than V_{DD}. The on/off state of the PSW 931 is controlled by the signal PON1, and the on/off state of the PSW 932 is controlled by the signal PON2. The number of power domains to which V_{DD} is supplied is one in the peripheral circuit 915 in FIG. 64 but can be more than one. In that case, a power switch is provided for each power domain.

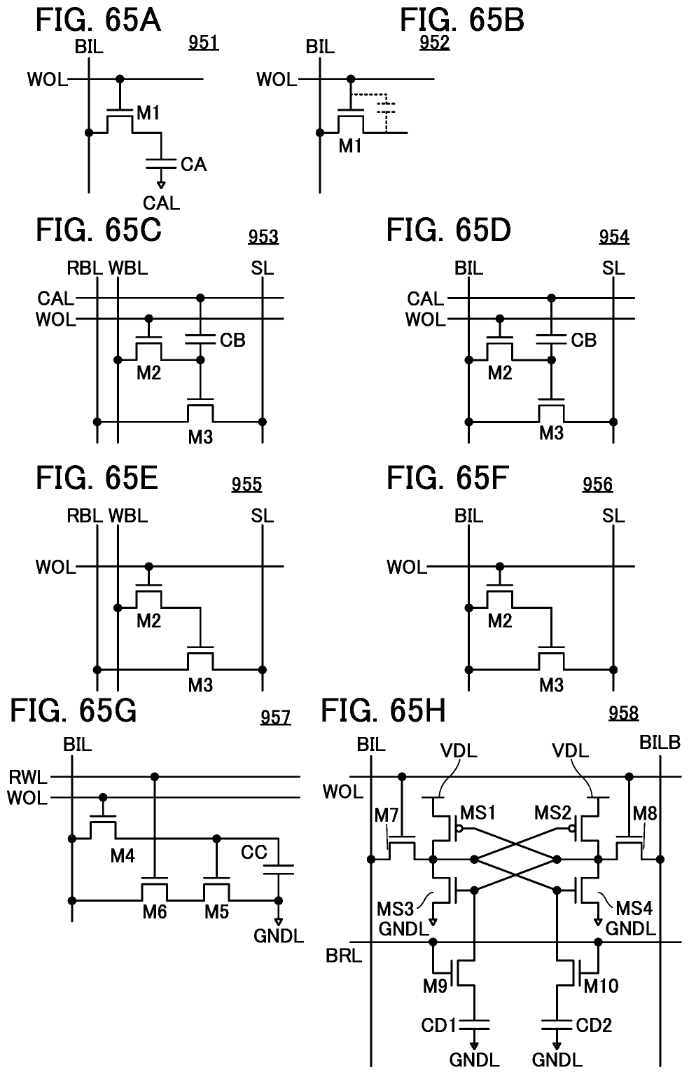

Structure examples of other memory cells each of which can be used as the memory cell 950 are described with reference to FIGS. 65A to 65H.

### [DOSRAM]

FIG. 65A illustrates a circuit configuration example of a memory cell for a DRAM. In this specification and the like, a DRAM using an OS transistor is referred to as a dynamic oxide semiconductor random access memory (DOSRAM). A memory cell 951 includes a transistor M1 and a capacitor CA.

Note that the transistor M1 may include a front gate (simply referred to as a gate in some cases) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to a wiring BIL. The gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and reading, a low-level potential (referred to as a reference potential in some cases) is preferably applied to the wiring CAL. Data writing and data reading are performed in such a manner that a high-level potential is applied to the wiring WOL to turn on the transistor M1, and thus the wiring BIL is connected to the first terminal of the capacitor CA. After the data writing ends, a low-level potential is applied to the wiring WOL to turn off the transistor M1. Thus, the potential of the first terminal of the capacitor CA is retained, so that written data can be retained. Note that the low-level potential applied to the wiring WOL may be a reference potential or a negative potential, for example. In this specification and the like, a negative potential refers to a potential lower than a reference potential. Thus, when the reference potential is 0 V, the negative potential is lower than 0 V. For example, in the case where the transistor M1 has normally-on characteristics, the transistor M1 can be turned off by applying a negative potential to the wiring WOL.

Note that “normally-on characteristics” in this specification and the like mean a state where a channel exists without voltage application to a gate and a current flows through a transistor. Furthermore, “normally-off characteristics” mean a state where a current does not flow through a transistor when no potential or a ground potential is applied to a gate.

The memory cell that can be used as the memory cell 950 is not limited to the memory cell 951, and the circuit configuration can be changed. For example, the configuration of a memory cell 952 illustrated in FIG. 65B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

Note that an OS transistor is preferably used as the transistor M1. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

### [NOSRAM]

FIG. 65C illustrates a circuit configuration example of a gain-cell memory cell including two transistors and one capacitor. A memory cell 953 includes a transistor M2, a transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. In the time of data writing, data retention, and data reading, a low-level potential or a ground potential is preferably applied to the wiring CAL.

Data writing is performed in such a manner that a high-level potential is applied to the wiring WOL to turn on the transistor M2, and thus the wiring WBL is connected to the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading a potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

The memory cell 100 described in Embodiment 1 can be used as the memory cell 953 illustrated in FIG. 65C. In this case, the transistor M2, the transistor M3, and the capacitor CB correspond to the transistor 200b, the transistor 200a, and the capacitor 300, respectively.

A miniaturized memory device including Si transistors has a high leakage current between Si transistors, between capacitors, or between a Si transistor and a capacitor. A leakage current hinders long-term retention of stored contents, so that in a conventional technique, stored contents are retained while the capacitance value of a capacitor is increased by using a high-k material for the capacitor, increasing the height of the capacitor, or the like. However, the use of a high-k material and a low leakage current often have a trade-off relationship, and thus it is difficult to obtain a large capacitance value by changing materials. Moreover, in terms of the height of a capacitor, a too high aspect ratio is making it difficult to solve a technical problem in a process.

In addition, due to a substrate floating effect or the like, it is technically difficult to employ the 4F² design rule including a vertical transistor for a miniaturized memory device including a Si transistor. Minimization of the design rule, specifically, employment of the 4F² design rule instead of the 6F² design rule is difficult, which is making also a cost problem hard to solve.

In contrast, an OS transistor has a low off-state current. Thus, by including an OS transistor, the semiconductor device can retain stored contents for a long time. In other words, such a semiconductor device does not require refresh operation or has an extremely low frequency of refresh operation, leading to a sufficient reduction in power consumption. Therefore, a semiconductor device with low power consumption can be provided. An OS transistor has high resistance to a short-channel effect. Accordingly, an OS transistor is hardly affected by a substrate floating effect even with a vertical structure and can easily have a short channel length even with a thick gate insulating film. That is, a gate leakage current can be reduced, so that the memory device can have improved retention characteristics.

In the case where a ground potential is applied to the wiring CAL, electrodes to each of which the ground potential is applied are adjacent to each other between the capacitors, so that a leakage current is not generated between the capacitors. As illustrated in FIGS. 1A and 1B, FIG. 9, or the like, when the conductor 312 is provided to extend or have a planar shape, a leakage current between the capacitors can be prevented.

The data reading time depends on the switching speed of the transistor M3 in a NOSRAM, and depends on the time taken for a change in the potential of the wiring BIL due to charge redistribution between the capacitor CA and the wiring BIL in a DOSRAM. Thus, the data reading time is short in the NOSRAM. Furthermore, the capacitance of the capacitor can be smaller in the NOSRAM than in the DOSRAM; thus, the data writing time is short in the NOSRAM. Thus, with the NOSRAM structure, a semiconductor device that operates at high speed can be provided. Meanwhile, the DOSRAM has a smaller number of transistors per memory cell than the NOSRAM; thus, the manufacturing cost of a semiconductor device can be reduced.

As another example, one wiring BIL may be provided instead of the wiring WBL and the wiring RBL. A circuit configuration example of the memory cell is illustrated in FIG. 65D. In a memory cell 954, one wiring BIL is provided instead of the wiring WBL and the wiring RBL in the memory cell 953, and the second terminal of the transistor M2 and the first terminal of the transistor M3 are electrically connected to the wiring BIL. In other words, one wiring BIL operates as the write bit line and the read bit line in the memory cell 954.

A memory cell 955 illustrated in FIG. 65E is an example in which the capacitor CB and the wiring CAL in the memory cell 953 are omitted. A memory cell 956 illustrated in FIG. 65F is an example in which the capacitor CB and the wiring CAL in the memory cell 954 are omitted. Such structures enable high integration of the memory cell.

Note that an OS transistor is preferably used as at least the transistor M2. In particular, an OS transistor is preferably used as each of the transistors M2 and M3.

Since the OS transistor has a characteristic of an extremely low off-state current, written data can be retained for a long time with the use of the transistor M2, and thus the frequency of refresh operation for the memory cell can be decreased. Alternatively, refresh operation for the memory cell can be omitted. In addition, owing to an extremely low leakage current, multilevel data or analog data can be retained in the memory cells 953, 954, 955, and 956.

The memory cells 953, 954, 955, and 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

When the OS transistor is used as the transistor M3, the memory cell can be configured with the transistors having the same conductivity type.

FIG. 65G illustrates an example of a gain memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is electrically connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is electrically connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed in such a manner that a high-level potential is applied to the wiring WOL to turn on the transistor M4, and thus the wiring BIL is connected to the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL to a predetermined potential, and then making the wiring BIL in an electrically floating state and applying a high-level potential to the wiring RWL. Since the wiring RWL has the high-level potential, the transistor M6 is turned on, so that the wiring BIL is electrically connected to the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than the OS transistor depending on the crystal state of silicon used in a semiconductor layer, for example.

When OS transistors are used as the transistors M5 and M6, the memory cell can be configured with the transistors having the same conductivity type.

### [OS-SRAM]

FIG. 65H illustrates an example of a static random access memory (SRAM) using an OS transistor. In this specification and the like, an SRAM using an OS transistor is referred to as an oxide semiconductor SRAM (OS-SRAM). A memory cell 958 illustrated in FIG. 65H is a memory cell of an SRAM capable of backup operation.

The memory cell 958 includes transistors M7 to M10, transistors MS1 to MS4, a capacitor CD1, and a capacitor CD2. The transistors MS1 and MS2 are p-channel transistors, and the transistors MS3 and MS4 are n-channel transistors.

A first terminal of the transistor M7 is connected to the wiring BIL. A second terminal of the transistor M7 is connected to a first terminal of the transistor MS1, a first terminal of the transistor MS3, a gate of the transistor MS2, a gate of the transistor MS4, and a first terminal of the transistor M10. A gate of the transistor M7 is connected to the wiring WOL. A first terminal of the transistor M8 is connected to a wiring BILB. A second terminal of the transistor M8 is connected to a first terminal of the transistor MS2, a first terminal of the transistor MS4, a gate of the transistor MS1, a gate of the transistor MS3, and a first terminal of the transistor M9. A gate of the transistor M8 is connected to the wiring WOL.

A second terminal of the transistor MS1 is electrically connected to a wiring VDL. A second terminal of the transistor MS2 is electrically connected to the wiring VDL. A second terminal of the transistor MS3 is electrically connected to the wiring GNDL. A second terminal of the transistor MS4 is electrically connected to the wiring GNDL.

A second terminal of the transistor M9 is connected to a first terminal of the capacitor CD1. The gate of the transistor M9 is connected to a wiring BRL. A second terminal of the transistor M10 is connected to a first terminal of the capacitor CD2. The gate of the transistor M10 is connected to the wiring BRL.

A second terminal of the capacitor CD1 is connected to the wiring GNDL. A second terminal of the capacitor CD2 is connected to the wiring GNDL.

The wiring BIL and the wiring BILB function as bit lines. The wiring WOL functions as a word line. The wiring BRL controls the on/off states of the transistors M9 and M10. The wiring VDL supplies a high-level potential. The wiring GNDL supplies a low-level potential.

Data writing is performed by applying a high-level potential to the wiring WOL and the wiring BRL. Specifically, when the transistor M10 is on, a potential corresponding to data to be stored is applied to the wiring BIL, and the potential is written to the second terminal side of the transistor M10.

In the memory cell 958, the transistors MS1 and MS2 form an inverter loop; hence, an inversion signal of a data signal corresponding to the potential is input to the second terminal side of the transistor M8. Since the transistor M8 is on, an inversion signal of the potential that has been applied to the wiring BIL (i.e., the signal that has been input to the wiring BIL) is output to the wiring BILB. Since the transistor M9 and the transistor M10 are on, the potential of the second terminal of the transistor M7 is retained in the first terminal of the capacitor CD2, and the potential of the second terminal of the transistor M8 is retained in the first terminal of the capacitor CD1. After that, a low-level potential is applied to the wiring WOL and the wiring BRL to turn off the transistors M7 to M10, whereby the potential of the first terminal of the capacitor CD1 and the potential of the first terminal of the capacitor CD2 are retained.

Data reading is performed in such a manner that the wiring BIL and the wiring BILB are precharged to a predetermined potential, and then a high-level potential is applied to the wiring WOL and the wiring BRL, whereby the potential of the first terminal of the capacitor CD1 is refreshed by the inverter loop in the memory cell 958 and output to the wiring BILB. Furthermore, the potential of the first terminal of the capacitor CD2 is refreshed by the inverter loop in the memory cell 958 and output to the wiring BIL. Since the potentials of the wiring BIL and the wiring BILB are changed from the precharged potentials to the potentials of the first terminal of the capacitor CD2 and the first terminal of the capacitor CD1, the potential retained in the memory cell can be read on the basis of the potentials of the wiring BIL and the wiring BILB.

Note that the transistors M7 to M10 are preferably OS transistors. In this case, with the use of the transistors M7 to M10, written data can be retained for a long time, and thus the frequency of refresh operation for the memory cell can be decreased. Alternatively, refresh operation for the memory cell can be omitted.

Note that the transistors MS1 to MS4 may be Si transistors.

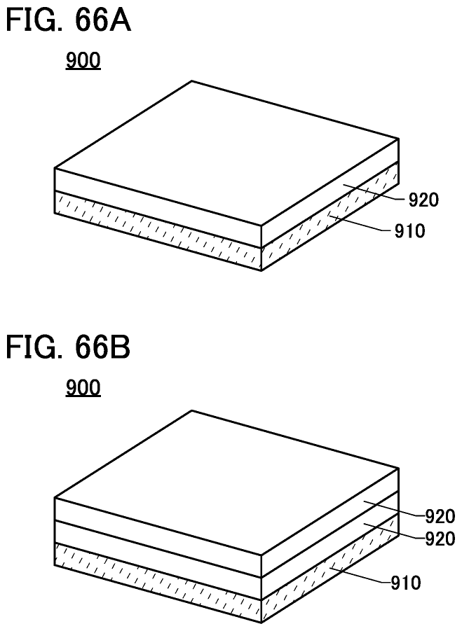

The driver circuit 910 and the memory array 920 included in the semiconductor device 900 may be provided on the same plane. Alternatively, as illustrated in FIG. 66A, the driver circuit 910 and the memory array 920 may be provided to overlap each other. Overlapping the driver circuit 910 and the memory array 920 can shorten a signal propagation distance. As illustrated in FIG. 66B, a plurality of memory arrays 920 may be stacked over the driver circuit 910. Note that it is assumed that the driver circuit 910 and the memory array 920 are not provided on the same plane because of the manufacturing process, so that the expression “on substantially the same plane” can be rephrased as “on the same plane”.

When an OS transistor is used as the transistor included in the memory array 920, the transistor can be formed during the BEOL process for forming a wiring of the semiconductor device 900. In the case where a Si transistor is used for the driver circuit 910 provided below the memory array 920, by employing the BEOL-Tr technique (the technique in which an OS transistor is directly formed on the Si transistor), the semiconductor device 900 can be miniaturized.

Next, description is made on an example of an arithmetic processing device that can include the semiconductor device, such as the memory device described above.

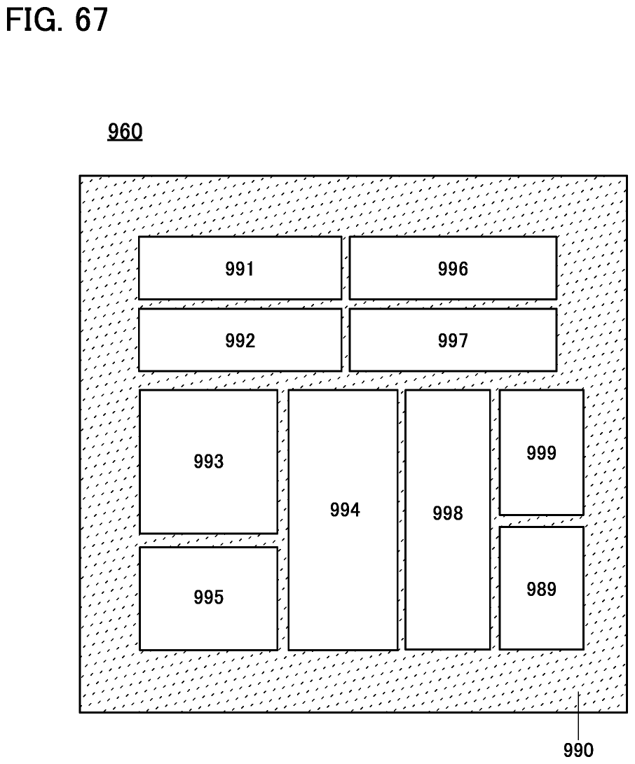

FIG. 67 is a block diagram of an arithmetic device 960. The arithmetic device 960 illustrated in FIG. 67 can be used for a CPU, for example. The arithmetic device 960 can also be used for a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 67 includes, over a substrate 990, an arithmetic logic unit (ALU) 991, an ALU controller 992, an instruction decoder 993, an interrupt controller 994, a timing controller 995, a register 996, a register controller 997, a bus interface 998, a cache 999, and a cache interface 989. A semiconductor substrate, an SOI substrate, a glass substrate, or the like is used as the substrate 990. The arithmetic device 960 may also include a rewritable ROM and a ROM interface. The cache 999 and the cache interface 989 may be provided in a separate chip.

The cache 999 is connected via the cache interface 989 to a main memory provided in another chip. The cache interface 989 has a function of supplying part of data retained in the main memory to the cache 999. The cache interface 989 also has a function of outputting part of data retained in the cache 999 to the ALU 991, the register 996, or the like through the bus interface 998.

As described later, the memory array 920 can be stacked over the arithmetic device 960. The memory array 920 can be used as a cache. Here, the cache interface 989 may have a function of supplying data retained in the memory array 920 to the cache 999. Moreover, in this case, the driver circuit 910 is preferably included in part of the cache interface 989.

Note that it is also possible that the cache 999 is not provided and only the memory array 920 is used as a cache.

The arithmetic device 960 illustrated in FIG. 67 is only an example with a simplified configuration, and the actual arithmetic device 960 has a variety of configurations depending on the application. For example, what is called a multicore configuration is preferably employed in which a plurality of cores each including the arithmetic device 960 in FIG. 67 operate in parallel. The larger number of cores can further enhance the arithmetic performance. The number of cores is preferably larger; for example, the number is preferably 2, further preferably 4, still further preferably 8, still further preferably 12, yet still further preferably 16 or larger. For application requiring extremely high arithmetic performance, e.g., a server, it is preferable to employ the multicore configuration including 16 or more, preferably 32 or more, further preferably 64 or more cores. The number of bits that the arithmetic device 960 can handle with an internal arithmetic circuit or a data bus can be 8, 16, 32, or 64, for example.

An instruction input to the arithmetic device 960 through the bus interface 998 is input to the instruction decoder 993 and decoded, and then input to the ALU controller 992, the interrupt controller 994, the register controller 997, and the timing controller 995.

The ALU controller 992, the interrupt controller 994, the register controller 997, and the timing controller 995 conduct various controls in accordance with the decoded instruction. Specifically, the ALU controller 992 generates signals for controlling the operation of the ALU 991. The interrupt controller 994 judges and processes an interrupt request from an external input/output device, a peripheral circuit, or the like on the basis of its priority, a mask state, or the like while the arithmetic device 960 is executing a program. The register controller 997 generates the address of the register 996, and reads/writes data from/to the register 996 in accordance with the state of the arithmetic device 960.

The timing controller 995 generates signals for controlling operation timings of the ALU 991, the ALU controller 992, the instruction decoder 993, the interrupt controller 994, and the register controller 997. For example, the timing controller 995 includes an internal clock generator for generating an internal clock signal on the basis of a reference clock signal, and supplies the internal clock signal to the above circuits.

In the arithmetic device 960 in FIG. 67, the register controller 997 selects operation of retaining data in the register 996 in accordance with an instruction from the ALU 991. That is, the register controller 997 selects whether data is retained by a flip-flop or by a capacitor in a memory cell included in the register 996. When data retention by the flip-flop is selected, power supply voltage is supplied to the memory cell in the register 996. When data retention by the capacitor is selected, the data is rewritten into the capacitor, and supply of power supply voltage to the memory cell in the register 996 can be stopped.

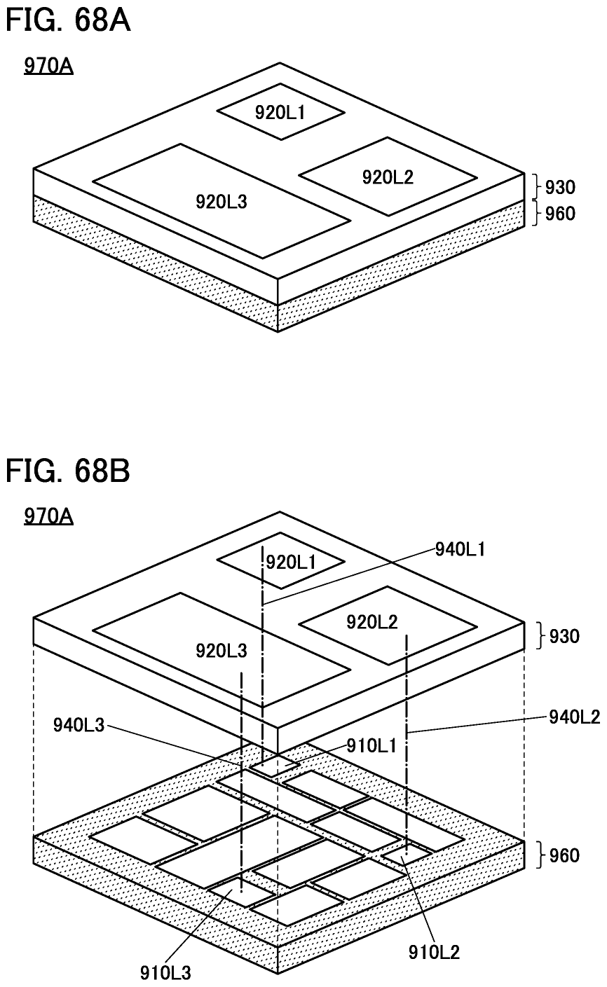

The memory array 920 and the arithmetic device 960 can be provided to overlap with each other. FIGS. 68A and 68B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 68B.

Overlapping the arithmetic device 960 and the layer 930 including the memory arrays can shorten the connection distance therebetween. Accordingly, the communication speed therebetween can be increased. Moreover, a short connection distance leads to lower power consumption.

As a method for stacking the layer 930 including the memory arrays and the arithmetic device 960, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are electrically connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 999 and the memory arrays 920L1, 920L2, and 920L3 provided in the layer 930 are each used as a cache. In this case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 999 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 68B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Note that although the case where three memory arrays function as caches is described here, the number of memory arrays may be one, two, or four or more.

In the case where the memory array 920L1 is used as a cache, the driver circuit 910L1 may function as part of the cache interface 989 or the driver circuit 910L1 may be connected to the cache interface 989. Similarly, each of the driver circuits 910L2 and 910L3 may function as part of the cache interface 989 or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

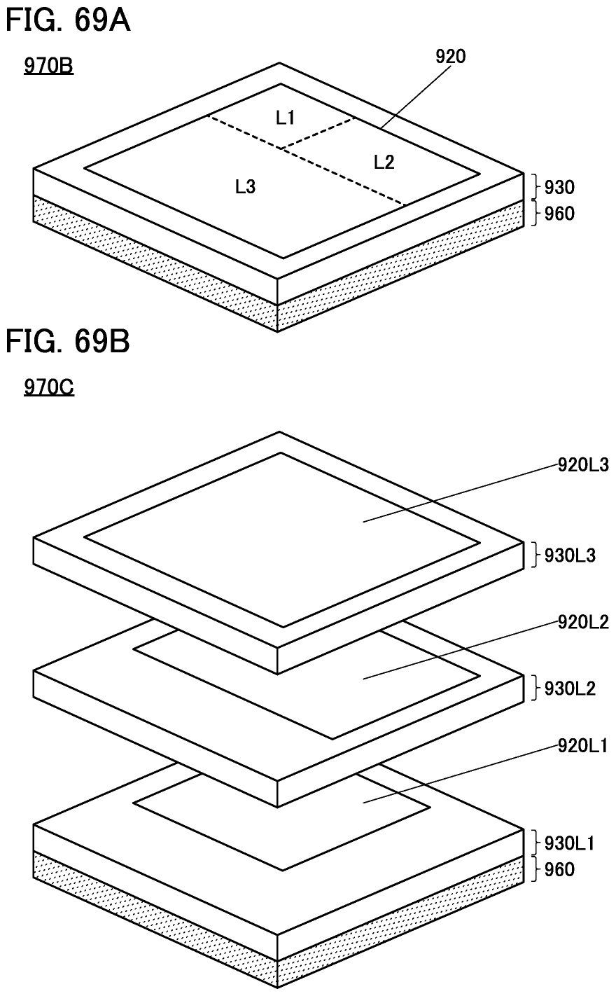

The layer 930 including one memory array 920 may be provided to overlap with the arithmetic device 960. FIG. 69A is a perspective view of a semiconductor device 970B.

In the semiconductor device 970B, one memory array 920 can be divided into a plurality of areas having different functions. FIG. 69A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 69B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

Note that this embodiment can be combined with any of the other embodiments in this specification as appropriate.

### Embodiment 3

In this embodiment, application examples of the memory device of one embodiment of the present invention will be described.

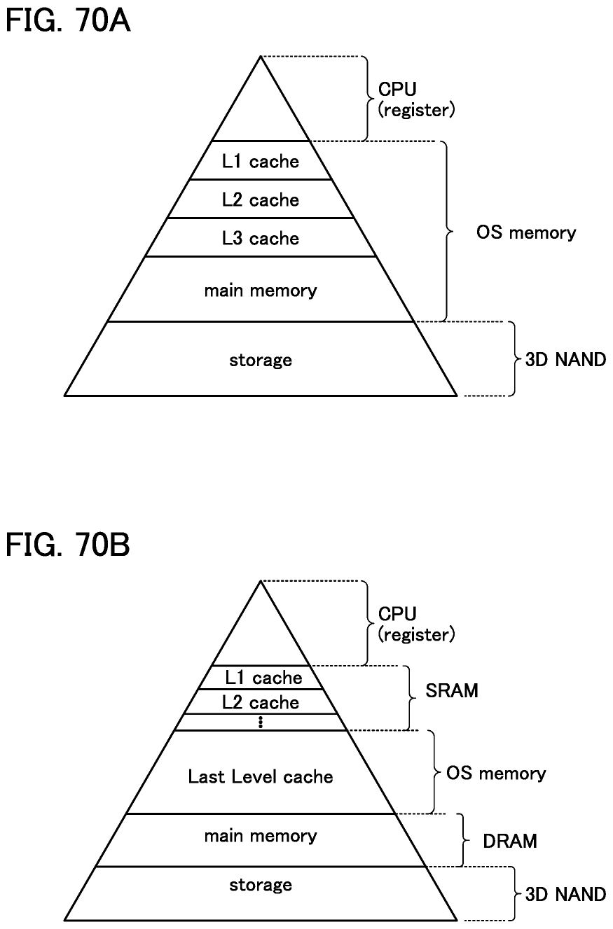

In general, a variety of memory devices are used in semiconductor devices such as computers in accordance with the intended use. FIG. 70A illustrates the hierarchy of various memory devices used in a semiconductor device. The memory devices at the upper levels require a higher operating speed, whereas the memory devices at the lower levels require a larger memory capacity and a higher memory density. FIG. 70A illustrates, for example, a memory included as a register in an arithmetic processing device such as a CPU, an L1 cache, an L2 cache, an L3 cache, a main memory, and a storage in this order from the uppermost layer. Although the caches up to the L3 cache are included in this example, a lower-level cache may be further included.

A memory included as a register in an arithmetic processing device such as a CPU is used for temporary storage of arithmetic operation results, for example, and thus is very frequently accessed by the arithmetic processing device. Accordingly, rapid operation is more important than the memory capacity of the memory. The register also has a function of retaining settings of the arithmetic processing device, for example.

The cache has a function of duplicating and retaining part of data retained in the main memory. Duplicating frequently used data and retaining the duplicated data in the cache facilitates rapid data access. The cache requires a smaller memory capacity than the main memory but a higher operating speed than the main memory. Data that is rewritten in the cache is duplicated, and the duplicated data is supplied to the main memory.

The main memory has a function of retaining a program and data that are read from the storage.

The storage has a function of retaining data that needs to be stored for a long time and programs used in an arithmetic processing device, for example. Therefore, the storage needs to have a high memory capacity and a high memory density rather than operating speed. For example, a high-capacity nonvolatile memory device such as a 3D NAND memory device can be used.

The memory device including an oxide semiconductor (the OS memory) of one embodiment of the present invention operates fast and can retain data for a long time. Thus, as illustrated in FIG. 70A, the memory device of one embodiment of the present invention can be favorably used at both the level including the cache and the level including the main memory. The memory device of one embodiment of the present invention can also be used at the level including the storage.

FIG. 70B illustrates an example in which an SRAM is used as at least one of the caches and the OS memory of one embodiment of the present invention is used as the other cache.

The lowest-level cache can be referred to as a last level cache (LLC). The LLC does not require a higher operation speed than a higher-level cache, but desirably has large storage capacity. The OS memory of one embodiment of the present invention operates at high speed and can retain data for a long time, and thus can be suitably used as the LLC. Note that the OS memory of one embodiment of the present invention can also be used as a final level cache (FLC).

For example, as illustrated in FIG. 70B, an SRAM can be used as the higher-level caches (the L1 cache, the L2 cache, and the like), and the OS memory of one embodiment of the present invention can be used as the LLC. Moreover, instead of the OS memory, a DRAM can be used as the main memory as illustrated in FIG. 70B.

Note that this embodiment can be combined with any of the other embodiments in this specification as appropriate.

### Embodiment 4

An electronic component, an electronic device, a large computer, a device for space, and a data center (also referred to as DC) for which the semiconductor device described in the above embodiments will be described in this embodiment. An electronic component, an electronic device, a large computer, a device for space, and a data center each employing the semiconductor device of one embodiment of the present invention are effective in improving performance, for example, reducing power consumption.

### [Electronic Component]

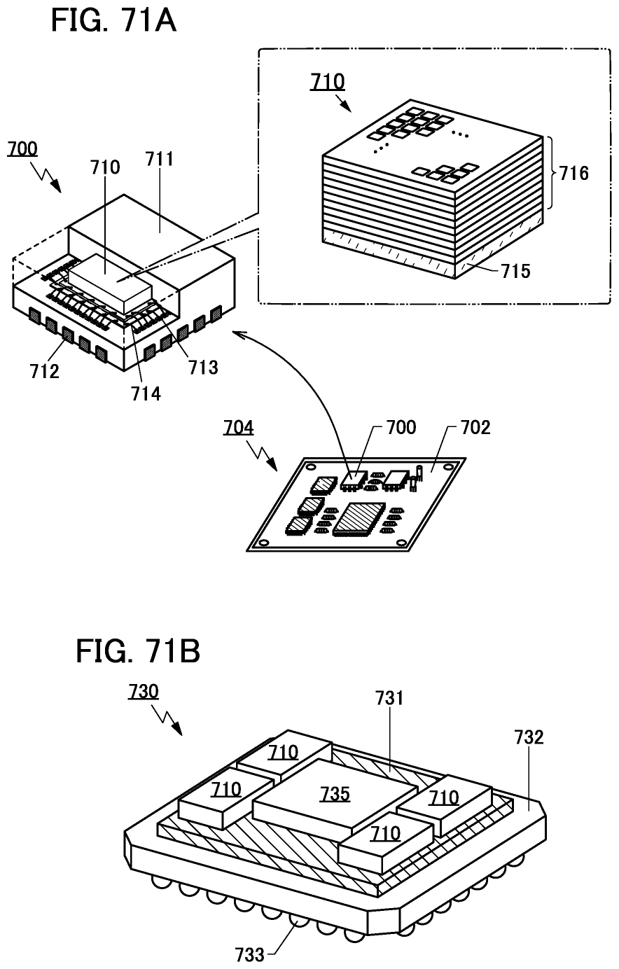

FIG. 71A is a perspective view of a substrate (a circuit board 704) provided with an electronic component 700. The electronic component 700 illustrated in FIG. 71A includes a semiconductor device 710 in a mold 711. Some components are omitted in FIG. 71A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected without using a through electrode technique such as a through-silicon via (TSV) technique and a bonding technique such as Cu—Cu direct bonding. By monolithically stacking the driver circuit layer 715 and the memory layer 716, for example, what is called an on-chip memory structure in which a memory is directly formed on a processor can be obtained. The on-chip memory structure allows an interface portion between the processor and the memory to operate at high speed.

With the on-chip memory structure, the sizes of a connection wiring and the like can be smaller than those in the case where the through electrode technique such as the TSV technique is employed, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 716 be formed with OS transistors and be monolithically stacked. The monolithic stacked-layer structure of a plurality of memory cell arrays can improve the bandwidth of the memory and/or the access latency of the memory. Note that the bandwidth refers to the data transfer volume per unit time, and the access latency refers to a period of time from data access to the start of data transmission. Note that in the case where the memory layer 716 is formed with Si transistors, the monolithic stacked-layer structure is difficult to form compared with the case where the memory layer 716 is formed with OS transistors. Therefore, an OS transistor is superior to a Si transistor in the monolithic stacked-layer structure.

The semiconductor device 710 may be called a die. Note that in this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

Next, FIG. 71B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are electrically connected with use of a silicon interposer, a TSV, and the like, a space for a width of the terminal pitch and the like is needed. Accordingly, in the case where the size of the electronic component 730 is reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 71B illustrates an example in which the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Electronic Device]

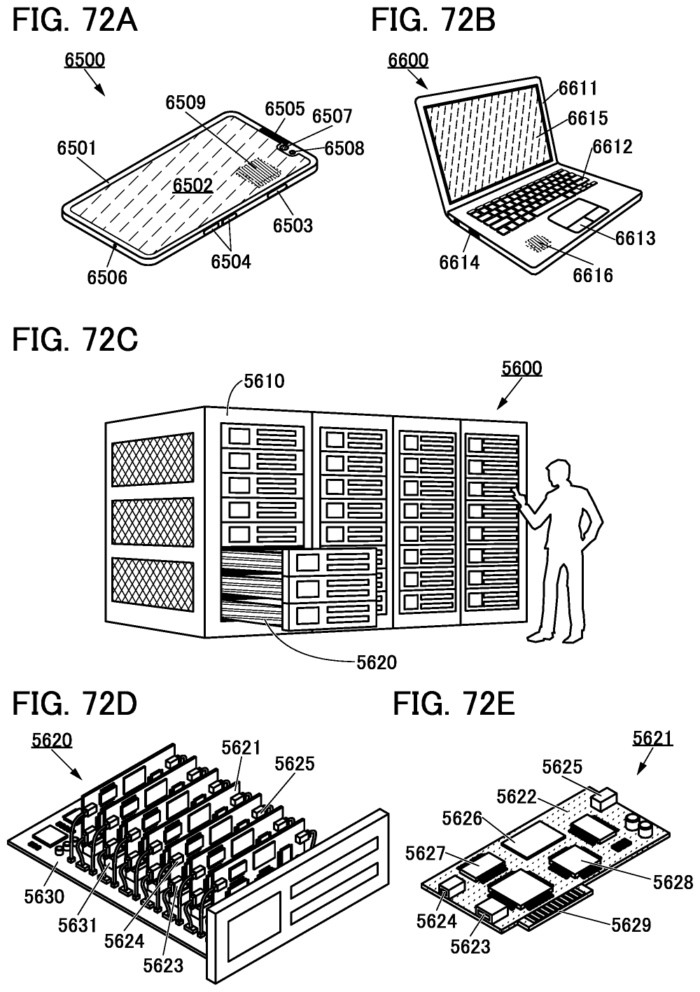

Next, FIG. 72A is a perspective view of an electronic device 6500. The electronic device 6500 illustrated in FIG. 72A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. Note that as the control device 6509, for example, one or more selected from a CPU, a GPU, and a memory device are included. The semiconductor device of one embodiment of the present invention can be used for the display portion 6502, the control device 6509, and the like.

An electronic device 6600 illustrated in FIG. 72B is an information terminal that can be used as a laptop computer. The electronic device 6600 includes a housing 6611, a keyboard 6612, a pointing device 6613, an external connection port 6614, a display portion 6615, a control device 6616, and the like. Note that as the control device 6616, for example, one or more selected from a CPU, a GPU, and a memory device are included. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

Next, FIG. 72C is a perspective view of a large computer 5600. In the large computer 5600 illustrated in FIG. 72C, a plurality of rack mount computers 5620 are stored in a rack 5610. Note that the large computer 5600 may be referred to as a supercomputer.

The computer 5620 can have a structure in a perspective view illustrated in FIG. 72D, for example. In FIG. 72D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 72E is an example of a processing board provided with a CPU, a GPU, a memory device, and the like. The PC card 5621 includes a board 5622. The board 5622 includes a connection terminal 5623, a connection terminal 5624, a connection terminal 5625, a semiconductor device 5626, a semiconductor device 5627, a semiconductor device 5628, and a connection terminal 5629. Note that FIG. 72E also illustrates semiconductor devices other than the semiconductor device 5626, the semiconductor device 5627, and the semiconductor device 5628, and the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can serve as, for example, an interface for performing power supply, signal input, or the like to the PC card 5621. As another example, they can serve as an interface for outputting a signal calculated by the PC card 5621. Examples of the standard for each of the connection terminal 5623, the connection terminal 5624, and the connection terminal 5625 include Universal Serial Bus (USB), Serial ATA (SATA), and Small Computer System Interface (SCSI). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device or the like. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Device for Space]

The semiconductor device of one embodiment of the present invention can be suitably used as a device for space, such as devices processing and storing information.

The semiconductor device of one embodiment of the present invention can include an OS transistor. A change in electrical characteristics of the OS transistor due to radiation irradiation is small. That is, the OS transistor is highly resistant to radiation, and thus can be suitably used even in an environment where radiation can enter. For example, the OS transistor can be suitably used in outer space.

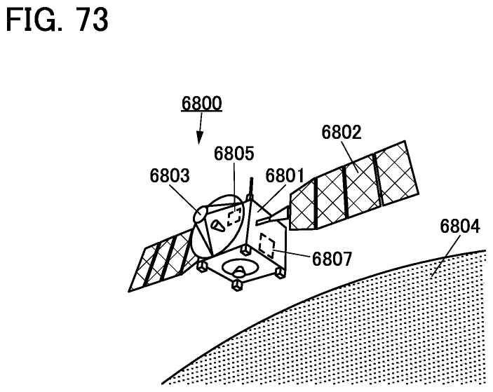

FIG. 73 illustrates an artificial satellite 6800 as an example of a device for space. The artificial satellite 6800 includes a body 6801, a solar panel 6802, an antenna 6803, a secondary battery 6805, and a control device 6807. In FIG. 73, a planet 6804 in outer space is illustrated as an example. Note that outer space refers to, for example, space at an altitude greater than or equal to 100 km, and outer space described in this specification can also include thermosphere, mesosphere, and stratosphere.

Although not illustrated in FIG. 73, a battery management system (also referred to as BMS) or a battery control circuit may be provided in the secondary battery 6805. The battery management system or the battery control circuit preferably uses the OS transistor, in which case it has low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beam, proton beam, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device of one embodiment of the present invention is suitably used for the control device 6807. A change in electrical characteristics of the OS transistor due to radiation irradiation is smaller than a change in electrical characteristics of a Si transistor. Accordingly, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of a device for space in this embodiment, one embodiment of the present invention is not limited to this example. The semiconductor device of one embodiment of the present invention can be suitably used for a device for space such as a spacecraft, a space capsule, or a space probe, for example.

As described above, an OS transistor has excellent effects of achieving a wide memory bandwidth and being highly resistant to radiation as compared with a Si transistor.

### [Data Center]

The semiconductor device of one embodiment of the present invention can be suitably used for, for example, a storage system in a data center or the like. Long-term management of data, such as guarantee of data immutability, is required for the data center. The long-term management of data needs setting a storage or a server for retaining a huge amount of data, stable power supply for retaining data, cooling equipment for retaining data, an increase in building size, and the like.

With use of the semiconductor device of one embodiment of the present invention for a storage system in a data center, electric power used for retaining data can be reduced and a semiconductor device for retaining data can be reduced in size. Accordingly, reductions in sizes of the storage system and the power supply for retaining data, downscaling of the cooling equipment, and the like can be achieved. Therefore, a space of the data center can be reduced.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

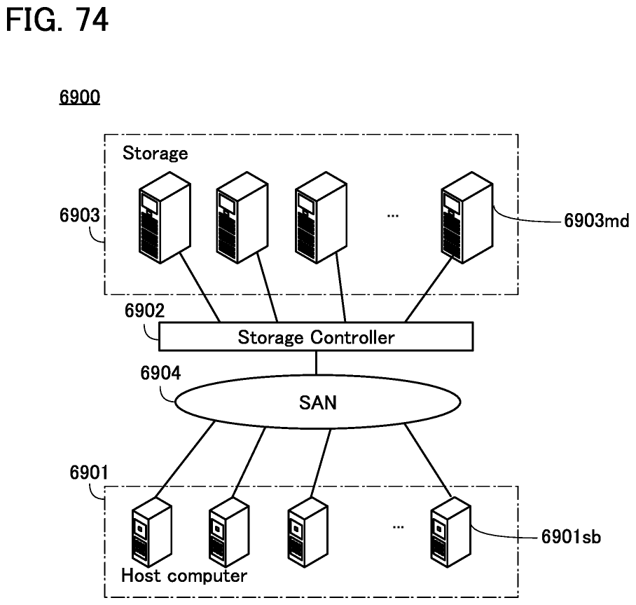

FIG. 74 illustrates a storage system that can be used in a data center. A storage system 6900 illustrated in FIG. 74 includes a plurality of servers 6901sb as a host 6901 (indicated as “Host Computer” in the diagram). The storage system 6900 includes a plurality of memory devices 6903md as a storage 6903 (indicated as “Storage” in the diagram). In the illustrated example, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer which accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in the storage 6903. In the storage system 6900, in order to solve the problem of low access speed of the storage 6903, a cache memory is normally provided in the storage 6903 to shorten the time for data storage and output.

The above-described cache memory is used in the storage control circuit 6902 and the storage 6903. The data transmitted between the host 6901 and the storage 6903 is stored in the cache memories in the storage control circuit 6902 and the storage 6903 and then output to the host 6901 or the storage 6903.

With a configuration in which an OS transistor is used as a transistor for storing data in the cache memory to retain a potential based on data, the frequency of refreshing can be decreased, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be implemented in an appropriate combination with any of the structures described in any of the other embodiments.

This application is based on Japanese Patent Application Serial No. 2023-039908 filed with Japan Patent Office on Mar. 14, 2023, the entire contents of which are hereby incorporated by reference.

What is claimed is:

1. A semiconductor device comprising:
a first transistor;
a capacitor over the first transistor; and
a second transistor over the capacitor,
wherein each of the first transistor and the second transistor comprises:
a semiconductor layer;
a first conductor over the semiconductor layer;
a first insulator; and
a second conductor over the first insulator,
wherein, in each of the first transistor and the second transistor, a side surface of the semiconductor layer is aligned with a side surface of the first conductor,
wherein, in each of the first transistor and the second transistor, each of the semiconductor layer and the first conductor comprises an opening,
wherein, in each of the first transistor and the second transistor, the first insulator is positioned inside the opening of the semiconductor layer and the opening of the first conductor,
wherein, in each of the first transistor and the second transistor, the first insulator comprises a depressed portion overlapping with the opening of the semiconductor layer and the opening of the first conductor,
wherein, in each of the first transistor and the second transistor, the second conductor fills the depressed portion,
wherein the capacitor comprises a third conductor serving as one of a pair of electrodes, and
wherein the second conductor of the first transistor is electrically connected to the semiconductor layer of the second transistor through the third conductor of the capacitor.

2. The semiconductor device according to claim 1, further comprising a fourth conductor,
wherein the third conductor of the capacitor is electrically connected to the semiconductor layer of the second transistor through the fourth conductor.

3. The semiconductor device according to claim 2,
wherein in a plan view, a center of the fourth conductor is shifted from a center of the opening of the semiconductor layer of the second transistor, and
wherein in the plan view, the center of the fourth conductor is shifted from a center of the third conductor.

4. The semiconductor device according to claim 1,
wherein the capacitor comprises a fifth conductor serving as the other of the pair of electrodes, and
wherein the fifth conductor has a planar shape.

5. The semiconductor device according to claim 4,
wherein the fifth conductor comprises a first region facing the third conductor with a dielectric of the capacitor therebetween and a second region not overlapping with the first transistor, and
wherein a width of the first region is equal to a thickness of the second region.

6. A semiconductor device comprising:
a first transistor;
a capacitor over the first transistor; and
a second transistor over the capacitor,
wherein each of the first transistor and the second transistor comprises:
a semiconductor layer;
a first conductor over the semiconductor layer;
a first insulator; and
a second conductor over the first insulator,
wherein, in each of the first transistor and the second transistor, a side surface of the semiconductor layer is aligned with a side surface of the first conductor,
wherein, in each of the first transistor and the second transistor, each of the semiconductor layer and the first conductor comprises an opening,
wherein, in each of the first transistor and the second transistor, the first insulator is positioned inside the opening of the semiconductor layer and the opening of the first conductor,
wherein, in each of the first transistor and the second transistor, the first insulator comprises a depressed portion overlapping with the opening of the semiconductor layer and the opening of the first conductor,
wherein, in each of the first transistor and the second transistor, the second conductor fills the depressed portion,
wherein the second conductor of the first transistor comprises a region serving as one of a pair of electrodes of the capacitor, and
wherein the second conductor of the first transistor is electrically connected to the semiconductor layer of the second transistor.

7. The semiconductor device according to claim 6, further comprising a third conductor,
wherein the second conductor of the first transistor is electrically connected to the semiconductor layer of the second transistor through the third conductor.

8. The semiconductor device according to claim 7,
wherein in a plan view, a center of the third conductor is shifted from a center of the opening of the semiconductor layer of the second transistor, and
wherein in the plan view, the center of the third conductor is shifted from a center of the second conductor of the first transistor.

9. The semiconductor device according to claim 6,
wherein the capacitor comprises a fourth conductor serving as the other of the pair of electrodes, and
wherein the fourth conductor has a planar shape.

10. The semiconductor device according to claim 6,
wherein the second conductor of the first transistor comprises a first region facing the semiconductor layer of the first transistor with the first insulator of the first transistor therebetween and a second region above the other of the pair of electrodes of the capacitor and in contact with a bottom surface of the semiconductor layer of the second transistor,
wherein the first region has a first width, and
wherein the second region has a second width larger than the first width.

11. The semiconductor device according to claim 1,
wherein in a cross-sectional view, a side surface of the semiconductor layer on an opening side has a tapered shape.

12. The semiconductor device according to claim 1,
wherein the semiconductor layer comprises a first metal oxide, a second metal oxide over the first metal oxide, and a third metal oxide over the second metal oxide.

13. The semiconductor device according to claim 6,
wherein in a cross-sectional view, a side surface of the semiconductor layer on an opening side has a tapered shape.

14. The semiconductor device according to claim 6,
wherein the semiconductor layer comprises a first metal oxide, a second metal oxide over the first metal oxide, and a third metal oxide over the second metal oxide.
